(19) United States
(12) Patent Application Publication
(10) Pub. No.: US 2026/0047268 A1
(43) Pub. Date: Feb. 12, 2026

(54) Light-Emitting Device And Display Apparatus

(71) Applicant: Semiconductor Energy Laboratory Co., Ltd., Kanagawa-ken (JP)

(72) Inventors: Satoshi SEO, Sagamihara (JP); Nobuharu OHSAWA, Zama (JP); Hiromi SEO, Sagamihara (JP); Hiromitsu KIDO, Atsugi (JP); Yuki HAYASHI, Atsugi (JP)

(73) Assignee: Semiconductor Energy Laboratory Co., Ltd., Kanagawa-ken (JP)

(21) Appl. No.: 19/292,318

(22) Filed: Aug. 6, 2025

(30) Foreign Application Priority Data
Aug. 9, 2024 (JP) 2024-134240

(51) Int. Cl. H10K 50/155; H10K 50/13; H10K 50/15; H10K 50/16; H10K 50/165; H10K 50/19; H10K 85/30; H10K 85/40; H10K 85/60

(52) U.S. Cl. CPC H10K 50/155; H10K 50/13; H10K 50/156; H10K 50/165; H10K 50/166; H10K 50/19; H10K 85/346; H10K 85/371; H10K 85/40; H10K 85/622; H10K 85/626; H10K 85/633; H10K 85/636; H10K 85/654; H10K 85/656; H10K 85/6572; H10K 85/6574; H10K 85/6576; H10K 85/658

(57) ABSTRACT

A light-emitting device having favorable characteristics is provided. The light-emitting device is a tandem light-emitting device. In the light-emitting device, a first light-emitting layer and a second light-emitting layer include a first light-emitting substance and a second light-emitting substance, respectively. Each of the first and second light-emitting substances is a TADF material. At least one of first and second hole-transport layers includes an organic compound having a π-electron rich heteroaromatic ring and no triarylamine skeleton. A difference between a maximum peak wavelength of an emission spectrum of the first light-emitting substance and a maximum peak wavelength of an emission spectrum of the second light-emitting substance is less than or equal to 30 nm. The first and second light-emitting layers each emit light with a hue different from a hue of light emitted by a light-emitting layer included in at least one of a plurality of adjacent light-emitting devices.

### BACKGROUND OF THE INVENTION

### 1. Field of the Invention

One embodiment of the present invention relates to a light-emitting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an imaging device, an electronic appliance, a driving method thereof, and a manufacturing method thereof.

### 2. Description of the Related Art

Recently, display devices have been expected to be applied to a variety of uses. Usage examples of large-sized display apparatuses include a television device for home use (also referred to as TV or television receiver), digital signage, and a public information display (PID). In addition, a smartphone and a tablet terminal each including a touch panel, for example, are being developed as portable information terminals.

Higher-resolution display apparatuses have been required. For example, devices for virtual reality (VR), augmented reality (AR), substitutional reality (SR), or mixed reality (MR) are given as devices requiring high-resolution display apparatuses and have been actively developed.

Light-emitting apparatuses that include light-emitting devices (also referred to as light-emitting elements) have been developed as display apparatuses, for example. Light-emitting devices utilizing electroluminescence (hereinafter referred to as EL; such devices are also referred to as EL devices or EL elements) have features such as ease of reduction in thickness and weight, high-speed response to input signals, and driving with a constant voltage DC power source, and have been widely used in display apparatuses.

Tandem light-emitting devices have attracted particular attention because of their high current efficiency, and Patent Documents 1 and 2 disclose tandem light-emitting devices fabricated by a side-by-side patterning method.

### REFERENCE

[Patent Document 1] Japanese Published Patent Application No. 2005-317548
[Patent Document 2] Japanese Published Patent Application No. 2023-161850

### SUMMARY OF THE INVENTION

An object of one embodiment of the present invention is to provide a light-emitting device having favorable characteristics. Another object of one embodiment of the present invention is to provide a light-emitting device having high emission efficiency. Another object of one embodiment of the present invention is to provide a light-emitting device having high reliability. Another object of one embodiment of the present invention is to provide a light-emitting device having a low driving voltage. Another object of one embodiment of the present invention is to provide a light-emitting device having high reliability and a low driving voltage.

Another object of one embodiment of the present invention is to provide a light-emitting device which enables a display apparatus to have favorable characteristics. Another object of one embodiment of the present invention is to provide a light-emitting device which enables a display apparatus to have high emission efficiency. Another object of one embodiment of the present invention is to provide a light-emitting device which enables a display apparatus to have high reliability. Another object of one embodiment of the present invention is to provide a light-emitting device which enables a display apparatus to have a low driving voltage. Another object of one embodiment of the present invention is to provide a light-emitting device which enables a display apparatus to have high reliability and a low driving voltage.

Another object of one embodiment of the present invention is to provide any of an organic semiconductor device, a light-emitting device, a light-receiving device, a display apparatus, an electronic appliance, and a lighting device each having low power consumption. Another object of one embodiment of the present invention is to provide an electronic appliance having high reliability or a lighting device having high reliability. Another object of one embodiment of the present invention is to provide any of a novel organic semiconductor device, a novel light-emitting device, a novel light-receiving device, a novel display apparatus, a novel electronic appliance, and a novel lighting device.

Note that the description of these objects does not preclude the existence of other objects. One embodiment of the present invention does not need to achieve all of these objects. Other objects will be apparent from and can be derived from the description of the specification, the drawings, the claims, and the like.

In one embodiment of the present invention, a substance capable of exhibiting thermally activated delayed fluorescence (TADF) is used as a light-emitting substance in each light-emitting layer of a tandem light-emitting device fabricated by a side-by-side patterning method. Furthermore, an organic compound having no triarylamine skeleton is used for a layer in contact with one of the light-emitting layers.

One embodiment of the present invention is a light-emitting device including a first electrode, a second electrode, an intermediate layer, a first light-emitting layer, a second light-emitting layer, a first hole-transport layer, and a second hole-transport layer. The intermediate layer is between the first electrode and the second electrode. The first light-emitting layer is between the first electrode and the intermediate layer. The second light-emitting layer is between the intermediate layer and the second electrode. The first hole-transport layer is between the first electrode and the first light-emitting layer. The second hole-transport layer is between the intermediate layer and the second light-emitting layer. The first light-emitting layer includes a first light-emitting substance. The second light-emitting layer includes a second light-emitting substance. Each of the first light-emitting substance and the second light-emitting substance is a TADF material. At least one of the first hole-transport layer and the second hole-transport layer includes an organic compound having a π-electron rich heteroaromatic ring and no triarylamine skeleton. A difference between a maximum peak wavelength of an emission spectrum of the first light-emitting substance and a maximum peak wavelength of an emission spectrum of the second light-emitting substance is less than or equal to 30 nm. The first light-emitting layer and the second light-emitting layer each emit light with a hue different from a hue of light emitted by a light-emitting layer included in at least one of a plurality of adjacent light-emitting devices.

Another embodiment of the present invention is a light-emitting device including a first electrode, a second electrode, an intermediate layer, a first light-emitting layer, a second light-emitting layer, a first hole-transport layer, and a second hole-transport layer. The intermediate layer is between the first electrode and the second electrode. The first light-emitting layer is between the first electrode and the intermediate layer. The second light-emitting layer is between the intermediate layer and the second electrode. The first hole-transport layer is between the first electrode and the first light-emitting layer. The second hole-transport layer is between the intermediate layer and the second light-emitting layer. The first hole-transport layer includes a first layer and a second layer. The first layer is in contact with the first light-emitting layer. The first light-emitting layer includes a first light-emitting substance and a first organic compound. A difference between a wavelength of an emission edge on a shorter wavelength side of a fluorescence spectrum of the first light-emitting substance and a wavelength of an emission edge on a shorter wavelength side of a phosphorescence spectrum of the first light-emitting substance is less than or equal to 30 nm. A wavelength of an emission edge on a shorter wavelength side of a phosphorescence spectrum of the first organic compound is shorter than the wavelength of the emission edge on the shorter wavelength side of the phosphorescence spectrum of the first light-emitting substance. The second light-emitting layer includes a second light-emitting substance and a second organic compound. A difference between a wavelength of an emission edge on a shorter wavelength side of a fluorescence spectrum of the second light-emitting substance and a wavelength of an emission edge on a shorter wavelength side of a phosphorescence spectrum of the second light-emitting substance is less than or equal to 30 nm. A wavelength of an emission edge on a shorter wavelength side of a phosphorescence spectrum of the second organic compound is shorter than the wavelength of the emission edge on the shorter wavelength side of the phosphorescence spectrum of the second light-emitting substance. The first layer includes a third organic compound. The third organic compound has a π-electron rich heteroaromatic ring and no triarylamine skeleton. The second layer includes a fourth organic compound. The fourth organic compound has a triarylamine skeleton. A difference between a maximum peak wavelength of the fluorescence spectrum of the first light-emitting substance and a maximum peak wavelength of the fluorescence spectrum of the second light-emitting substance is less than or equal to 30 nm. The first light-emitting layer and the second light-emitting layer each emit light with a hue different from a hue of light emitted by a light-emitting layer included in at least one of a plurality of adjacent light-emitting devices.

Another embodiment of the present invention is the light-emitting device with the above structure, in which a difference between a singlet excitation energy level (S₁ level) of the first light-emitting substance and a triplet excitation energy level (T₁ level) of the first light-emitting substance is greater than 0 eV and less than or equal to 0.20 eV, and a difference between a singlet excitation energy level (S₁ level) of the second light-emitting substance and a triplet excitation energy level (T₁ level) of the second light-emitting substance is greater than 0 eV and less than or equal to 0.20 eV.

Another embodiment of the present invention is the light-emitting device with the above structure, in which a wavelength of an emission edge on a shorter wavelength side of a fluorescence spectrum of the first organic compound is shorter than a wavelength of an absorption edge on a longer wavelength side of an absorption spectrum of the first light-emitting substance, and a wavelength of an emission edge on a shorter wavelength side of a fluorescence spectrum of the second organic compound is shorter than a wavelength of an absorption edge on a longer wavelength side of an absorption spectrum of the second light-emitting substance.

Another embodiment of the present invention is the light-emitting device with the above structure, in which each of the first light-emitting substance and the second light-emitting substance is a substance capable of exhibiting thermally activated delayed fluorescence.

Another embodiment of the present invention is the light-emitting device with the above structure, in which the fourth organic compound has a polycyclic aromatic ring.

Another embodiment of the present invention is the light-emitting device with any of the above structures, in which the first light-emitting substance is the same substance as the second light-emitting substance.

Another embodiment of the present invention is the light-emitting device with any of the above structures, including a first electron-transport layer between the first light-emitting layer and the intermediate layer. The first electron-transport layer includes an organic compound having any one of a triazine ring, a pyrimidine ring, an imidazole ring, and an anthracene ring.

Another embodiment of the present invention is the light-emitting device with any of the above structures, including a second electron-transport layer between the second light-emitting layer and the second electrode. The second electron-transport layer includes a layer including an organic compound having a triazine ring. The intermediate layer includes a first mixed layer of lithium or a lithium compound and an organic compound having a phenanthroline ring.

Another embodiment of the present invention is the light-emitting device with the above structure, in which the second electron-transport layer includes a second mixed layer of lithium or a lithium compound and an organic compound having a triazine ring. The second mixed layer is between the second electrode and the layer including the organic compound having the triazine ring.

Another embodiment of the present invention is a display apparatus including a light-emitting device A and a light-emitting device B. The light-emitting device A and the light-emitting device B emit light of different colors. The light-emitting device A includes a first electrode A, a second electrode A, an intermediate layer A, a first light-emitting layer A, a second light-emitting layer A, a first hole-transport layer A, and a second hole-transport layer A. The intermediate layer A is between the first electrode A and the second electrode A. The first light-emitting layer A is between the first electrode A and the intermediate layer A. The second light-emitting layer A is between the intermediate layer A and the second electrode A. The first hole-transport layer A is between the first electrode A and the first light-emitting layer A. The second hole-transport layer A is between the intermediate layer A and the second light-emitting layer A. The first light-emitting layer A includes a first light-emitting substance. The second light-emitting layer A includes a second light-emitting substance. The first light-emitting substance is a substance capable of exhibiting thermally activated delayed fluorescence. The second light-emitting substance is a substance capable of exhibiting thermally activated delayed fluorescence. At least one of the first hole-transport layer A and the second hole-transport layer A includes an organic compound A having a π-electron rich heteroaromatic ring and no triarylamine skeleton. A difference between a maximum peak wavelength of an emission spectrum of the first light-emitting substance and a maximum peak wavelength of an emission spectrum of the second light-emitting substance is less than or equal to 30 nm. The light-emitting device B includes a first electrode B, a second electrode B, an intermediate layer B, a first light-emitting layer B, a second light-emitting layer B, a first hole-transport layer B, and a second hole-transport layer B. The intermediate layer B is between the first electrode B and the second electrode B. The first light-emitting layer B is between the first electrode B and the intermediate layer B. The second light-emitting layer B is between the intermediate layer B and the second electrode B. The first hole-transport layer B is between the first electrode B and the first light-emitting layer B. The second hole-transport layer B is between the intermediate layer B and the second light-emitting layer B. The first light-emitting layer B includes a first phosphorescent substance. The second light-emitting layer B includes a second phosphorescent substance. At least one of the first hole-transport layer B and the second hole-transport layer B includes an organic compound B having a triarylamine skeleton. A difference between a maximum peak wavelength of an emission spectrum of the first phosphorescent substance and a maximum peak wavelength of an emission spectrum of the second phosphorescent substance is less than or equal to 30 nm. The first light-emitting layer A and the second light-emitting layer A each emit light with a hue different from a hue of light emitted by each of the first light-emitting layer B and the second light-emitting layer B.

Another embodiment of the present invention is a display apparatus including a light-emitting device A and a light-emitting device B. The light-emitting device A and the light-emitting device B emit light of different colors. The light-emitting device A includes a first electrode A, a second electrode A, an intermediate layer A, a first light-emitting layer A, a second light-emitting layer A, a first hole-transport layer A, and a second hole-transport layer A. The intermediate layer A is between the first electrode A and the second electrode A. The first light-emitting layer A is between the first electrode A and the intermediate layer A. The second light-emitting layer A is between the intermediate layer A and the second electrode A. The first hole-transport layer A is between the first electrode A and the first light-emitting layer A. The second hole-transport layer A is between the intermediate layer A and the second light-emitting layer A. The first light-emitting layer A includes a first light-emitting substance. The second light-emitting layer A includes a second light-emitting substance. The first light-emitting substance is a substance capable of exhibiting thermally activated delayed fluorescence. The second light-emitting substance is a substance capable of exhibiting thermally activated delayed fluorescence. At least one of the first hole-transport layer A and the second hole-transport layer A includes an organic compound A having no triarylamine skeleton. A difference between a maximum peak wavelength of an emission spectrum of the first light-emitting substance and a maximum peak wavelength of an emission spectrum of the second light-emitting substance is less than or equal to 30 nm. The light-emitting device B includes a first electrode B, a second electrode B, an intermediate layer B, a first light-emitting layer B, a second light-emitting layer B, a first hole-transport layer B, and a second hole-transport layer B. The intermediate layer B is between the first electrode B and the second electrode B. The first light-emitting layer B is between the first electrode B and the intermediate layer B. The second light-emitting layer B is between the intermediate layer B and the second electrode B. The first hole-transport layer B is between the first electrode B and the first light-emitting layer B. The second hole-transport layer B is between the intermediate layer B and the second light-emitting layer B. The first light-emitting layer B includes a first fluorescent substance. The second light-emitting layer B includes a second fluorescent substance. At least one of the first hole-transport layer B and the second hole-transport layer B includes an organic compound B having a triarylamine skeleton. A difference between a maximum peak wavelength of an emission spectrum of the first fluorescent substance and a maximum peak wavelength of an emission spectrum of the second fluorescent substance is less than or equal to 30 nm. The first light-emitting layer A and the second light-emitting layer A each emit light with a hue different from a hue of light emitted by each of the first light-emitting layer B and the second light-emitting layer B.

Another embodiment of the present invention is a light-emitting apparatus including any of the above light-emitting devices and a transistor or a substrate.

Another embodiment of the present invention is an electronic appliance including the above light-emitting apparatus, and a sensing portion, an input portion, or a communication portion.

One embodiment of the present invention can provide a light-emitting device having favorable characteristics. Another embodiment of the present invention can provide a light-emitting device having high emission efficiency. Another embodiment of the present invention can provide a light-emitting device having high reliability. Another embodiment of the present invention can provide a light-emitting device having a low driving voltage. Another embodiment of the present invention can provide a light-emitting device having high reliability and a low driving voltage.

Another embodiment of the present invention can provide a light-emitting device which enables a display apparatus to have favorable characteristics. Another embodiment of the present invention can provide a light-emitting device which enables a display apparatus to have high emission efficiency. Another embodiment of the present invention can provide a light-emitting device which enables a display apparatus to have high reliability. Another embodiment of the present invention can provide a light-emitting device which enables a display apparatus to have a low driving voltage. Another embodiment of the present invention can provide a light-emitting device which enables a display apparatus to have high reliability and a low driving voltage.

Another embodiment of the present invention can provide any of an organic semiconductor device, a light-emitting device, a light-receiving device, a display apparatus, an electronic appliance, and a lighting device each having low power consumption. Another embodiment of the present invention can provide an electronic appliance having high reliability or a lighting device having high reliability. Another embodiment of the present invention can provide any of a novel organic semiconductor device, a novel light-emitting device, a novel light-receiving device, a novel display apparatus, a novel electronic appliance, and a novel lighting device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A and 1B each illustrate a light-emitting device.

FIG. 2 illustrates a light-emitting device.

FIGS. 3A and 3B each illustrate a light-emitting device.

FIG. 4 illustrates a light-emitting device.

FIGS. 5A and 5B illustrate a display apparatus of one embodiment of the present invention.

FIGS. 6A and 6B are a top view and a cross-sectional view of a light-emitting apparatus.

FIGS. 7A to 7G are top views each illustrating a structure example of a pixel.

FIGS. 8A to 8I are top views each illustrating a structure example of a pixel.

FIGS. 9A and 9B are perspective views illustrating a structure example of a display module.

FIGS. 10A and 10B are cross-sectional views illustrating structure examples of a display apparatus.

FIG. 11 is a perspective view illustrating a structure example of a display apparatus.

FIG. 12 is a cross-sectional view illustrating a structure example of a display apparatus.

FIG. 13 is a cross-sectional view illustrating a structure example of a display apparatus.

FIGS. 14A to 14C are a cross-sectional view and top views illustrating a structure example of a display apparatus.

FIG. 15 is a cross-sectional view illustrating a structure example of a display apparatus.

FIGS. 16A to 16C are a cross-sectional view and top views illustrating a structure example of a display apparatus.

FIGS. 17A to 17D illustrate examples of electronic appliances.

FIGS. 18A to 18F illustrate examples of electronic appliances.

FIGS. 19A to 19G illustrate examples of electronic appliances.

FIG. 20 illustrates a structure of light-emitting devices.

FIG. 21 illustrates a structure of light-emitting devices.

FIG. 22 is a graph showing luminance-current density characteristics of light-emitting devices B-1, B-2, and B-3.

FIG. 23 is a graph showing luminance-voltage characteristics of the light-emitting devices B-1, B-2, and B-3.

FIG. 24 is a graph showing current efficiency-luminance characteristics of the light-emitting devices B-1, B-2, and B-3.

FIG. 25 is a graph showing current density-voltage characteristics of the light-emitting devices B-1, B-2, and B-3.

FIG. 26 is a graph showing blue index (BI)-current density characteristics of the light-emitting devices B-1, B-2, and B-3.

FIG. 27 is a graph showing electroluminescence spectra of the light-emitting devices B-1, B-2, and B-3.

FIG. 28 is a graph showing luminance-current density characteristics of light-emitting devices G-1, G-2, and G-3.

FIG. 29 is a graph showing luminance-voltage characteristics of the light-emitting devices G-1, G-2, and G-3.

FIG. 30 is a graph showing current efficiency-luminance characteristics of the light-emitting devices G-1, G-2, and G-3.

FIG. 31 is a graph showing current density-voltage characteristics of the light-emitting devices G-1, G-2, and G-3.

FIG. 32 is a graph showing electroluminescence spectra of the light-emitting devices G-1, G-2, and G-3.

FIG. 33 is a graph showing luminance-current density characteristics of light-emitting devices R-1 and R-2.

FIG. 34 is a graph showing luminance-voltage characteristics of the light-emitting devices R-1 and R-2.

FIG. 35 is a graph showing current efficiency-luminance characteristics of the light-emitting devices R-1 and R-2.

FIG. 36 is a graph showing current density-voltage characteristics of the light-emitting devices R-1 and R-2.

FIG. 37 is a graph showing electroluminescence spectra of the light-emitting devices R-1 and R-2.

FIGS. 38A and 38B are graphs each showing an emission spectrum of ν-DABNA.

FIGS. 39A and 39B are graphs each showing an emission spectrum of DACT-II.

FIGS. 40A and 40B are graphs each showing an emission spectrum of TDBA-Si.

FIGS. 41A and 41B are graphs each showing an emission spectrum of 4,6mCzP2Pm.

FIGS. 42A and 42B are graphs each showing an emission spectrum of 3,10PCA2Nbf(IV)-02.

FIGS. 43A to 43C are graphs showing an emission spectrum of αN-βNPAnth.

FIG. 44 is a graph showing an emission spectrum of 2PCAPA.

FIG. 45 is a graph showing an emission spectrum of cgDBCzPA.

FIG. 46 is a graph showing an absorption spectrum and an emission spectrum of TDBA-Si.

FIG. 47 is a graph showing an absorption spectrum and an emission spectrum of ν-DABNA.

FIG. 48 is a graph showing an absorption spectrum and an emission spectrum of 4,6mCzP2Pm.

FIG. 49 is a graph showing an absorption spectrum and an emission spectrum of DACT-II.

FIG. 50 is a graph showing an emission spectrum of oFBiSF(2).

FIG. 51 is a graph showing an emission spectrum of PSiCzCz.

FIG. 52 is a graph showing an emission spectrum of mPCCzPTzn-02.

FIG. 53 is a graph showing an emission spectrum of mFBPTzn.

FIG. 54 is a graph showing an emission spectrum of DBfBB1TP.

FIG. 55 is a graph showing an emission spectrum of PCCP.

FIG. 56 is a graph showing an emission spectrum of 11mDBtBPPnfpr.

FIG. 57 is a graph showing an emission spectrum of PCBBiF.

FIG. 58 is a graph showing luminance-current density characteristics of light-emitting devices B-4, G-4, and R-3.

FIG. 59 is a graph showing luminance-voltage characteristics of the light-emitting devices B-4, G-4, and R-3.

FIG. 60 is a graph showing current efficiency-luminance characteristics of the light-emitting devices B-4, G-4, and R-3.

FIG. 61 is a graph showing current density-voltage characteristics of the light-emitting devices B-4, G-4, and R-3.

FIG. 62 is a graph showing blue index (BI)-current density characteristics of the light-emitting device B-4.

FIG. 63 is a graph showing electroluminescence spectra of the light-emitting devices B-4, G-4, and R-3.

FIGS. 64A and 64B are graphs each showing an emission spectrum of 3Ph2CzCzBN.

FIGS. 65A and 65B are graphs each showing an emission spectrum of SiTrzCz2.

FIGS. 66A and 66B are graphs each showing an emission spectrum of PSiCzCz.

FIG. 67 is a graph showing an absorption spectrum and an emission spectrum of 3Ph2CzCzBN.

FIG. 68 is a graph showing an absorption spectrum and an emission spectrum of SiTrzCz2.

FIG. 69 is a graph showing an absorption spectrum and an emission spectrum of PSiCzCz.

FIG. 70 is a graph showing emission spectra of a film of SiTrzCz2, a film of PSiCzCz, and a mixed film of SiTrzCz2 and PSiCzCz.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases. Furthermore, an injection layer, a transport layer, or a blocking layer may be referred to simply as a layer. Similarly, the other layers such as a light-emitting layer and an intermediate layer may each be referred to simply as a layer.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape indicates a shape such that at least part of a side surface of a structure is inclined relative to a substrate surface. For example, a tapered shape preferably includes a region where the angle formed between the inclined side surface and the substrate surface (such an angle is also referred to as a taper angle) is less than 90°. Note that the side surface of the component and the substrate surface are not necessarily completely flat and may be substantially flat with a slight curvature or with slight unevenness.

Note that the light-emitting apparatus in this specification includes, in its category, an image display device that uses an organic EL device. The light-emitting apparatus may also include a module in which an organic EL device is provided with a connector such as an anisotropic conductive film or a tape carrier package (TCP), a module in which a printed wiring board is further provided at the end of the TCP, and a module in which an integrated circuit (IC) is directly mounted on an organic EL device by a chip on glass (COG) method. Furthermore, a lighting device or the like may include the light-emitting apparatus.

Note that in this specification and the like, a photoluminescence (PL) spectrum refers to a spectrum obtained by scanning the wavelength of light emission while the excitation wavelength of excitation light is fixed in fluorometry. A PL spectrum is also referred to as an emission spectrum in some cases. Note that an emission spectrum may include a fluorescence component and a phosphorescence component. In this specification and the like, an emission spectrum including a fluorescence component is particularly referred to as a fluorescence spectrum, and an emission spectrum including a phosphorescence component is particularly referred to as a phosphorescence spectrum in some cases. Since a phosphorescent substance does not emit fluorescent light, the emission spectrum of a phosphorescent substance is a phosphorescence spectrum. Furthermore, since a TADF material at room temperature converts triplet excitation energy into singlet excitation energy and emits fluorescent light, the emission spectrum of a TADF material at room temperature is a fluorescence spectrum.

### Embodiment 1

A tandem light-emitting device has a structure in which a plurality of light-emitting units are stacked between a pair of electrodes with an intermediate layer (a charge-generation layer) between the plurality of light-emitting units. The plurality of light-emitting units include their respective light-emitting layers, and each of the light-emitting layers can emit light with a flow of current therethrough. The tandem light-emitting device having such a structure has a much higher current efficiency than a non-tandem light-emitting device, and can thus be suitably used for a display apparatus that is required to perform high-luminance display or that needs to have high reliability.

Since the tandem light-emitting device includes a plurality of light-emitting layers and can thus easily provide white light emission, many full-color display apparatuses including the tandem light-emitting device employ a “white+color filter” method. A color conversion method is also in practical use in which light-emitting layers that emit blue light are stacked and a color conversion layer typified by quantum dots is used.

Meanwhile, some full-color display apparatuses employing a side-by-side patterning method and the tandem light-emitting device have also been put into practical use. A light-emitting device fabricated by the side-by-side patterning method has little or no energy loss due to a color filter or a color conversion layer and can thus have a higher emission efficiency than light-emitting devices fabricated by the above-described two methods.

The light-emitting layer included in the tandem light-emitting device is preferably separated from a light-emitting layer included in at least one adjacent light-emitting device. Alternatively, the light-emitting layer included in the tandem light-emitting device is preferably different from a light-emitting layer included in at least one adjacent light-emitting device. Alternatively, the emission color of the tandem light-emitting device is preferably different from the emission color of at least one adjacent light-emitting device. Alternatively, a light-emitting substance included in the light-emitting layer of the tandem light-emitting device preferably has a structure different from that of a light-emitting substance included in a light-emitting layer of at least one adjacent light-emitting device.

The light-emitting device of one embodiment of the present invention that has the above structure can have high current efficiency, low energy loss, and favorable characteristics. A display apparatus of one embodiment of the present invention that includes such a light-emitting device can achieve low power consumption, high reliability, high-luminance display, and high visibility.

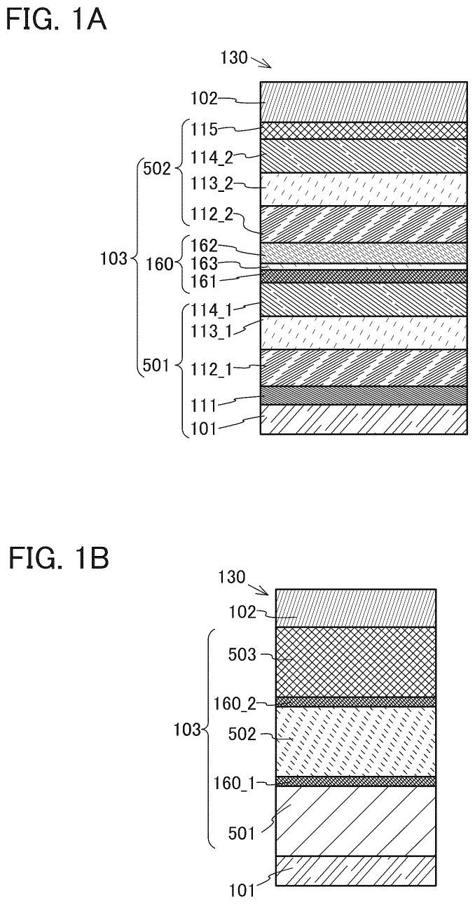

Next, light-emitting devices of embodiments of the present invention will be described in detail with reference to the drawings. FIG. 1A illustrates a light-emitting device 130 of one embodiment of the present invention. The light-emitting device of one embodiment of the present invention is a tandem light-emitting device including an organic compound layer 103 (also referred to as an EL layer) between a first electrode 101 including an anode and a second electrode 102 including a cathode. The organic compound layer 103 includes a first light-emitting unit 501 including a first light-emitting layer 113_1, a second light-emitting unit 502 including a second light-emitting layer 1132, and an intermediate layer 160.

Although light-emitting devices each including one intermediate layer 160 and two light-emitting units are described as examples in this embodiment, a light-emitting device including n intermediate layer(s) (n is an integer greater than or equal to 1) and n+1 light-emitting units may be employed. For example, the light-emitting device 130 illustrated in FIG. 1B is an example of a tandem light-emitting device with n=2 that includes the first light-emitting unit 501, a first intermediate layer 1601, the second light-emitting unit 502, a second intermediate layer 1602, and a third light-emitting unit 503.

### <Light-Emitting Layer>

In one embodiment of the present invention, a material that can exhibit thermally activated delayed fluorescence (TADF material) is used as a light-emitting substance in the first light-emitting layer 113_1 or the second light-emitting layer 113_2. A TADF material is a material having a function of converting both singlet excitation energy and triplet excitation energy into light emission. A TADF material is preferably used for a light-emitting layer, in which case the emission efficiency of a light-emitting device can be increased. It is particularly preferable to use a TADF material for light-emitting device that emits green light and a light-emitting device that emits blue light.

A TADF material has a small difference between the triplet excitation energy level (T₁ level) and the singlet excitation energy level (S₁ level) and a function of converting triplet excitation energy into singlet excitation energy by reverse intersystem crossing. Thus, a TADF material enables up-conversion (reverse intersystem crossing) from a triplet excited state to a singlet excited state using a little thermal energy and efficiently exhibit light emission (fluorescence) from the singlet excited state. Thermally activated delayed fluorescence is efficiently obtained under the condition where a difference between a wavelength of an emission edge on a shorter wavelength side of a fluorescence spectrum and a wavelength of an emission edge on a shorter wavelength side of a phosphorescence spectrum is less than or equal to 30 nm, or the condition where an energy difference between the T₁ level and the S₁ level is preferably greater than 0 eV and less than or equal to 0.20 eV, further preferably greater than 0 eV and less than or equal to 0.10 eV.

As an indicator of a T₁ level, a phosphorescence component in a photoluminescence (PL) spectrum (phosphorescence spectrum) observed at a low temperature (at any temperature in the range from 4 K to 80 K, for example) is used. For example, a PL spectrum (phosphorescence spectrum) is measured at a measurement temperature of 10 K, and the energy of an emission edge on a shorter wavelength side of the spectrum can be regarded as the T₁ level. As an indicator of an S₁ level, a PL spectrum measured at a low temperature (at any temperature in the range from 4 K to 80 K, for example) or room temperature is used. For example, a PL spectrum is measured at room temperature, and the energy of an emission edge on a shorter wavelength side of the spectrum can be regarded as the S₁ level. In the case where a fluorescence spectrum and a phosphorescence spectrum are observed in a PL spectrum measured at a low temperature, the energy of an emission edge on the shortest wavelength side of the PL spectrum (fluorescence spectrum) can be regarded as the S₁ level. The emission edge on the shorter wavelength side of the PL spectrum can be determined as the intersection between a tangent and the horizontal axis (representing wavelength) or the baseline. The tangent is drawn at a point at which the slope on a shorter wavelength side of the shortest-wavelength peak (or the shortest-wavelength shoulder peak) of the PL spectrum has the maximum absolute value. Note that an emission edge on a shorter wavelength side of a fluorescence spectrum and an emission edge on a shorter wavelength side of a phosphorescence spectrum can be determined in a similar manner.

As the TADF material, for example, an organic compound having a fused heteroaromatic ring containing nitrogen is preferably used, and an organic compound having a diaza-boranaphto-anthracene ring or an indolocarbazole ring is further preferably used. The fused heteroaromatic ring containing nitrogen preferably include, in addition to boron and the above ring, at least one of an aromatic ring (a monocyclic aromatic ring or a polycyclic aromatic ring) and an alkyl group. Examples of the aromatic ring include a benzene ring, a fluorene ring, a carbazole ring, and a dibenzofuran ring. Examples of the alkyl group include a methyl group, an ethyl group, a cyclohexyl group, a propyl group, and a tert-butyl group. A structure in which an alkyl group is bonded to an aromatic ring is preferable. In particular, a structure in which a plurality of alkyl groups are bonded to one benzene ring is suitable. A structure in which a plurality of alkyl groups are bonded to one benzene ring included in a fused ring (e.g., a carbazole ring, a fluorene ring, or a dibenzofuran ring) is also desirable. When the structure in which an alkyl group is bonded to an aromatic ring is included, concentration quenching, or aggregation or crystallization caused by stacking interaction between molecules can be inhibited; accordingly, device characteristic (e.g., efficiency or reliability) can be improved. Note that the above examples of an aromatic ring and an alkyl group are preferable examples, and any of the other aromatic rings and alkyl groups described in this specification can be used.

As the organic compound having a fused heteroaromatic ring containing nitrogen, specifically, any of the following can be suitably used, for example: 5,9-diphenyl-5H,9H-[1,4]benzazaborino[2,3,4-kl]phenazaborine (abbreviation: DABNA-1) represented by Structural Formula (400), 2,12-di-tert-butyl-5,9-bis(4-tert-butylphenyl)-5,9-dihydro-5,9-diaza-13b-boranaphtho[3,2,1-de]anthracene (abbreviation: t-DABNA) represented by Structural Formula (401), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA) represented by Structural Formula (402), 7-(9H-carbazol-9-yl)-5,9-diphenyl-5H,9H-[1,4]benzazaborino[2,3,4-kl]phenazaborine (abbreviation: Cz-DABNA) represented by Structural Formula (403), N,N,5,9-tetraphenyl-5H,9H-[1,4]benzazaborino[2,3,4-kl]phenazaborin-7-amine (abbreviation: DPhA-DABNA) represented by Structural Formula (404), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA) represented by Structural Formula (405), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA) represented by Structural Formula (406), 2,12-di-tert-butyl-5,9-bis(4-(tert-butyl)phenyl)-7-(3,6-di-tert-butyl-9H-carbazol-9-yl)-5,9-dihydro-5,9-diaza-13b-boranaphtho[3,2,1-de]anthracene (abbreviation: TBN-TPA) represented by Structural Formula (407), N⁷N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: ν-DABNA) represented by Structural Formula (408), N⁷,N⁷,N¹³,N¹³,5,15-hexaphenyl-9,11-bis(4-(tert-butyl)phenyl)-5,9,11,15-tetrahydro-5,9,11,15-tetraaza-19b,20b-diboradinaphtho[3,2,1-de:1′,2′,3′-jk]pentacene-7,13-diamine (abbreviation: t-Bu-ν-DABNA) represented by Structural Formula (409), 3,11-bis(2,7-di-tert-butyl-9H-carbazol-9-yl)-7-[2,7-di(3,5-di-tert-butylphenyl)-9H-carbazol-9-yl]-5,9-diphenyl-5H,9H-[1,4]benzazaborino[2,3,4-kl]phenazaborine (abbreviation: mmtBuP2Cz-(2,7tBuCz)2DABNA) represented by Structural Formula (410), 9-(biphenyl-3-yl)-N,N,5,11-tetraphenyl-5H,9H-[1,4]benzazaborino[2,3,4-kl]phenazaborin-3-amine (abbreviation: DABNA-2) represented by Structural Formula (411), N-([1,1′-biphenyl]-3-yl)-N,5,9-tris(2,6-dimethylphenyl)-3,11-diphenyl-5,9-dihydro-5,9-diaza-13b-boranaphtho[3,2,1-de]anthracen-7-amine (abbreviation: mBP-DABNA-Me) represented by Structural Formula (412), N-([1,1′-biphenyl]-4-yl)-N,5,9-tris(2,6-dimethylphenyl)-2,12-diphenyl-5,9-dihydro-5,9-diaza-13b-boranaphtho[3,2,1-de]anthracen-7-amine (abbreviation: pBP-DABNA-Me) represented by Structural Formula (413), 2-(4-tert-butylphenyl)benz[5,6]indolo[3,2,1-jk]benzo[b]carbazole (abbreviation: tBuPBibc) represented by Structural Formula (414), benz[5,6]indolo[3,2,1-jk]benzo[b]carbazole (abbreviation: Bibc) represented by Structural Formula (415), and compounds represented by Structural Formulae (416) to (421).

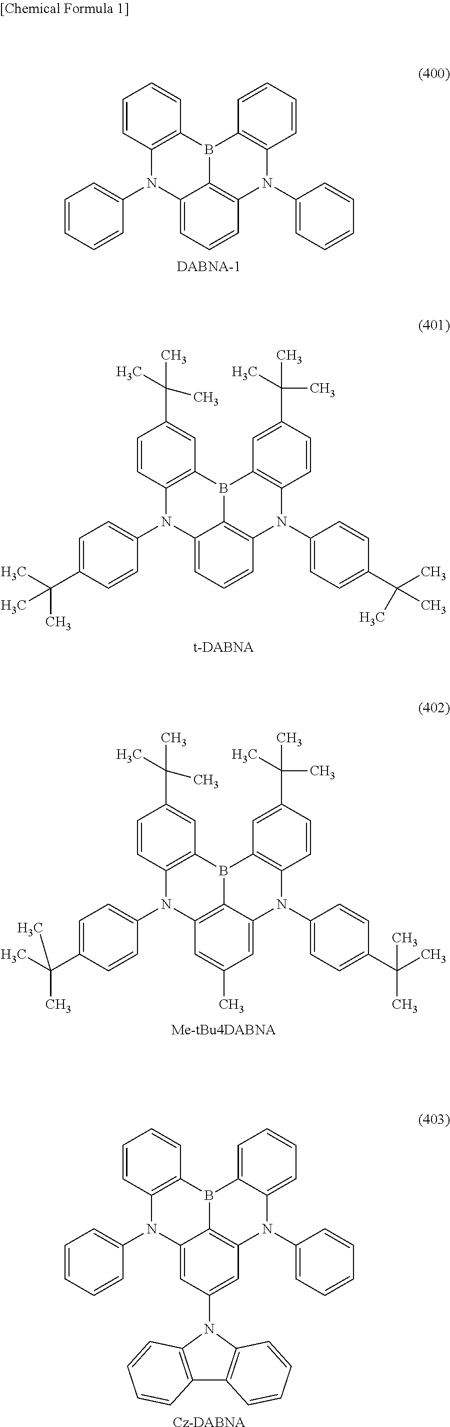

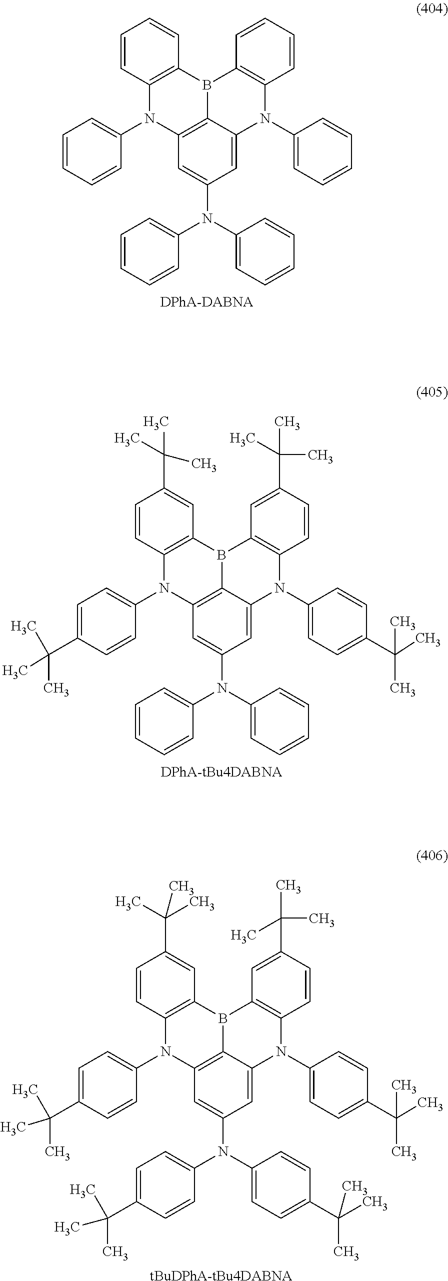

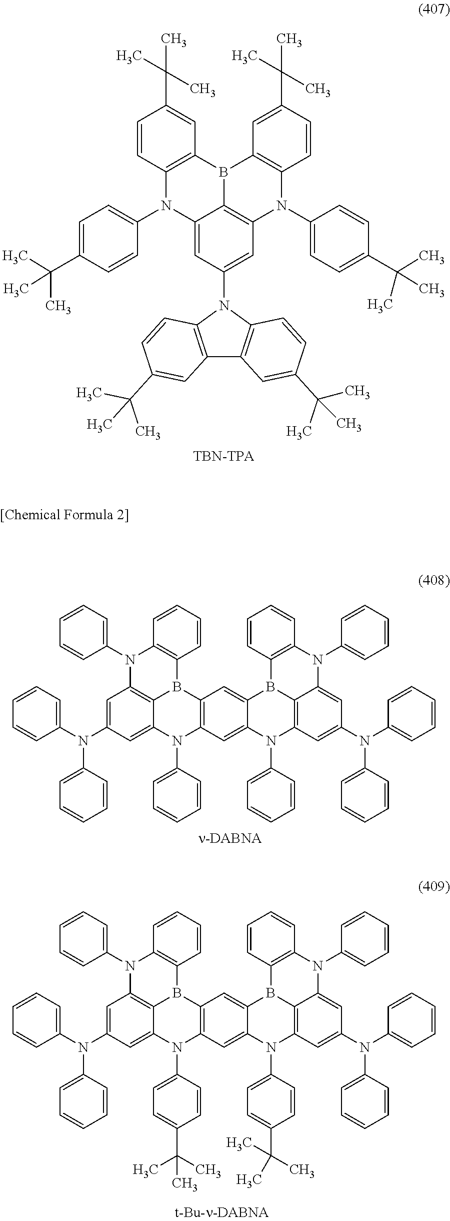

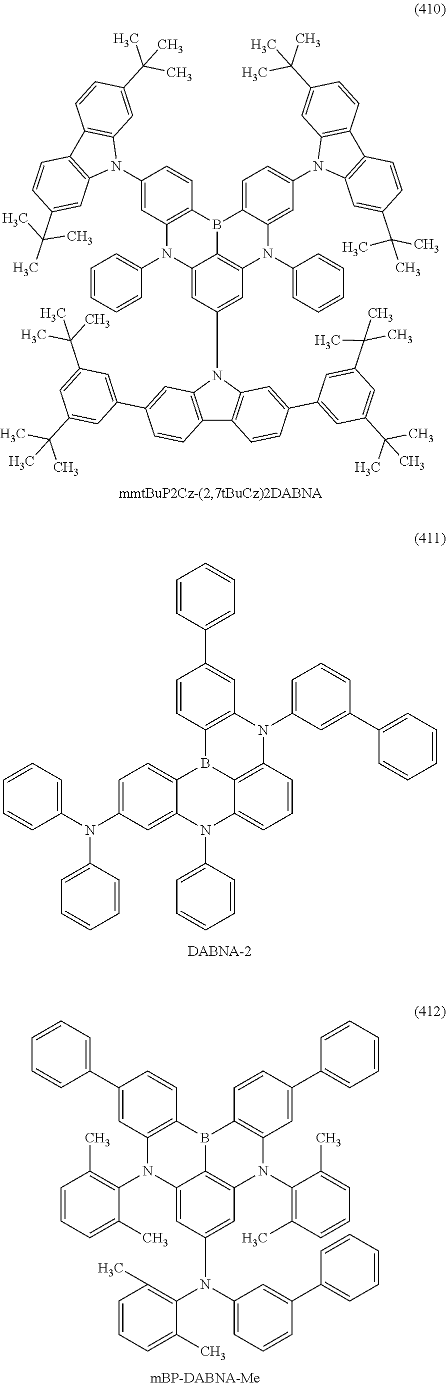

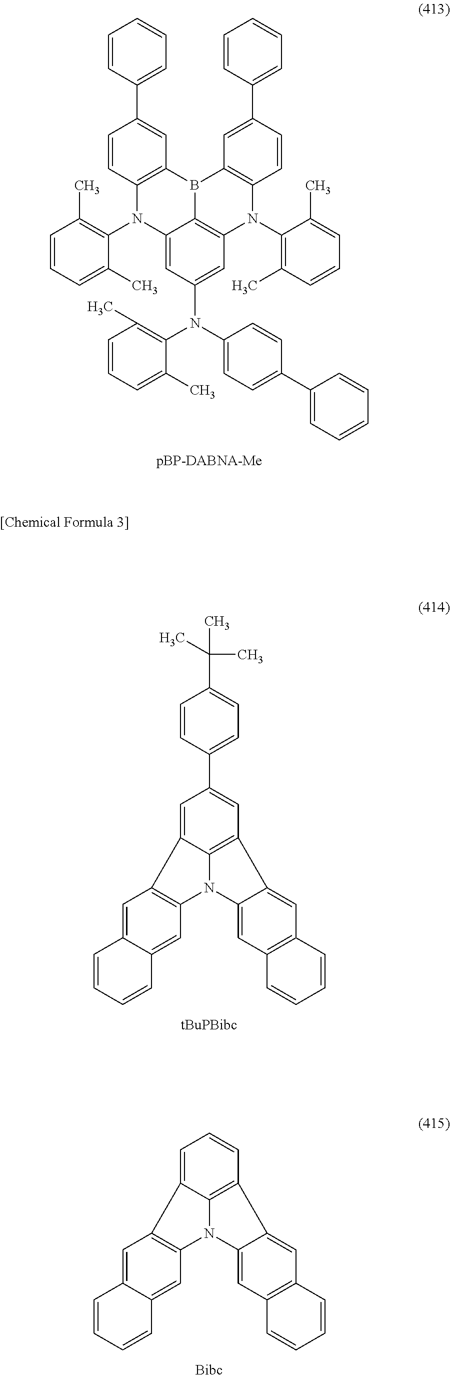 [SMILES: Cc1cccc(C)c1N(c1ccc(-c2ccccc2)cc1)c1cc2c3c(c1)N(c1c(C)cccc1C)c1ccc(-c4ccccc4)cc1B3c1cc(-c3ccccc3)ccc1N2c1c(C)cccc1C ; CC(C)(C)c1ccc(-c2cc3c4cc5ccccc5cc4n4c5cc6ccccc6cc5c(c2)c34)cc1 ; c1ccc2cc3c(cc2c1)c1cccc2c4cc5ccccc5cc4n3c12]

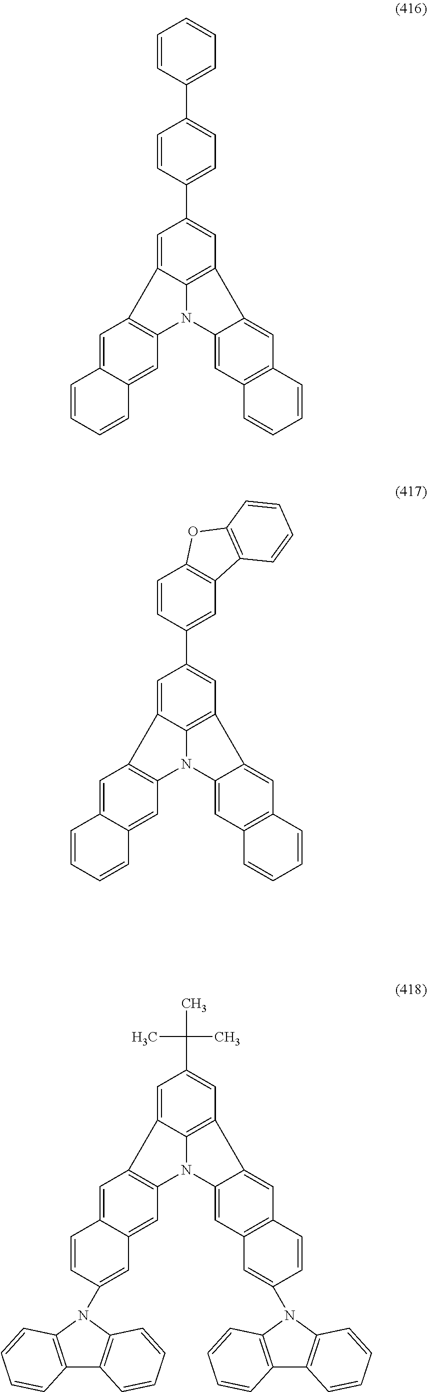 [SMILES: c1ccc(-c2ccc(-c3cc4c5cc6ccccc6cc5n5c6cc7ccccc7cc6c(c3)c45)cc2)cc1 ; c1ccc2cc3c(cc2c1)c1cc(-c2ccc4oc5ccccc5c4c2)cc2c4cc5ccccc5cc4n3c12 ; CC(C)(C)c1cc2c3cc4ccc(-n5c6ccccc6c6ccccc65)cc4cc3n3c4cc5cc(-n6c7ccccc7c7ccccc76)ccc5cc4c(c1)c23]

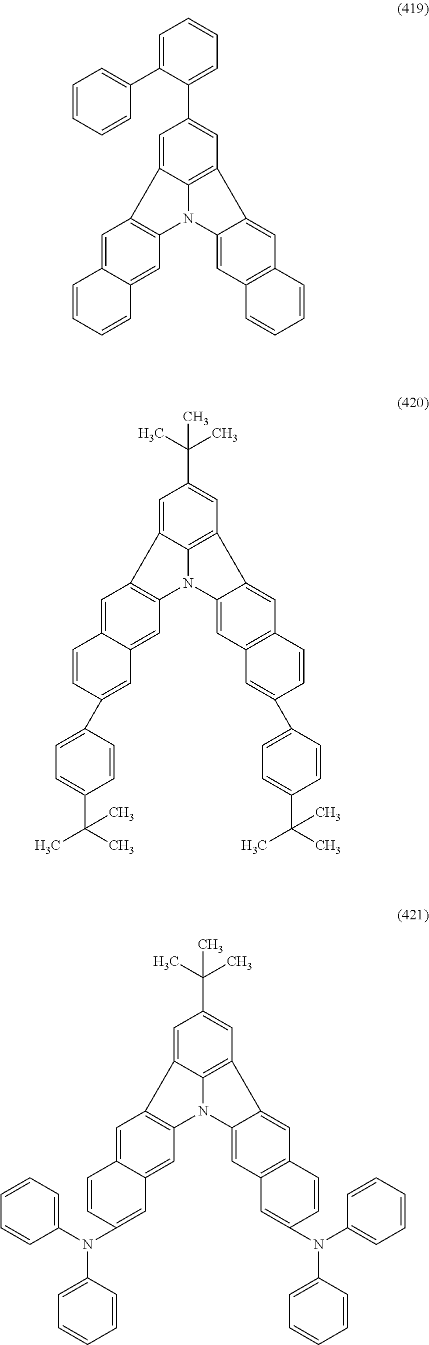 [SMILES: c1ccc(-c2ccccc2-c2cc3c4cc5ccccc5cc4n4c5cc6ccccc6cc5c(c2)c34)cc1 ; CC(C)(C)c1ccc(-c2ccc3cc4c5cc(C(C)(C)C)cc6c7cc8ccc(-c9ccc(C(C)(C)C)cc9)cc8cc7n(c4cc3c2)c56)cc1 ; CC(C)(C)c1cc2c3cc4ccc(N(c5ccccc5)c5ccccc5)cc4cc3n3c4cc5cc(N(c6ccccc6)c6ccccc6)ccc5cc4c(c1)c23]

Examples of the TADF material include a fullerene, a derivative thereof, an acridine, a derivative thereof, and an eosin derivative. Furthermore, a metal-containing porphyrin, such as a porphyrin containing magnesium (Mg), zine (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)) represented by Structural Formula (422), a mesoporphyrin-tin fluoride complex (SnF₂(Meso IX)) represented by Structural Formula (423), a hematoporphyrin-tin fluoride complex (SnF₂(Hemato IX)) represented by Structural Formula (424), a coproporphyrin tetramethyl ester-tin fluoride complex (SnF₂(Copro III-4Me)) represented by Structural Formula (425), an octaethylporphyrin-tin fluoride complex (SnF₂(OEP)) represented by Structural Formula (426), an etioporphyrin-tin fluoride complex (SnF₂(Etio I)) represented by Structural Formula (427), and an octaethylporphyrin-platinum chloride complex (PtCl₂OEP) represented by Structural Formula (428).

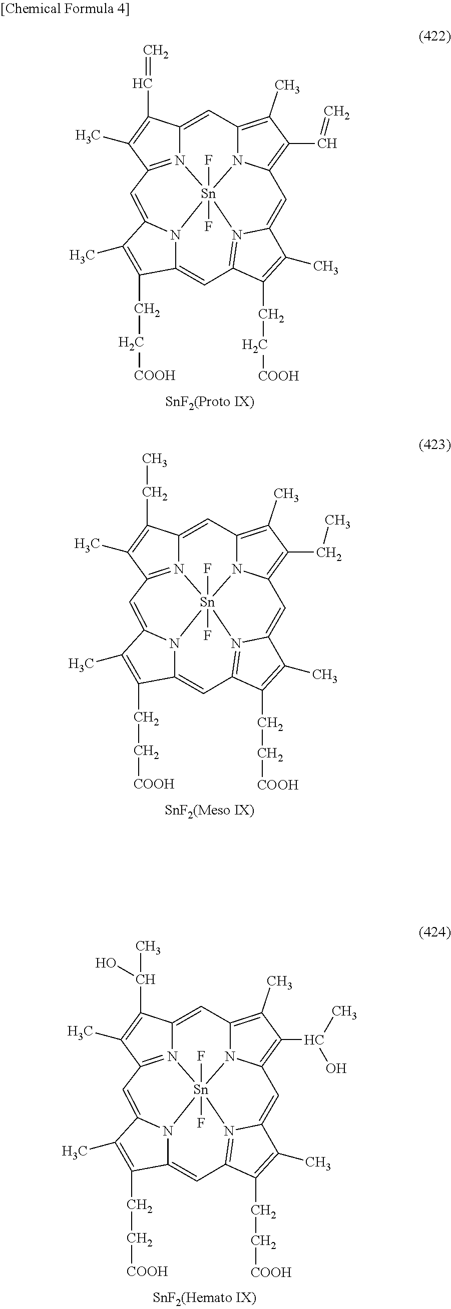

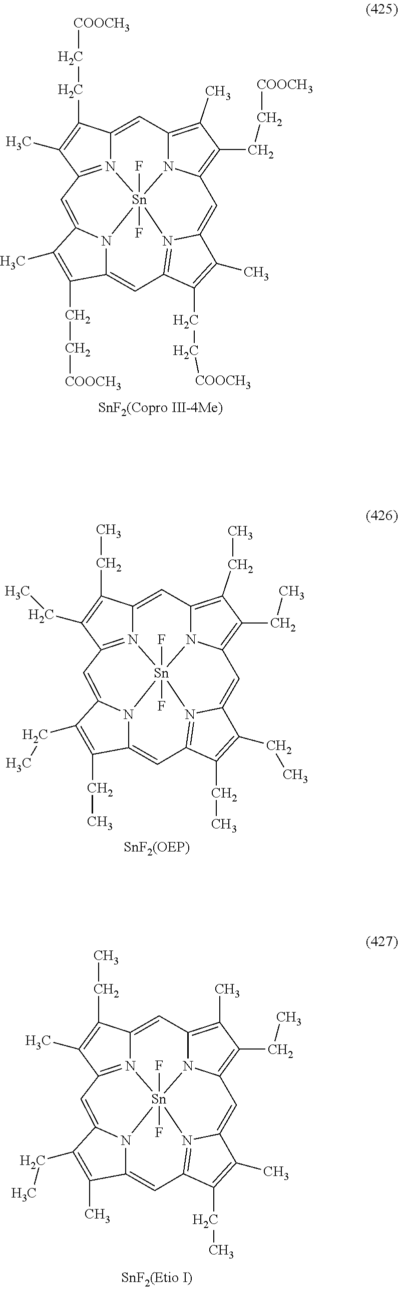

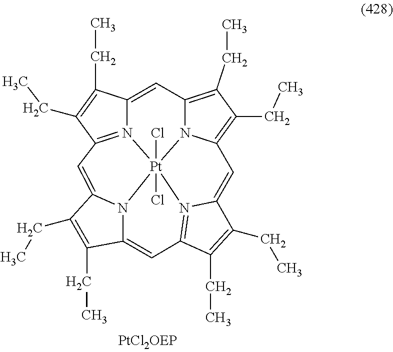

Alternatively, it is possible to use a heterocyclic compound having one or both of a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ) represented by Structural Formula (429), 9-(4,6-diphenyl-1,3,5-triazin-2-yl)-9′-phenyl-9H,9′H-3,3′-bicarbazole (abbreviation: PCCzTzn) represented by Structural Formula (430), 9-[4-(4,6-diphenyl-1,3,5-triazin-2-yl)phenyl]-9′-phenyl-3,3′-bi-9H-carbazole (abbreviation: PCCzPTzn) represented by Structural Formula (431), 2-[4-(10H-phenoxazin-10-yl)phenyl]-4,6-diphenyl-1,3,5-triazine (abbreviation: PXZ-TRZ) represented by Structural Formula (432), 3-[4-(5-phenyl-5,10-dihydrophenazin-10-yl)phenyl]-4,5-diphenyl-1,2,4-triazole (abbreviation: PPZ-3TPT) represented by Structural Formula (433), 3-(9,9-dimethyl-9H-acridin-10-yl)-9H-xanthen-9-one (abbreviation: ACRXTN) represented by Structural Formula (434), bis[4-(9,9-dimethyl-9,10-dihydroacridine)phenyl]sulfone (abbreviation: DMAC-DPS) represented by Structural Formula (435), or 10-phenyl-10H,10′H-spiro[acridin-9,9′-anthracen]-10′-one (abbreviation: ACRSA) represented by Structural Formula (436). Such a heterocyclic compound is preferable because of having high electron-transport and hole-transport properties owing to the one or both of a π-electron rich heteroaromatic ring and a π-electron deficient heteroaromatic ring. Among π-electron deficient heteroaromatic rings, a pyridine ring, a diazine ring (a pyrimidine ring, a pyrazine ring, and a pyridazine ring), and a triazine ring are preferable because of their high stability and reliability. A benzofuropyrimidine ring, a benzothienopyrimidine ring, a benzofuropyrazine ring, and a benzothienopyrazine ring have high acceptor properties and high reliability; thus, it is particularly preferable to use a compound having at least one of these rings or a compound having a fused ring including at least one of these rings. Among π-electron rich heteroaromatic rings, an acridine ring, a phenoxazine ring, a phenothiazine ring, a furan ring, a thiophene ring, and a pyrrole ring have high stability and reliability; thus, it is preferable to use a compound having at least one of these rings or a compound having a fused ring including at least one of these rings. A dibenzofuran ring is preferable as a fused ring including a furan ring, and a dibenzothiophene ring is preferable as a fused ring including a thiophene ring. As a fused ring including a pyrrole ring, an indole ring, a carbazole ring, an indolocarbazole ring, a bicarbazole ring, and a 3-(9-phenyl-9H-carbazol-3-yl)-9H-carbazole ring are particularly preferable. Note that a compound in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, a triarylamine skeleton, a phenazine skeleton, or the like can be used. As a π-electron deficient skeleton, a xanthene ring, a thioxanthene dioxide ring, an oxadiazole ring, a triazole ring, an imidazole ring, an anthraquinone ring, a skeleton including boron such as phenylborane or boranthrene, an aromatic ring to which a cyano group or a nitrile group is bonded such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

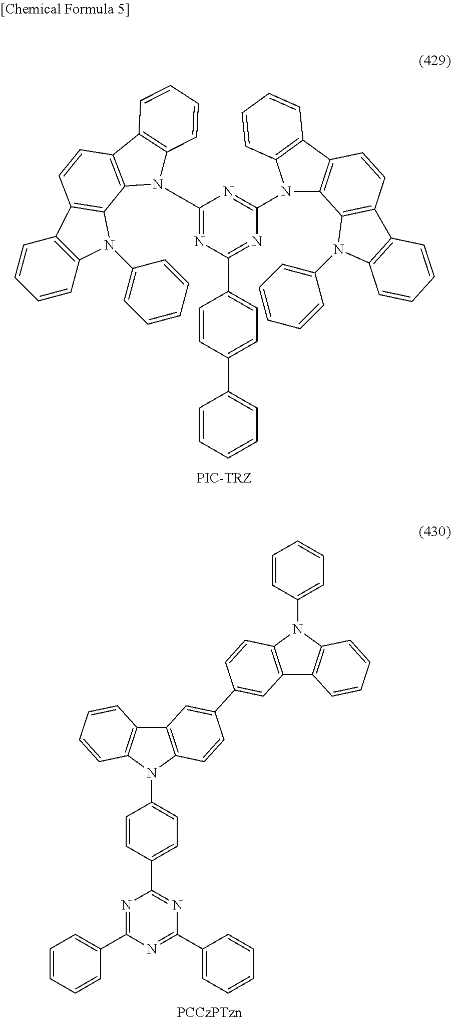 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

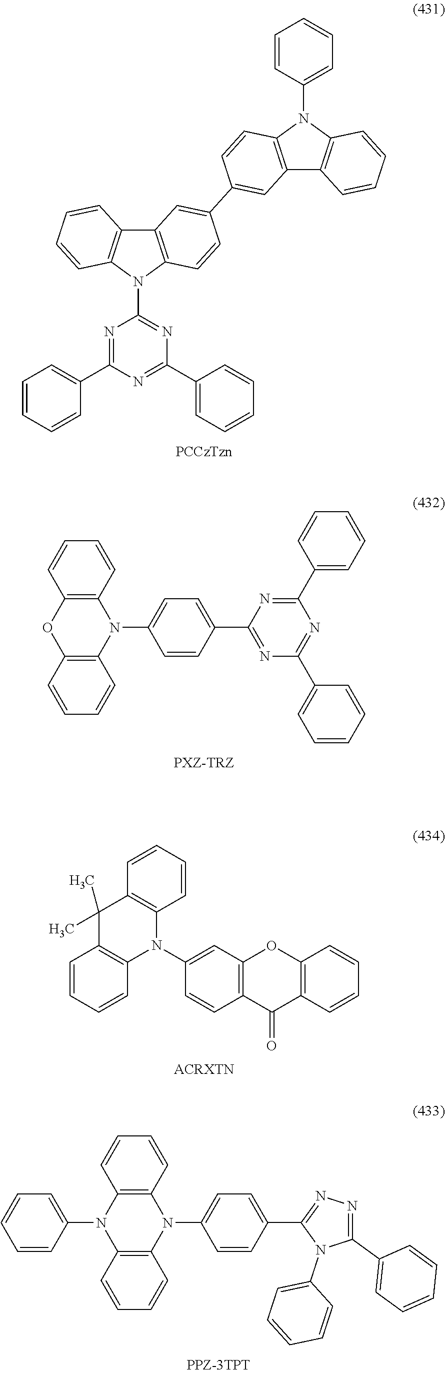 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

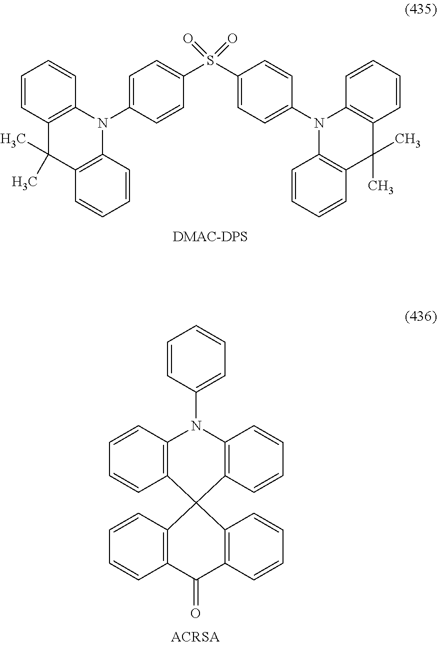 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specific examples of the TADF material include an organic compound represented by Structural Formula (437) and 3,6-bis(diphenylamino)-9-[4-(4,6-diphenyl-1,3,5-triazin-2-yl)phenyl]-9H-carbazole (abbreviation: DACT-II) represented by Structural Formula (438).

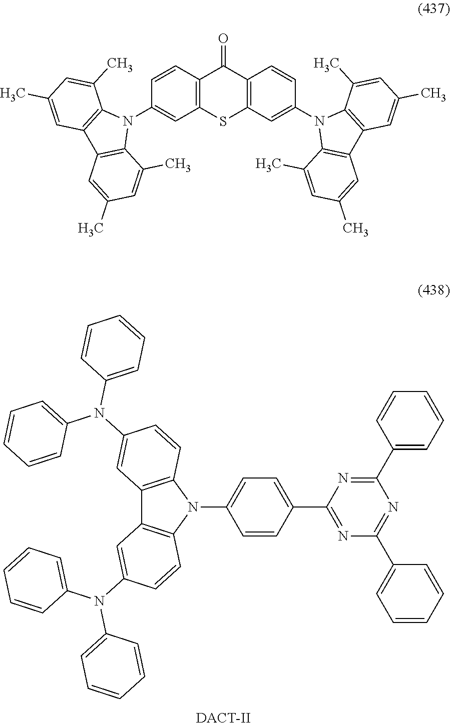

With the use of any of the above TADF materials, a light-emitting device with high emission efficiency can be provided.

Note that at least one of light-emitting layers included in the tandem light-emitting device of one embodiment of the present invention preferably contains a TADF material and at least one kind of host material. The tandem light-emitting device of one embodiment of the present invention has a structure in which energy is transferred from the at least one kind of host material to the TADF material to make the TADF material emit light.

In the at least one of the light-emitting layers included in the tandem light-emitting device of one embodiment of the present invention, a wavelength of an emission edge on a shorter wavelength side of a phosphorescence component (phosphorescence spectrum) in a PL spectrum of the host material observed at a low temperature (at any temperature in the range from 4 K to 80 K, for example) is preferably shorter than a wavelength of an emission edge on a shorter wavelength side of a phosphorescence component (phosphorescence spectrum) in a PL spectrum of the TADF material observed at a low temperature. In other words, the T₁ level of the host material is preferably higher than the T₁ level of the TADF material. Such a relation allows efficient transfer of excitation energy from the host material to the TADF material and enables the TADF material to emit light efficiently.

As described above, the TADF material enables up-conversion (reverse intersystem crossing) from a triplet excited state to a singlet excited state using a little thermal energy. Thus, in the at least one of the light-emitting layers included in the tandem light-emitting device of one embodiment of the present invention, the TADF material that receives energy from the host material and becomes a triplet excited state enables up-conversion from the triplet excited state to a singlet excited state. Accordingly, light emission (fluorescence) from the singlet excited state can be efficiently exhibited.

In the at least one of the light-emitting layers included in the tandem light-emitting device of one embodiment of the present invention, a wavelength of an emission edge on a shorter wavelength side of a fluorescence component (fluorescence spectrum) in a PL spectrum of the host material observed at room temperature is preferably shorter than a wavelength of an absorption edge on a longer wavelength side of an absorption spectrum of the TADF material measured at room temperature. Such a relation allows efficient transfer of excitation energy from the host material to the TADF material and enables the TADF material to emit light efficiently. The absorption edge on the longer wavelength side of the absorption spectrum can be determined as the intersection between a tangent and the horizontal axis (representing wavelength) or the baseline. The tangent is drawn at a point at which the slope on a longer wavelength side of the longest-wavelength peak (or the longest-wavelength shoulder peak) of the absorption spectrum has the minimum value (the maximum absolute value).

When the at least one of the light-emitting layers included in the tandem light-emitting device of one embodiment of the present invention contains a TADF material and two kinds of host materials (a first host material and a second host material), the two kinds of host materials may form an exciplex in combination. In that case, the first host material, the second host material, and the exciplex formed by the first host material and the second host material can be regarded as serving as energy donors. An exciplex is easily formed when an electron-transport material and a hole-transport material are used as the first host material and the second host material in combination. When a TADF material and an exciplex are included in the light-emitting layer, exciplex-triplet energy transfer (ExTET), which is energy transfer from the exciplex to the TADF material, can be performed efficiently, increasing emission efficiency. This structure also enables the light-emitting device to have high efficiency, low-voltage driving, and a long lifetime at the same time.

The highest occupied molecular orbital (HOMO) level of a hole-transport material is preferably higher than or equal to that of an electron-transport material so that the exciplex can be efficiently formed by the materials in combination. In addition, the lowest unoccupied molecular orbital (LUMO) level of the hole-transport material is preferably higher than or equal to that of the electron-transport material. In addition, the difference between the HOMO levels of the hole-transport material and the electron-transport material is preferably greater than or equal to 0.2 eV. In addition, the difference between the LUMO levels of the hole-transport material and the electron-transport material is preferably greater than or equal to 0.2 eV. Such a structure is suitable because it facilitates hole injection into the hole-transport material and electron injection into the electron-transport material. The LUMO levels and the HOMO levels of the materials can be derived from the electrochemical characteristics (reduction potentials and oxidation potentials) of the materials that are measured by cyclic voltammetry (CV) or derived by photoelectron spectroscopy, optical absorption spectroscopy, inverse photoelectron spectroscopy, or the like. For comparison between the values of different compounds, it is preferable to use values estimated by the same measurement.

Preferably, the HOMO level of the phosphorescent substance is lower than that of the hole-transport material and the LUMO level of the phosphorescent substance is higher than that of the electron-transport material. In other words, the energy difference between the LUMO and HOMO levels of the phosphorescent substance is preferably greater than the energy difference between the LUMO level of the electron-transport material and the HOMO level of the hole-transport material. That can inhibit the phosphorescent substance from forming an exciplex with the hole-transport material or the electron-transport material, leading to efficient light emission of the light-emitting device.

The formation of an exciplex can be confirmed by a phenomenon in which the emission spectrum of the mixed film in which the hole-transport material and the electron-transport material are mixed is shifted to a longer wavelength than the emission spectrum of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

It is preferable to use, as the host material, at least one of a compound having a π-electron deficient heteroaromatic ring and a compound having a π-electron rich heteroaromatic ring. The compound having a π-electron deficient heteroaromatic ring serves as an electron-transport material, and the compound having a π-electron rich heteroaromatic ring serves as a hole-transport material. It is further preferable to use an organic compound having no triarylamine skeleton as the host material. The organic compound having no triarylamine skeleton is preferable because the organic compound tends to have a high T₁ level, which is higher than the T₁ level of the above-described TADF material.

In this specification and the like, a triarylamine skeleton refers to a skeleton in which three aryl groups are bonded to a nitrogen atom, and the three aryl groups are not bonded to one another. Moreover, specific examples of an organic compound having a triarylamine skeleton include triphenylamine.

As the compound having a π-electron deficient heteroaromatic ring that can be used as the host material, a compound having an azine ring is preferably used. Examples of the azine ring include a pyridine ring, a pyrimidine ring, and a triazine ring. These rings can improve an electron-transport property. A compound in which a carbazole ring is directly bonded to an azine ring or bonded to an azine ring through an arylene group is preferably used, and the number of carbazole rings is preferably more than one. Such a structure having carbazole rings enables adjustment of the carrier-transport property. Furthermore, the compound having a heteroaromatic ring may include one or more kinds of elements such as silicon, boron, oxygen, and sulfur.

As the compound having a π-electron rich heteroaromatic ring that can be used as the host material, a compound having a carbazole ring is preferably used. These rings can improve a hole-transport property. The compound having a carbazole ring preferably has a plurality of carbazole rings. It is preferable to employ at least one of a structure in which the 3-position of one carbazole ring is bonded to the 9-position of another carbazole ring, a structure in which the 2-position of one carbazole ring is bonded to the 9-position of another carbazole ring, a structure in which the 4-position of one carbazole ring is bonded to the 9-position of another carbazole ring, a structure in which the 1-position of one carbazole ring is bonded to the 9-position of another carbazole ring, and a structure in which the 3-position of one carbazole ring is bonded to the 3-position of another carbazole ring. It is further preferable to employ a plurality of the above structures. Furthermore, the compound having a carbazole ring may include one or more kinds of elements such as silicon, boron, oxygen, and sulfur.

The compound having a π-electron deficient heteroaromatic ring or the compound having a π-electron rich heteroaromatic ring preferably includes a group containing silicon, such as a triphenylsilyl group, in which case an intermolecular distance can be increased and the thermal stability of the at least one of the light-emitting layers can be improved.

Specific examples of the organic compound that can be used as the host material include 9,9′-{6-[3-(triphenylsilyl)phenyl]-1,3,5-triazine-2,4-diyl}bis(9H-carbazole) (abbreviation: SiTrzCz2) represented by Structural Formula (450), 2-phenyl-4,6-bis[3-(triphenylsilyl)phenyl]-1,3,5-triazine (abbreviation: mSiTrz) represented by Structural Formula (451), 9-{4-phenyl-6-[3-(triphenylsilyl)phenyl]-1,3,5-triazin-2-yl}-9H-carbazole (abbreviation: SiCzTrz) represented by Structural Formula (452), 9-{4,6-bis[3-(triphenylsilyl)phenyl]-1,3,5-triazin-2-yl}-9H-carbazole (abbreviation: DSiCzTrz) represented by Structural Formula (453), 9-(biphenyl-4-yl)-3-(4-{[4′-(4,6-diphenyl-1,3,5-triazin-2-yl)biphenyl-4-yl]diphenylsilyl}phenyl)-9H-carbazole (abbreviation: CzSiTzn) represented by Structural Formula (454), 3-{6-[3-(4,6-diphenyl-1,3,5-triazin-2-yl)phenyl]dibenzothiophen-4-yl}-9-phenyl-9H-carbazole (abbreviation: mPCDBtPTzn) represented by Structural Formula (455), 9-[3-(triphenylsilyl)phenyl]-3,9′-bi-9H-carbazole (abbreviation: PSiCzCz) represented by Structural Formula (456), and [4-(2,12-di-tert-butyl-5,9-dioxa-13b-boranaphtho[3,2,1-de]anthracen-7-yl)phenyl]triphenylsilane (abbreviation: TDBA-Si) represented by Structural Formula (457). Alternatively, any of organic compounds represented by Structural Formulae (458), (459), and (460) can be used. The organic compound represented by any of Structural Formulae (450) to (460) can be used as a host material of a light-emitting layer of a blue-light-emitting device, for example.

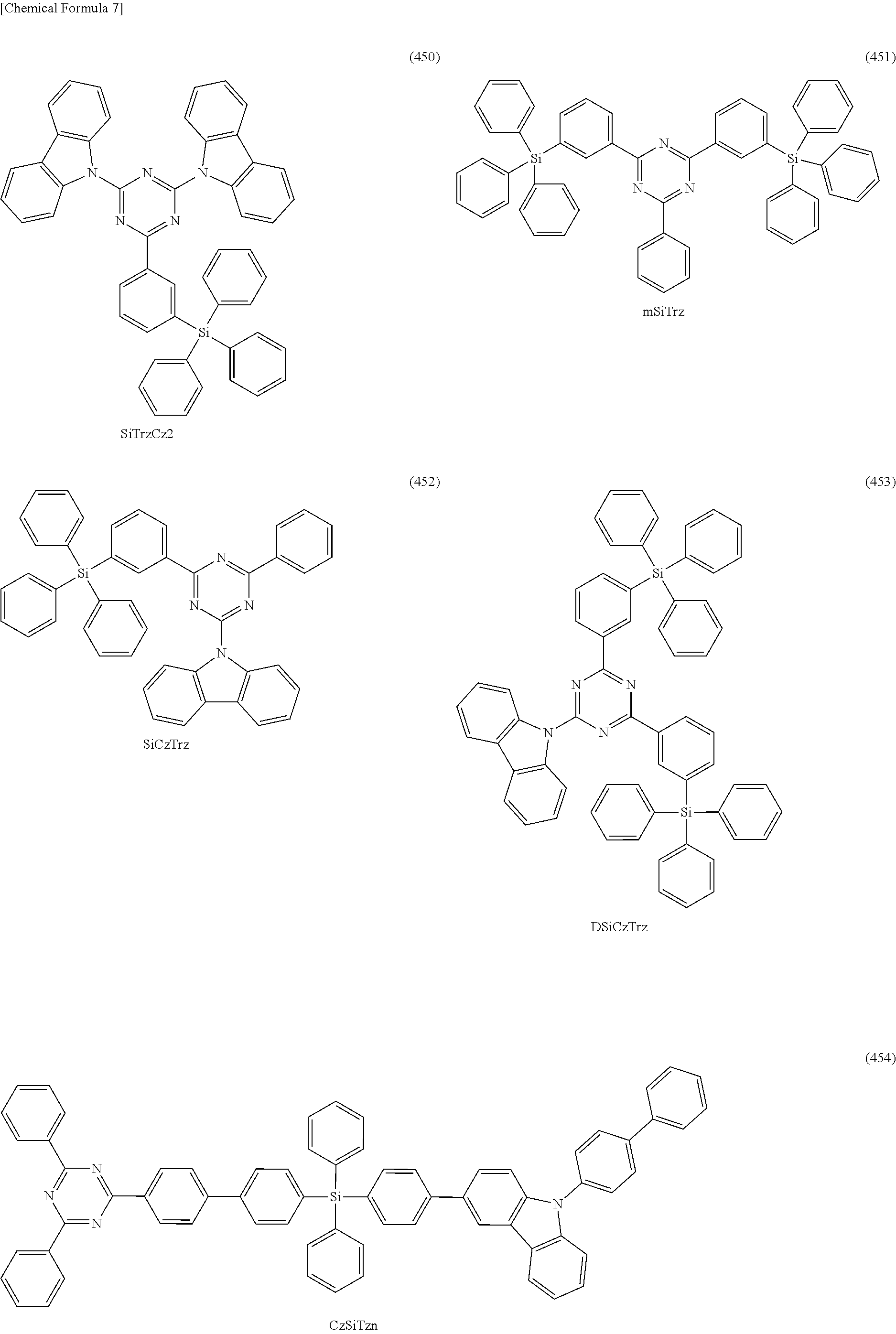

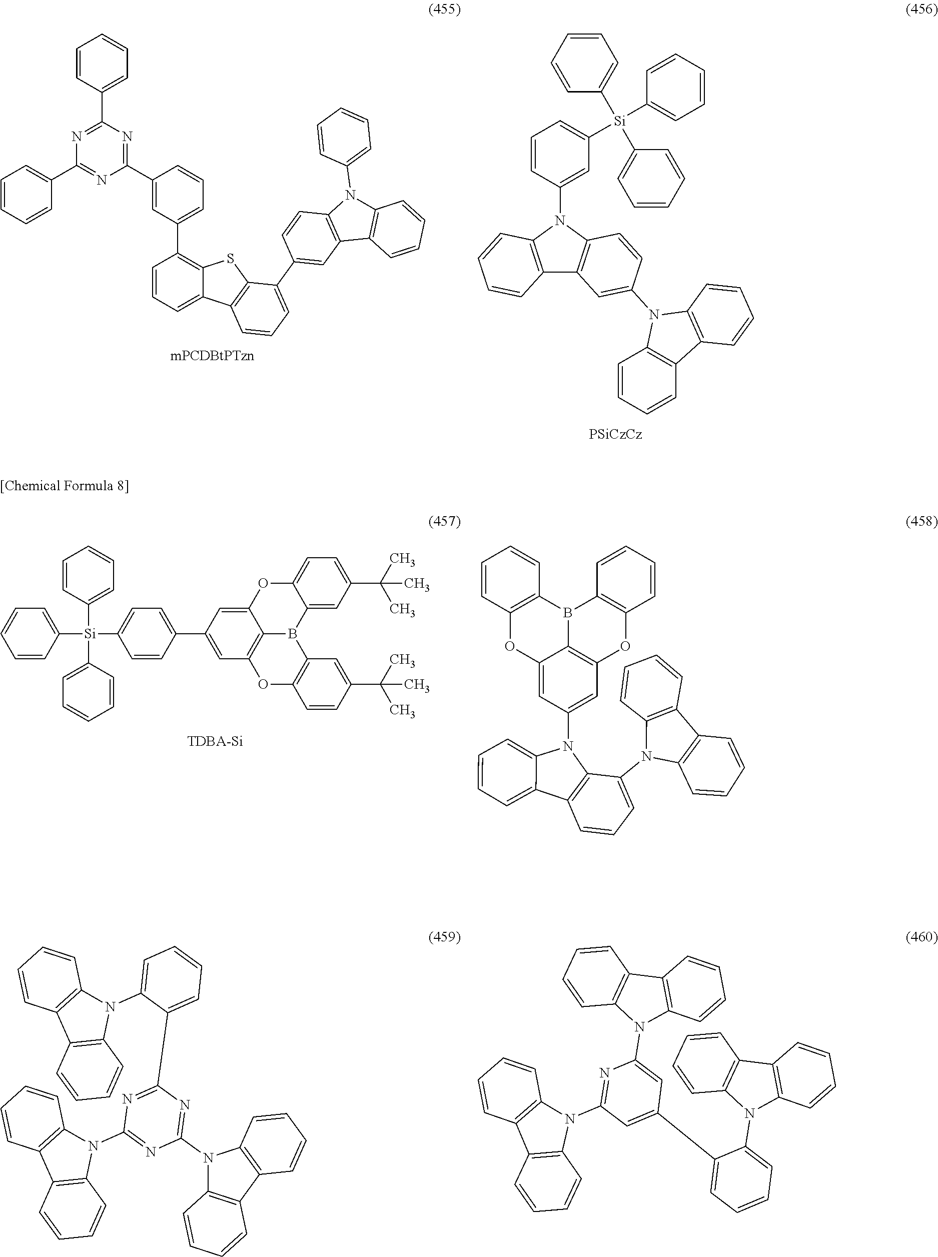

Specific examples of the organic compound that can be used as the host material also include 4,6-bis[3-(9H-carbazol-9-yl)phenyl]pyrimidine (abbreviation: 4,6mCzP2Pm) represented by Structural Formula (461), 4-(9′-phenyl-[3,3′-bi-9H-carbazol]-9-yl)benzofuro[3,2-d]pyrimidine (abbreviation: 4PCCzBfpm) represented by Structural Formula (462), 9-(4,6-diphenylpirimidin-2-yl)-9′-phenyl-2,3′-bi-9H-carbazole (abbreviation: 2PCCzPm) represented by Structural Formula (463), and 9-[3-(4,6-diphenyl-1,3,5-triazin-2-yl)phenyl]-9′-phenyl-3,3′-bi-9H-carbazole (abbreviation: mPCCzPTzn) represented by Structural Formula (464). The organic compound represented by any of Structural Formulae (461) to (464) can be used as a host material of a light-emitting layer of a green-light-emitting device, for example.

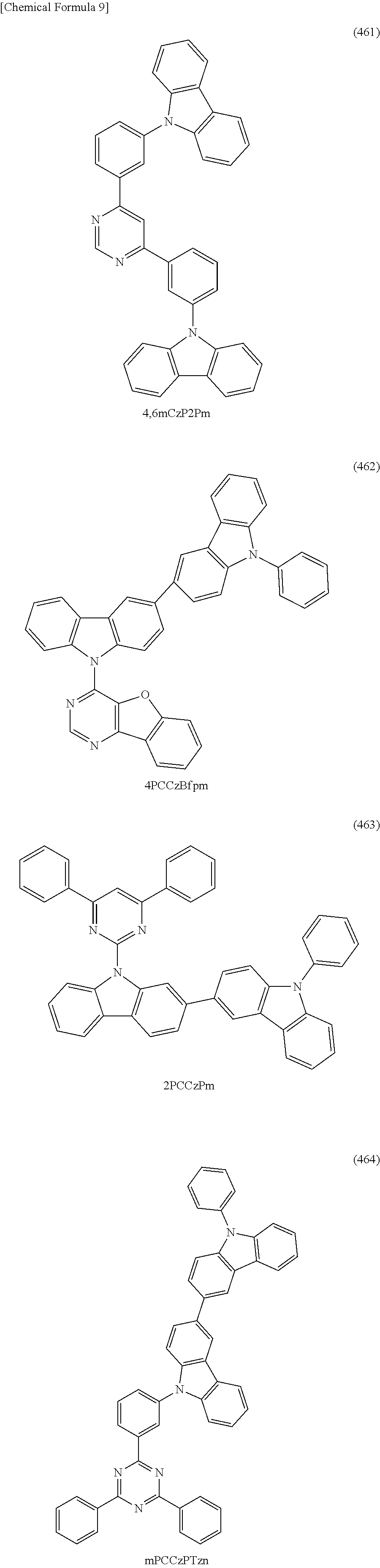 [SMILES: c1cc(-c2cc(-c3cccc(-n4c5ccccc5c5ccccc54)c3)ncn2)cc(-n2c3ccccc3c3ccccc32)c1 ; c1ccc(-n2c3ccccc3c3cc(-c4ccc5c(c4)c4ccccc4n5-c4ncnc5c4oc4ccccc45)ccc32)cc1 ; c1ccc(-c2cc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

Specific examples of the organic compound that can be used as the host material also include organic compounds each having a heteroaromatic ring including a diazine ring, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophene-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), 8-([2,2′-binaphthalen]-6-yl)-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), and 8-(p-terphenyl-3-yl)-4-[3-(dibenzothiophen-4-yl)phenyl]-[1]benzofuro[3,2-d]pyrimidine (abbreviation: 8mpTP-4mDBtPBfpm).

Note that in this specification and the like, a “heteroaromatic ring including an A ring” can mean an A ring or a fused ring including an A ring. An “A ring” refers to a heteroaromatic ring. In the case where an A ring is a diazine ring, a “heteroaromatic ring including a diazine ring” can mean a diazine ring or a fused ring including a diazine ring.

Specific examples of the organic compound that can be used as the host material also include PIC-TRZ, PCCzTzn, PCCzPTzn, PXZ-TRZ, PPZ-3TPT, ACRXTN, DMAC-DPS, and ACRSA, which are given above as examples of the TADF material.

With the use of the above host materials in combination with a phosphorescent substance, a light-emitting device with high emission efficiency can be provided.

The first light-emitting unit 501 and the second light-emitting unit 502 may each include another functional layer in addition to the above-described light-emitting layer. In the structure illustrated in FIG. 1A, the first light-emitting unit 501 includes a first hole-transport layer 112_1, a hole-injection layer 111, and a first electron-transport layer 114_1 in addition to the first light-emitting layer 113_1, and the second light-emitting unit 502 includes a second hole-transport layer 112_2, a second electron-transport layer 114_2, and an electron-injection layer 115 in addition to the second light-emitting layer 113_2. However, the structure of the organic compound layer 103 in one embodiment of the present invention is not limited thereto and any of the layers may be omitted or other layers may be added.

### <Hole-Transport Layer>

Although being a single layer in FIG. 1A, each of the first hole-transport layer 112_1 and the second hole-transport layer 112_2 may be a single layer or have a stacked-layer structure. The first hole-transport layer 112_1 and the second hole-transport layer 112_2 do not necessarily have same structure. For example, a structure in which the first hole-transport layer 112_1 is a single layer and the second hole-transport layer 112_2 has a stacked-layer structure may be employed.

In one embodiment of the present invention, each of the first hole-transport layer 112_1 and the second hole-transport layer 112_2 is preferably formed using a material having an excellent hole-transport property, a low electron-transport property, and a T₁ level higher than that of a TADF material used for the corresponding light-emitting layer. It is particularly preferable to use, for a layer in contact with the first light-emitting layer 1131 in the first hole-transport layer 112_1, a material having a higher T₁ level than the TADF material used for the first light-emitting layer 113_1, and to use, for a layer in contact with the second light-emitting layer 1132 in the second hole-transport layer 112_2, a material having a higher T₁ level than the TADF material used for the second light-emitting layer 113_2. In that case, excitation energy of excitons, which are generated by recombination of carriers in the light-emitting layers, can be prevented from diffusing into the layers in contact with the light-emitting layers; consequently, the light-emitting device can have high emission efficiency. An organic compound having a π-electron rich heteroaromatic ring such as a carbazole ring and having no triarylamine skeleton has an excellent hole-transport property and a high T₁ level in many cases and thus is suitable for the first hole-transport layer 112_1 and the second hole-transport layer 112_2.

When the first hole-transport layer 112_1 has a stacked-layer structure and the layer in contact with the first light-emitting layer 113_1 includes a material whose LUMO level is higher than that of the material included in the first light-emitting layer 113_1, electrons can be prevented from passing the first light-emitting layer 113_1 to the first electrode 101 side. Similarly, when the second hole-transport layer 112_2 has a stacked-layer structure and the layer in contact with the second light-emitting layer 113_2 includes a material whose LUMO level is higher than that of the material included in the second light-emitting layer 113_2, electrons can be prevented from passing the second light-emitting layer 113_2 to the intermediate layer 160. As a result, a display apparatus with high efficiency and a long lifetime can be obtained.

Specific examples of an organic compound that can be used for the layer that is included in the first hole-transport layer 112_1 or the second hole-transport layer 112_2 and in contact with the corresponding light-emitting layer include 9-[3-(triphenylsilyl)phenyl]-3,9′-bi-9H-carbazole (abbreviation: PSiCzCz) represented by Structural Formula (350), 9′-[3-(triphenylsilyl)phenyl]-9′H-9,3′:6′,9″-tercarbazole (abbreviation: PSiCzGI) represented by Structural Formula (351), 9,9″-(1,3-phenylene)bis(3,9′-bi-9H-carbazole) (abbreviation: mCzCz2P) represented by Structural Formula (352), 1,3-bis(N-carbazolyl)benzene (abbreviation: mCP) represented by Structural Formula (353), 9,9″-[3,3′-(diphenylsilyl)diphenyl]bis(3,9′-bi-9H-carbazole) (abbreviation: mCzCz2PSi) represented by Structural Formula (354), 3,3′-9H-carbazol-9-yl-biphenyl (abbreviation: mCBP) represented by Structural Formula (359), 9′-phenyl-9′H-9,3′:6′,9″-tercarbazole (abbreviation: PhCzGI) represented by Structural Formula (360), 12-[3-(9H-carbazol-9-yl)phenyl]-5,12-dihydro-5-phenyl-indolo[3,2-a]carbazole (abbreviation: mCzPICz) represented by Structural Formula (361), 5,12-bis[3-(9H-carbazol-9-yl)phenyl]-5,12-dihydro-indolo[3,2-a]carbazole (abbreviation: mCzP2ICz) represented by Structural Formula (362), 5-[3-(9H-carbazol-9-yl)phenyl]-5,12-dihydro-12-phenyl-indolo[3,2-a]carbazole (abbreviation: mCzPICz-02) represented by Structural Formula (363), 12,12′-(1,4-phenylene)bis(5,12-dihydro-5-phenyl-indolo[3,2-a]carbazole) (abbreviation: ICz2P) represented by Structural Formula (364), 12,12′-(1,3-phenylene)bis(5,12-dihydro-5-phenyl-indolo[3,2-a]carbazole) (abbreviation: mICz2P) represented by Structural Formula (365), and 5,5′-(1,3-phenylene)bis(5,12-dihydro-12-phenyl-indolo[3,2-a]carbazole) (abbreviation: mICz2P-02) represented by Structural Formula (366). Other examples include organic compounds represented by Structural Formulae (355) to (358). The organic compound represented by any of Structural Formulae (350) to (366) can be used for the layer that is included in the first hole-transport layer 112_1 or the second hole-transport layer 112_2 and in contact with the light-emitting layer in the case of a blue-light-emitting device, for example. The organic compound represented by any of Structural Formulae (350) to (366) can be used as the host material of the light-emitting layer of a blue-light-emitting device, for example.

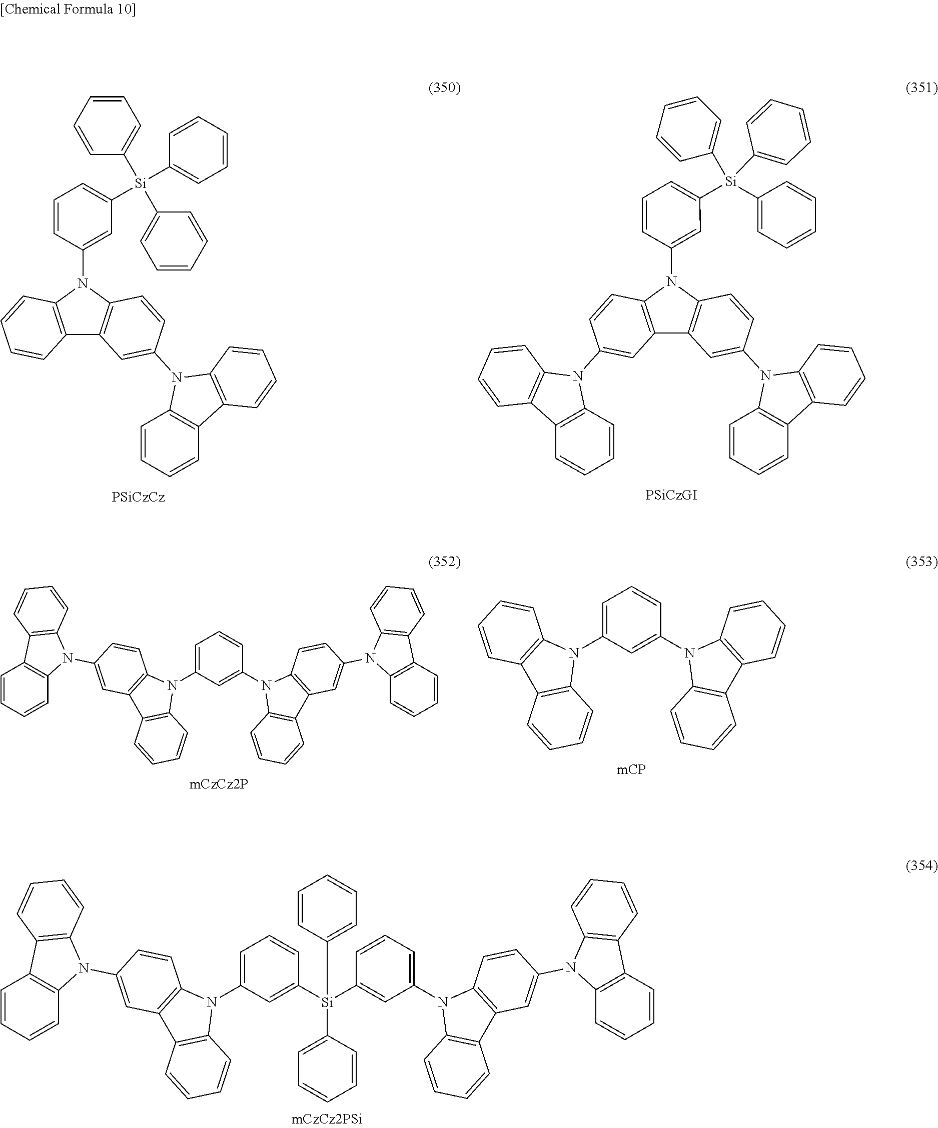 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-n3c4ccc(-n5c6ccccc6c6ccccc65)cc4c4cc(-n5c6ccccc6c6ccccc65)ccc43)c2)cc1 ; c1cc(-n2c3ccccc3c3cc(-n4c5ccccc5c5ccccc54)ccc32)cc(-n2c3ccccc3c3cc(-n4c5ccccc5c5ccccc54)ccc32)c1 ; c1cc(-n2c3ccccc3c3ccccc32)cc(-n2c3ccccc3c3ccccc32)c1 ; c1ccc([Si](c2ccccc2)(c2cccc(-n3c4ccccc4c4cc(-n5c6ccccc6c6ccccc65)ccc43)c2)c2cccc(-n3c4ccccc4c4cc(-n5c6ccccc6c6ccccc65)ccc43)c2)cc1]

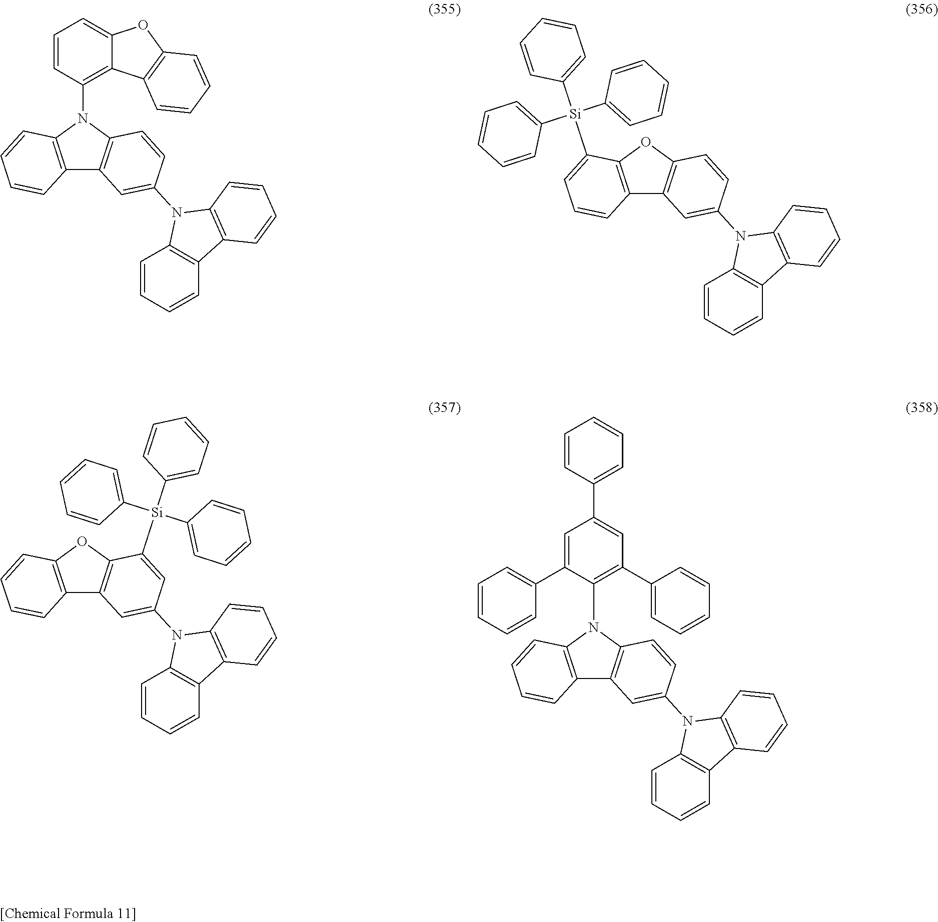 [SMILES: c1ccc2c(c1)oc1cccc(-n3c4ccccc4c4cc(-n5c6ccccc6c6ccccc65)ccc43)c12 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2cc(-c3ccccc3)c(-n3c4ccccc4c4cc(-n5c6ccccc6c6ccccc65)ccc43)c(-c3ccccc3)c2)cc1]

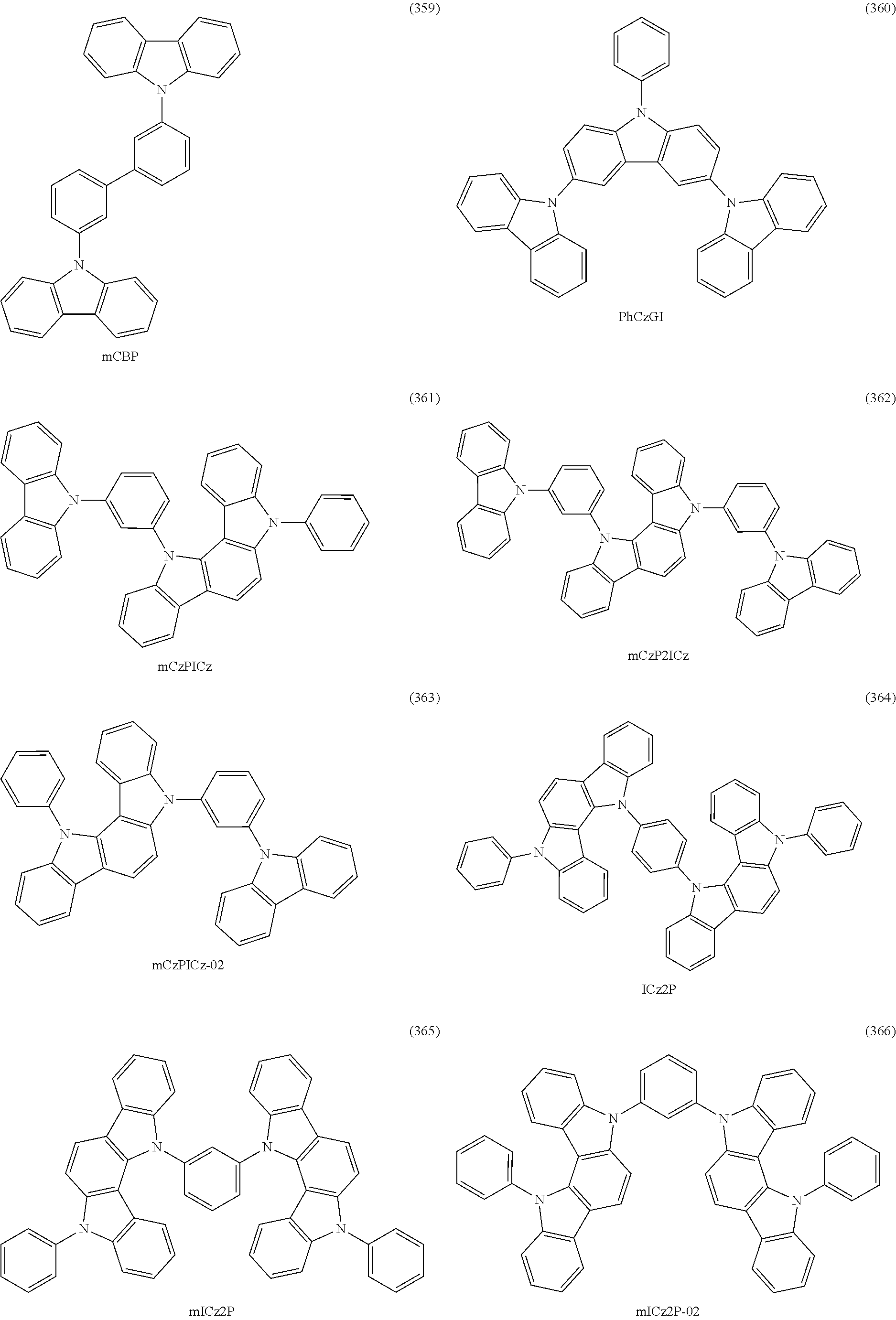

Other specific examples of the organic compound that can be used for the layer that is included in the first hole-transport layer 112_1 or the second hole-transport layer 112_2 and in contact with the corresponding light-emitting layer include 9,9′-diphenyl-9H,9′H-3,3′-bicarbazole (abbreviation: PCCP) represented by Structural Formula (367), 9-(2-naphthyl)-9′-phenyl-3,3′-bi-9H-carbazole (abbreviation: βNCCP) represented by Structural Formula (368), 9-(biphenyl-3-yl)-9′-(biphenyl-4-yl)-9H,9′H-3,3′-bicarbazole (abbreviation: mBPCCBP) represented by Structural Formula (369), 9-(biphenyl-4-yl)-9′-phenyl-3,3′-bi-9H-carbazole (abbreviation: PCCzBP) represented by Structural Formula (370), 9-phenyl-9′-(triphenylen-2-yl)-9H,9′H-3,3′-bicarbazole (abbreviation: PCCzTp) represented by Structural Formula (371), 3,9-bis(9-phenyl-9H-carbazol-3-yl)-9H-carbazole (abbreviation: PCCzPC) represented by Structural Formula (372), PCCzPC-02 represented by Structural Formula (373), 9,9′-bis(biphenyl-4-yl)-3,3′-bi-9H-carbazole (abbreviation: BisBPCz) represented by Structural Formula (374), 9-[(4-phenyl)dibenzothiophen-2-yl]-9′-phenyl-3,3′-bi-9H-carbazole (abbreviation: PDBtCPC) represented by Structural Formula (375), 5,9-bis(biphenyl-3-yl)-7,9-dihydro-7,7-dimethyl-5H-cyclopenta[1,2-b:4,3-b′]dicarbazole (abbreviation: mBPCdcz) represented by Structural Formula (376), 9-(4-biphenyl)-9′-(2-naphthyl)-3,3′-bi-9H-carbazole (abbreviation: βNCCBP) represented by Structural Formula (377), 9-(9,9-dimethyl-9H-fluoren-2-yl)-9′-phenyl-3,3′-bi-9H-carbazole (abbreviation: PCCzF) represented by Structural Formula (378), 9,9′-di(2-naphthyl)-9H,9′H-3,3′-bicarbazole (abbreviation: BisβNCz) represented by Structural Formula (379), 9-(biphenyl-3-yl)-9′-phenyl-3,3′-bi(9H-carbazole) (abbreviation: PCCzmBP) represented by Structural Formula (380), and BisDBtCz represented by Structural Formula (381). The organic compound represented by any of Structural Formulae (367) to (381) can be used for the layer that is included in the first hole-transport layer 112_1 or the second hole-transport layer 112_2 and in contact with the light-emitting layer in the case of a green-light-emitting device, for example. The organic compound represented by any of Structural Formulae (367) to (381) can be used as the host material of the light-emitting layer of a green-light-emitting device, for example.

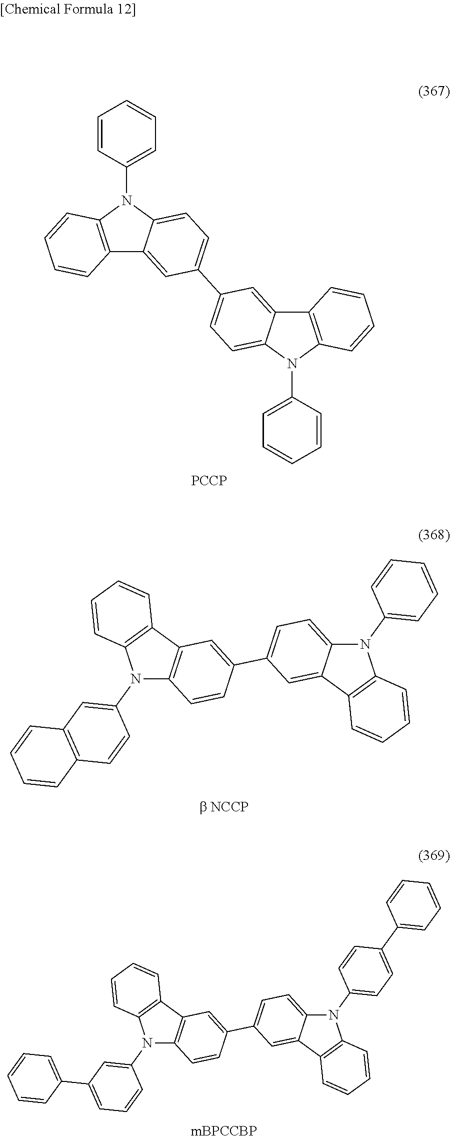 [SMILES: c1ccc(-n2c3ccccc3c3cc(-c4ccc5c(c4)c4ccccc4n5-c4ccccc4)ccc32)cc1 ; "PCCP" ; c1ccc(-n2c3ccccc3c3cc(-c4ccc5c(c4)c4ccccc4n5-c4ccc5ccccc5c4)ccc32)cc1 ; c1ccc(-c2ccc(-n3c4ccccc4c4cc(-c5ccc6c(c5)c5ccccc5n6-c5cccc(-c6ccccc6)c5)ccc43)cc2)cc1]

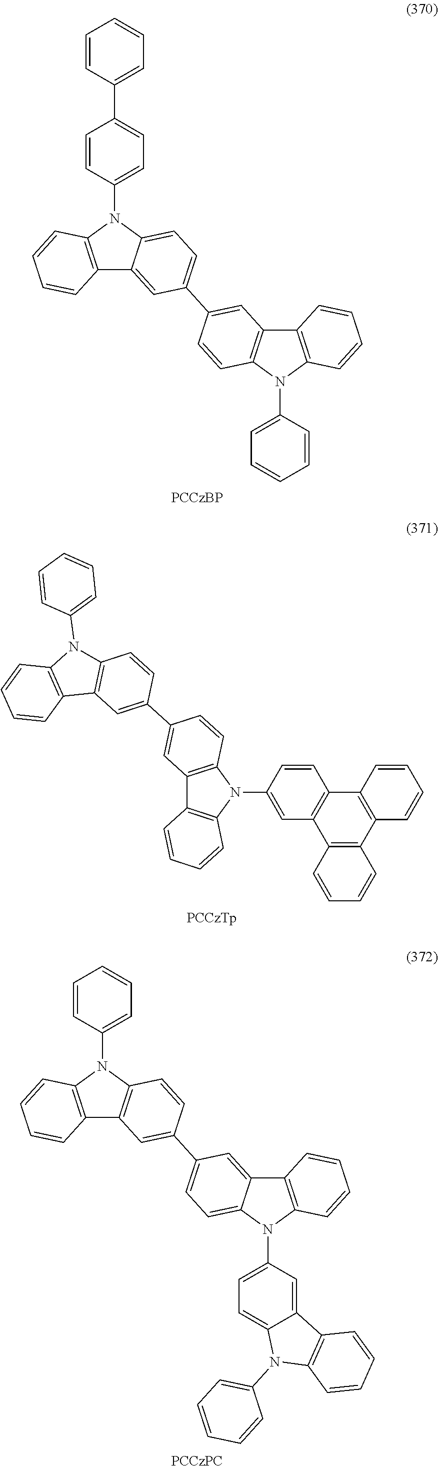

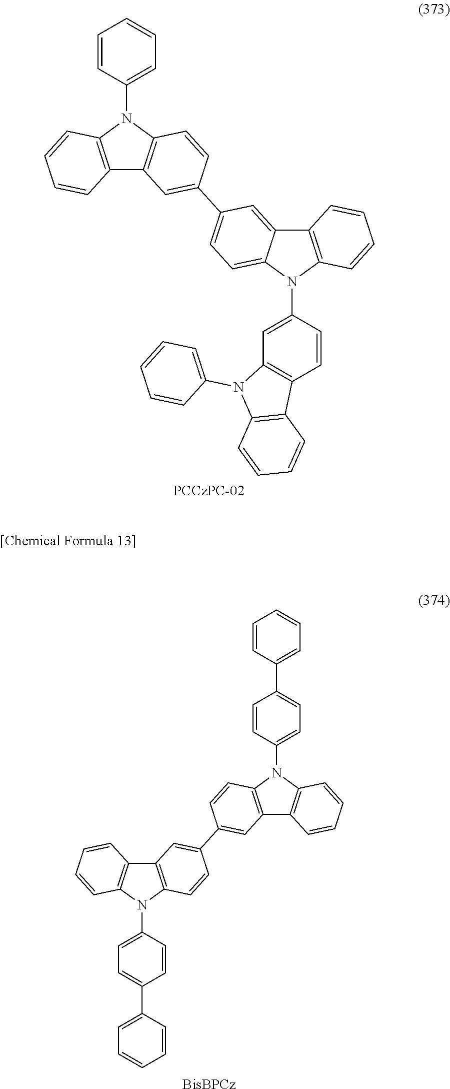

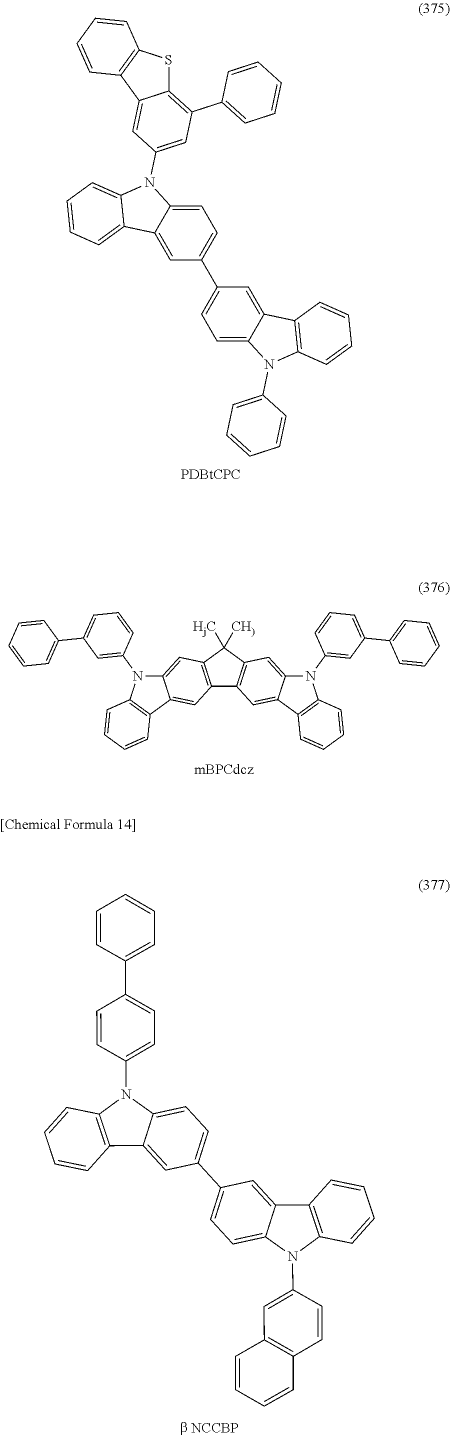

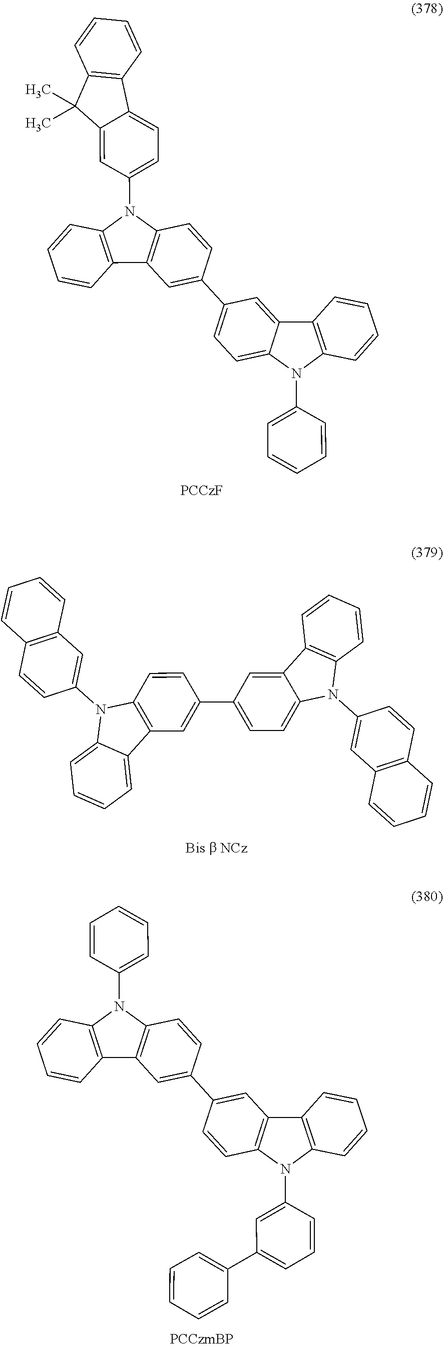 [SMILES: CC1(C)c2ccccc2-c2ccc(-n3c4ccccc4c4cc(-c5ccc6c(c5)c5ccccc5n6-c5ccccc5)ccc43)cc21 ; c1ccc2cc(-n3c4ccccc4c4cc(-c5ccc6c(c5)c5ccccc5n6-c5ccc6ccccc6c5)ccc43)ccc2c1 ; c1ccc(-c2cccc(-n3c4ccccc4c4cc(-c5ccc6c(c5)c5ccccc5n6-c5ccccc5)ccc43)c2)cc1]

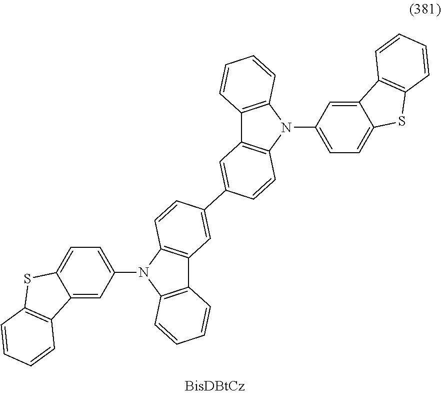 [SMILES: c1ccc2c(c1)sc1ccc(-n3c4ccccc4c4cc(-c5ccc6c(c5)c5ccccc5n6-c5ccc6sc7ccccc7c6c5)ccc43)cc12]

It is preferable to use an organic compound having a triarylamine skeleton for a layer that is included in the first hole-transport layer 112_1 or the second hole-transport layer 112_2 and is not in contact with the corresponding light-emitting layer. Examples of an aromatic ring included in the organic compound having a triarylamine skeleton include a monocyclic aromatic ring and a polycyclic aromatic ring; the polycyclic aromatic ring is particularly preferable because of its high heat resistance and stability. An organic compound having a triarylamine skeleton and a fluorene ring is preferable because of its high reliability and high hole-transport property, leading to low power consumption. These aromatic rings may have an alkyl group as a substituent.

Examples of the monocyclic aromatic ring include aromatic hydrocarbon rings such as a benzene ring and heteroaromatic rings such as a pyrrole ring and a furan ring. Having the aromatic ring as a substituent has the effect of improving heat resistance, specifically, a glass transition temperature (T_{g}). Having the aromatic ring as a substituent also has the effect of adjusting the transport property of carriers such as holes or electrons, for example. Furthermore, having a plurality of such monocyclic aromatic rings can further improve T_{g}; a biphenyl structure or a terphenyl structure is preferably used, for example. A paraphenylene structure, a metaphenylene structure, or an orthophenylene structure may be used. When at least one of a metaphenylene structure and an orthophenylene structure is used, the solubility of a compound can be improved to facilitate manufacturing the compound and a reduction in refractive index can also be achieved. When a terphenyl structure or the like having three or more benzene rings is used, it is preferable to use an aromatic ring having at least two selected from a paraphenylene structure, a metaphenylene structure, and an orthophenylene structure, which enables adjustment of the solubility, the refractive index, and the carrier-transport property.

Examples of the polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, and a xanthene ring. A compound having the polycyclic aromatic ring as a substituent can improve heat resistance more than a compound having the monocyclic aromatic ring and is thus preferable. A plurality of polycyclic aromatic rings are preferably included. The plurality of polycyclic aromatic rings included may be the same as or different from each other. In the case of the same rings, a structure including a plurality of aromatic hydrocarbon rings, a structure including a plurality of heteroaromatic rings, a structure including one or more aromatic hydrocarbon rings and one or more heteroaromatic rings, or the like can be given. In the case of the same aromatic rings, a reduction in raw material cost and simplification of the synthesis process can be expected. In the case of using different aromatic rings, the transport property of carriers such as holes or electrons can be adjusted or T_{g} can be adjusted depending on the kinds of the aromatic rings used. Examples of the case of using a plurality of polycyclic aromatic rings include a structure including a carbazole ring and a dibenzofuran ring, a structure including two, three, or four or more carbazole rings, and a structure including two, three, or four or more fluorene rings.

A compound having as a substituent a ring in which an aromatic ring (e.g., the above-described monocyclic aromatic ring) is further fused to any of the above polycyclic aromatic rings can further improve heat resistance. Examples of the ring in which an aromatic ring is further fused to the polycyclic aromatic ring include a benzofluorene ring, a benzonaphthofuran ring, a benzoxanthene ring, and a benzonaphthothiophene ring.

As the substituent, the monocyclic aromatic ring and the polycyclic aromatic ring can be used. For example, a structure in which a monocyclic aromatic ring is used as a linking group between nitrogen in an amine skeleton and the polycyclic aromatic ring can be given. Other examples include a structure in which a phenylene group is used between nitrogen and a fluorene ring, a structure in which a phenylene group is used between nitrogen and a carbazole ring, and a structure in which a phenylene group is used between nitrogen and a dibenzofluorene ring. A structure in which a plurality of polycyclic aromatic rings are bonded to one phenylene group used as a linking group is also effective. The plurality of polycyclic aromatic rings may be the same or different aromatic rings. For example, a compound in which both a carbazole ring and a dibenzofluorene ring are bonded to one phenylene group can have improved T_{g} as well as both functions of the carbazole ring and the dibenzofluorene ring.

Examples of the alkyl group include a methyl group, an ethyl group, a propyl group, a tertiary butyl group, a cyclohexyl group, and an adamantyl group. A layer including a compound having the alkyl group as a substituent can have a low refractive index. This can inhibit total reflection at the interface between the layer and another layer and improve the light extraction efficiency of the light-emitting device including the layer. When such a compound having an alkyl group is used also for the hole-transport layer, the refractive index of the hole-transport layer can be lowered. In particular, when a compound having a triarylamine skeleton and an alkyl group is used for the hole-transport layer, the effect of improving the light extraction efficiency can be synergistically enhanced. A compound having an alkyl group having a plurality of carbon atoms, preferably three or more carbon atoms, further preferably four or more carbon atoms, still further preferably five or more carbon atoms, can enhance the effect of lowering the refractive index. Moreover, a plurality of alkyl groups are preferably bonded to one aromatic ring, in which case the refractive index can be further reduced. In that case, the plurality of alkyl groups may be the same as or different from each other. For example, two or three tertiary butyl groups are preferably bonded to one benzene ring. In the case where a plurality of aromatic rings are included, bonding alkyl groups to two or more aromatic rings enables a reduction in refractive index. In addition, including alkyl groups in some of a plurality of aromatic rings enables adjustment of the refractive index. An example is a structure in which two out of three aromatic rings each include an alkyl group and the remaining one aromatic ring includes no alkyl group.

Structural Formulae (300) to (330) represent examples of the organic compound having a triarylamine skeleton. Specifically, the following organic compounds are preferable: BBASF(4) represented by Structural Formula (300); oBBASF represented by Structural Formula (301); BBAFLP(4) represented by Structural Formula (302); oFBiSF(2) represented by Structural Formula (303); FBiSF(4) represented by Structural Formula (304); oFBiSF represented by Structural Formula (305); FBimFLP represented by Structural Formula (306); FBimMemFLP represented by Structural Formula (307); SF(4)FAF represented by Structural Formula (308); FrBBiFLP represented by Structural Formula (309); tBu-oFBiSF(2) represented by Structural Formula (310); FBiFLPB represented by Structural Formula (311); DBfBBFLP(2) represented by Structural Formula (312); FLP2oBP represented by Structural Formula (313); PCAFLP(2)-02 represented by Structural Formula (314); tBu2FoFBi represented by Structural Formula (315); oFrTPPnox represented by Structural Formula (316); mPDBfBNBN represented by Structural Formula (317); BBAaBnf(7) represented by Structural Formula (318); DBfBB1TP represented by Structural Formula (319); BOx3Am represented by Structural Formula (320); BBA2BP represented by Structural Formula (321); PCBBi1BP represented by Structural Formula (322); YGBBi1BP-02 represented by Structural Formula (323); YGBBi1BP represented by Structural Formula (324); PCBBi1TP represented by Structural Formula (325); YGBBiPDBf represented by Structural Formula (326); BPPCA represented by Structural Formula (327); PCBBiF represented by Structural Formula (328); DBf-YGBBi1BP represented by Structural Formula (329); and YGTPDBfB represented by Structural Formula (330).

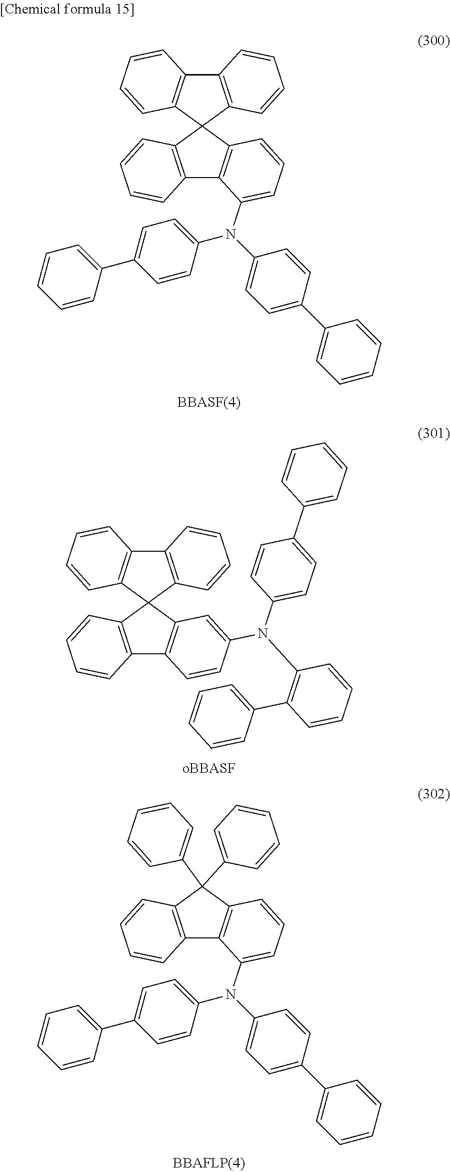 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(N(c3ccc(-c4ccccc4)cc3)c3cccc4c3-c3ccccc3C4(c3ccccc3)c3ccccc3)cc2)cc1]

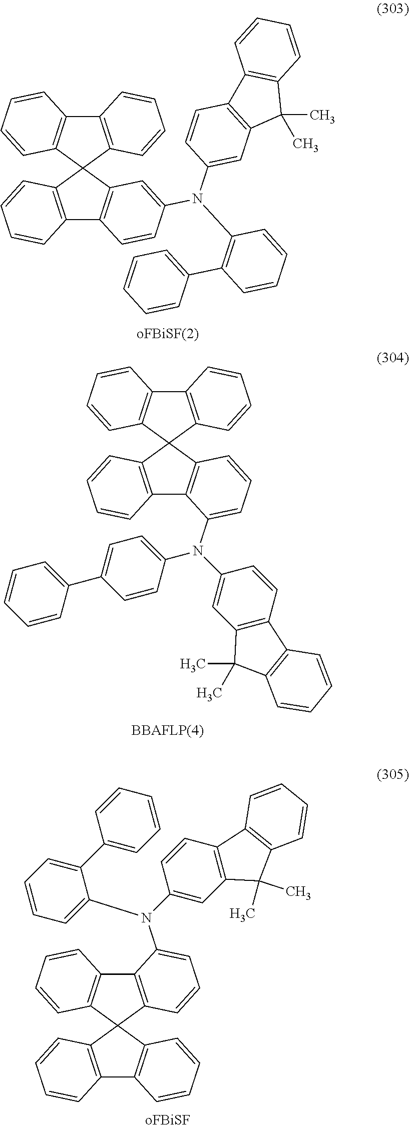 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccccc3-c3ccccc3)c3cccc4c3-c3ccccc3C43c4ccccc4-c4ccccc43)cc21]

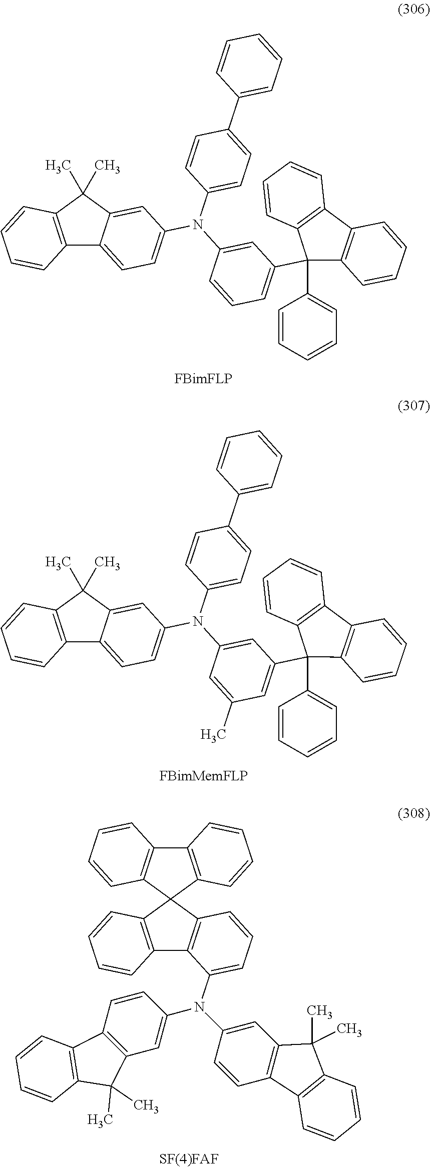 [SMILES: CC1(C)c2ccccc2-c2ccc(N(c3ccc(-c4ccccc4)cc3)c3cccc(C4(c5ccccc5)c5ccccc5-c5ccccc54)c3)cc21 ; Cc1cc(N(c2ccc(-c3ccccc3)cc2)c2ccc3c(c2)C(C)(C)c2ccccc2-3)cc(C2(c3ccccc3)c3ccccc3-c3ccccc32)c1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

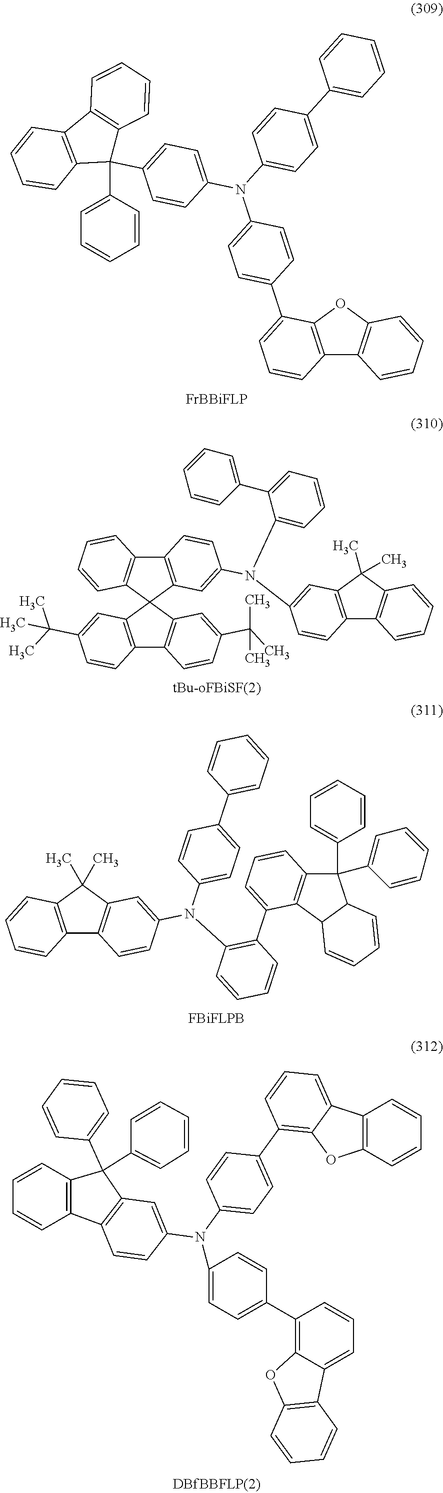 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc(-c4ccccc4)cc3)c3ccccc3-c3cccc4c3C3C=CC=CC3C4(c3ccccc3)c3ccccc3)cc21 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1]

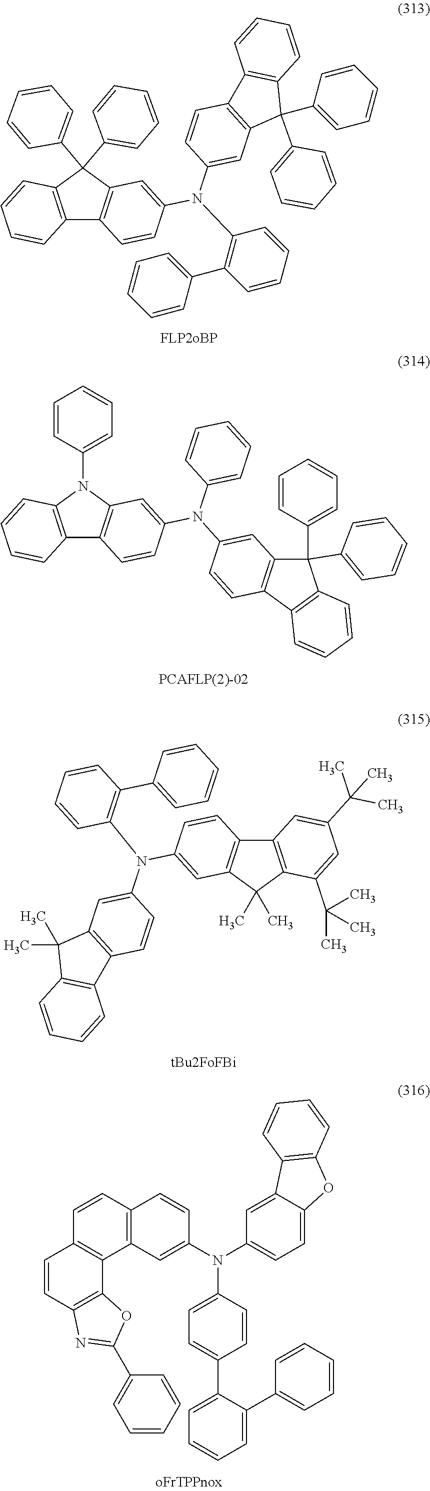 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(N(c2ccc3c(c2)C(c2ccccc2)(c2ccccc2)c2ccccc2-3)c2ccc3c4ccccc4n(-c4ccccc4)c3c2)cc1 ; CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2 ; c1ccc(-c2nc3ccc4ccc5ccc(N(c6ccc(-c7ccccc7-c7ccccc7)cc6)c6ccc7oc8ccccc8c7c6)cc5c4c3o2)cc1]

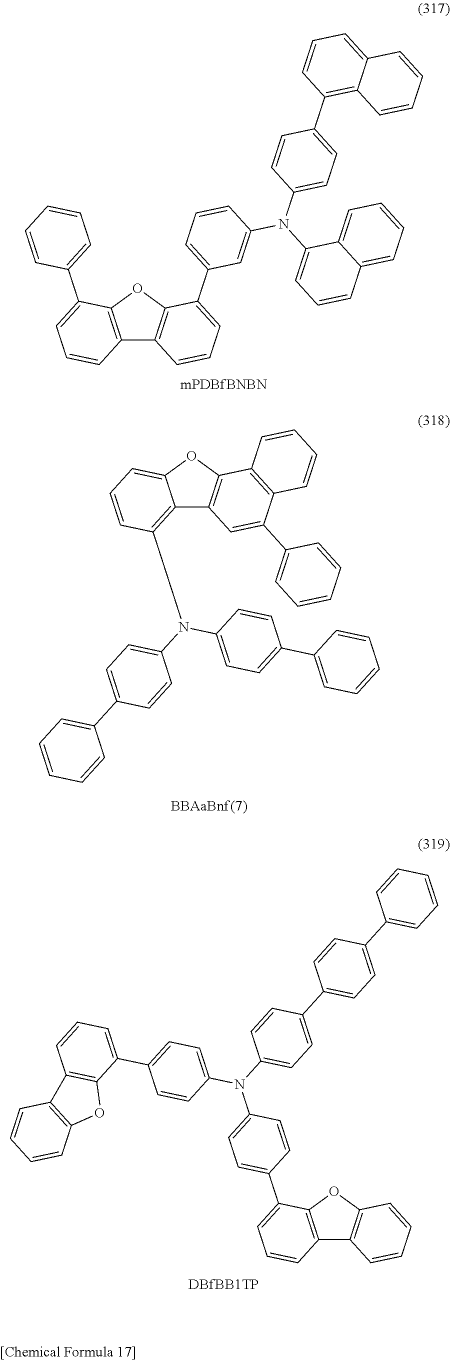 [SMILES: c1ccc(-c2cccc3c2oc2c(-c4cccc(N(c5ccc(-c6cccc7ccccc67)cc5)c5cccc6ccccc56)c4)cccc23)cc1 ; c1ccc(-c2ccc(N(CCc3cccc4oc5c6ccccc6c(-c6ccccc6)cc5c34)c3ccc(-c4ccccc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

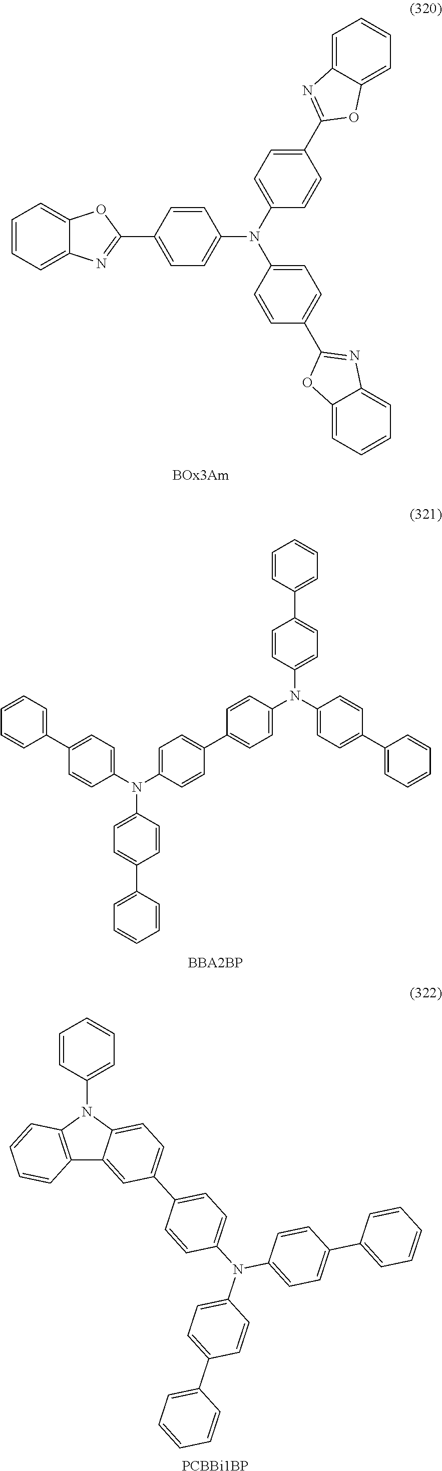

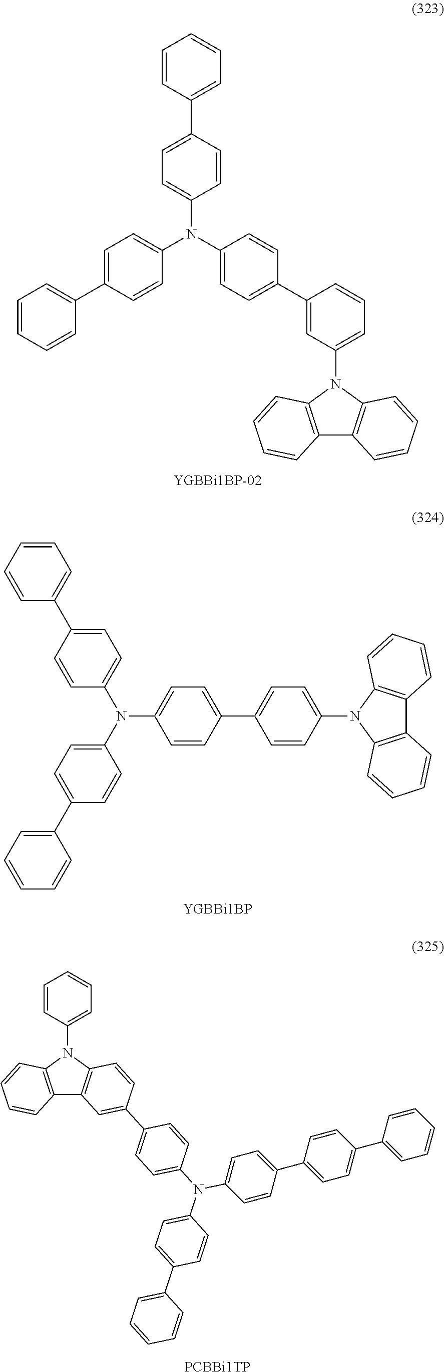

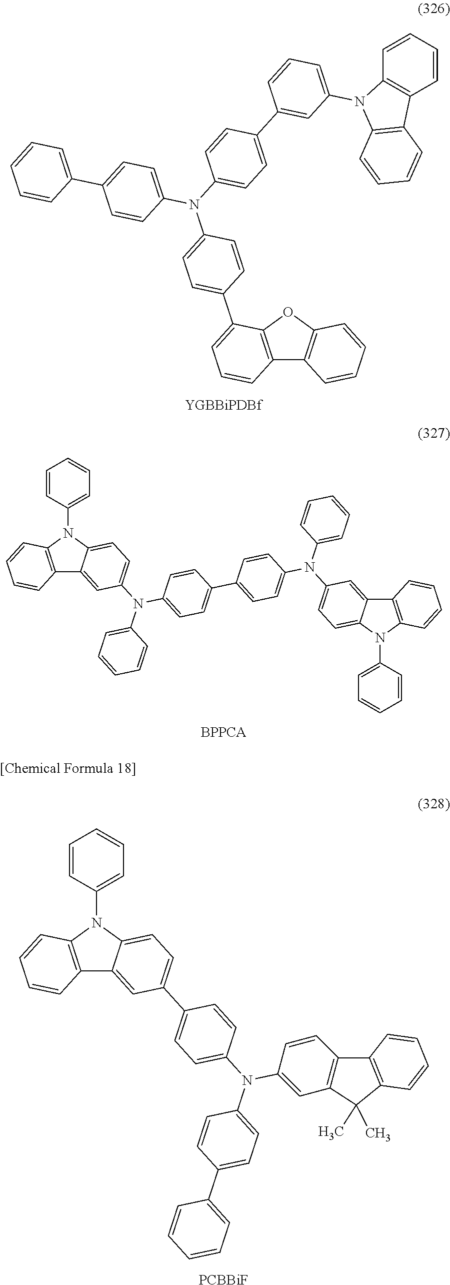

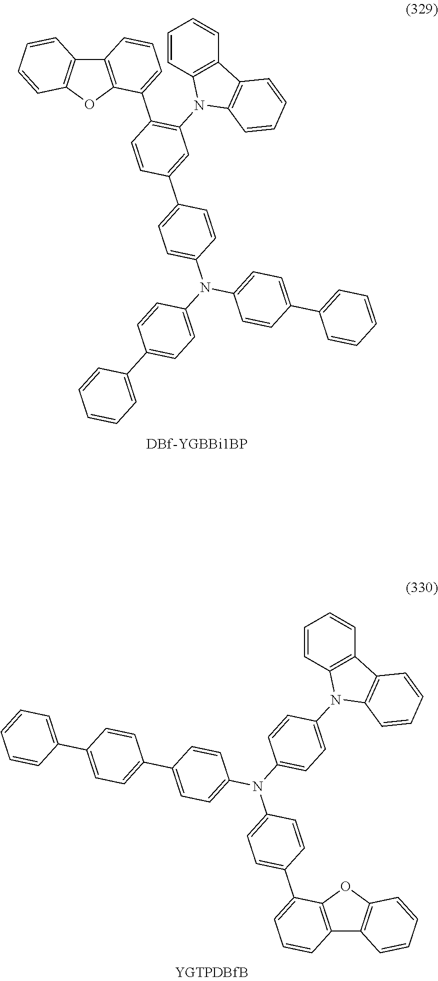 [SMILES: c1ccc(-c2ccc(N(c3ccc(-c4ccccc4)cc3)c3ccc(-c4ccc(-c5cccc6c5oc5ccccc56)c(-n5c6ccccc6c6ccccc65)c4)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

Among the organic compounds represented by Structural Formulae (300) to (330), for example, an organic compound having an amine skeleton and a polycyclic heteroaromatic ring, or an organic compound having an amine skeleton and a furan ring or a dibenzofuran ring is preferably used for the first hole-transport layer 112_1 and the second hole-transport layer 112_2. For the layers in contact with the light-emitting layers in the case where the first hole-transport layer 112_1 and the second hole-transport layer 112_2 each have a stacked-layer structure, in particular, an organic compound having a higher LUMO level than a material included in the corresponding light-emitting layer (at least the host material, preferably a material included in the light-emitting layer) is preferably selected and used as appropriate.

### <Electron-Transport Layer>

Although being a single layer in FIG. 1A, each of the first electron-transport layer 114_1 and the second electron-transport layer 114_2 may be a single layer or have a stacked-layer structure. The first electron-transport layer 114_1 and the second electron-transport layer 114_2 do not necessarily have same structure.

For example, the structure in which the first electron-transport layer 1141 is a single layer and the second electron-transport layer 114_2 has a stacked-layer structure may be employed. Specifically, the structure may be employed in which the electron-transport layer (e.g., the second electron-transport layer 114_2 in FIG. 1A) included in the light-emitting unit on the cathode side has a stacked-layer structure, and the electron-transport layer (e.g., the first electron-transport layer 114_1 in FIG. 1A) included in another light-emitting unit has a single-layer structure.

In one embodiment of the present invention, at least one electron-transport layer included in the light-emitting unit on the cathode side preferably includes an organic compound having a triazine ring. Alternatively, layers including organic compounds having different triazine rings may be stacked. Among the stacked layers, in particular, a layer on the cathode side preferably includes an organic compound having a triazine ring and an alkali metal such as Li. Such a structure can improve the electron-injection property.

The electron-transport layer included in the light-emitting unit closer to the anode than the light-emitting unit on the cathode side is (hereinafter also referred to as a light-emitting unit on the anode side) may include an organic compound that is the same as or different from the organic compound included in the electron-transport layer in the light-emitting unit on the cathode side. For example, an organic compound having a triazine ring, a pyrimidine ring, an imidazole ring, or an anthracene ring can be used. Alternatively, an organic compound having a triazine ring, which is different from the organic compound having a triazine ring in the electron-transport layer included in the light-emitting unit on the cathode side, may be used, for example.

Moreover, the electron-transport layer included in the light-emitting unit on the anode side preferably includes an organic compound having a triazine ring in order to reduce power consumption. In particular, the electron-transport layer included in the light-emitting unit on the anode side preferably includes the same organic compound as that in the electron-transport layer included in the light-emitting unit on the cathode side in order to inhibit a manufacturing apparatus from becoming complex and offer a cost advantage in raw material procurement.

When the electron-transport layer included in the light-emitting unit on the anode side includes an organic compound having no triazine ring, the carrier-transport property can be easily controlled to provide a light-emitting device with better characteristics. The organic compound having no triazine ring is preferably an organic compound having a heteroaromatic ring including a pyridine ring or an organic compound having a heteroaromatic ring including a diazine (pyrimidine or pyrazine) ring.

The electron-transport layer included in the light-emitting unit on the anode side may have a stacked-layer structure or a single-layer structure. When the electron-transport layer has a stacked-layer structure, the light-emitting device can have high current efficiency, low power consumption, and favorable characteristics. When the electron-transport layer has a single-layer structure, the number of film formation chambers can be reduced, which is advantageous in terms of manufacturing cost.

The above-described organic compound having a triazine ring that can be used in the electron-transport layer included in the light-emitting unit on each of the anode side and the cathode side preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The organic compound having a triazine ring preferably has a triazine ring and an aromatic ring. The aromatic ring is preferably a monocyclic aromatic ring, a polycyclic aromatic ring, an aromatic ring having an alkyl group as a substituent, an aromatic ring having a fluoro group as a substituent, an aromatic ring having a cyano group as a substituent, or the like. The triazine ring may have a substituent other than the above-described aromatic ring, and the aromatic ring may have a substituent other than the above-described fluoro group, cyano group, or alkyl group.

Examples of the monocyclic aromatic ring include aromatic hydrocarbon rings such as a benzene ring and heteroaromatic rings such as a pyrrole ring, a pyridine ring, a pyrimidine ring, and a triazine ring. Having the aromatic ring as a substituent has the effect of improving heat resistance, specifically, T_{g}, and the effect of improving an electron-transport property, for example.

Examples of the polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, a xanthene ring, an indolocarbazole ring, and an indenocarbazole ring. A compound having the polycyclic aromatic ring as a substituent can improve heat resistance more than a compound having a benzene ring and is thus preferable. A compound having as a substituent a ring in which an aromatic ring (e.g., a benzene ring, a naphthalene ring, or a pyridine ring) is further fused to any of the above polycyclic aromatic rings can further improve heat resistance. Examples of the ring in which an aromatic ring is further fused to the polycyclic aromatic ring include a benzofluorene ring, a benzonaphthofuran ring, a benzoxanthene ring, and a benzonaphthothiophene ring. Providing a layer including a compound having high heat resistance in the vicinity of the cathode can inhibit heat damage to the device when high-temperature treatment in a patterning step or the like is performed after the layer or the cathode is formed.

Examples of the alkyl group include a methyl group, an ethyl group, a propyl group, a tertiary butyl group, a cyclohexyl group, and an adamantyl group. A layer including a compound having the alkyl group as a substituent can have a low refractive index. This can inhibit total reflection at the interface between the layer and another layer and improve the light extraction efficiency of the light-emitting device including the layer. When such a compound having an alkyl group is used also for the hole-transport layer, the refractive index of the hole-transport layer can be lowered. In particular, when a compound having a triazine ring and an alkyl group is used for the electron-transport layer and a compound having a triarylamine skeleton and an alkyl group is used for the hole-transport layer, the effect of improving the light extraction efficiency can be synergistically enhanced. A compound having an alkyl group having a plurality of carbon atoms, preferably three or more carbon atoms, further preferably four or more carbon atoms, still further preferably five or more carbon atoms, can enhance the effect of lowering the refractive index. A layer including a compound having a fluoro group as a substituent is also preferable because it can lower the refractive index. In particular, a compound having a plurality of fluoro groups can enhance the effect of lowering the refractive index. It is also effective to use a compound having a fluoro group for both the electron-transport layer and the hole-transport layer.

A compound having a cyano group as a substituent is preferable because it can improve the electron-transport property.

A combination of some of polycyclic aromatic rings, alkyl groups, fluoro groups, and cyano groups is also suitable for substituents of the compound. Having a polycyclic aromatic ring and a cyano group as substituents, for example, can improve both the heat resistance and the electron-transport property. In addition, having a polycyclic aromatic ring and an alkyl group can improve both the heat resistance and the light extraction efficiency. In this manner, substituents can be combined in accordance with the required function.

A compound having a plurality of polycyclic aromatic rings as substituents can further improve the heat resistance. In that case, the compound preferably has the aromatic hydrocarbon ring and the heteroaromatic ring.

Specific examples of the organic compound having a triazine ring include 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-[8-([1,1′: 4′,1″-terphenyl]-4-yl)-1-dibenzofuranyl]-1,3,5-triazine (abbreviation: mBP-TPDBfTzn), 2-[4-(2-naphthyl)phenyl]-4-phenyl-6-spiro[9H-fluorene-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-pheny-9-[4-phenyl-6-(9-phenyl-3-dibenzofuranyl)-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), 2,4-diphenyl-6-[3′-(spiro[7H-benzo[c]fluorene-7,9′-[9H]xanthen]-2′-yl)biphenyl-3-yl]-1,3,5-triazine (abbreviation: mSbfxBPTzn), 3′-[4-phenyl-6-(spiro[9H-fluorene-9,9′-[9H]xanthen]-2′-yl)-1,3,5-triazin-2-yl]biphenyl-4-carbonitrile (abbreviation: mpCNBP-SFxTzn), and 2,2′-(1,2-naphthalenediyldi-4,1-phenylene)bis[4,6-diphenyl-1,3,5-triazine](abbreviation: TznP2N). It is particularly preferable to use any of TznP2N represented by Structural Formula (500), mSbfxBPTzn represented by Structural Formula (501), mpCNBP-SFxTzn represented by Structural Formula (502), CNBPNPTzn represented by Structural Formula (503), PNP-SFx(4)Tzn represented by Structural Formula (504), mmtBuBP-mDMePyPTzn represented by Structural Formula (505), and mBnfBPTzn represented by Structural Formula (506). The above organic compounds can be used as the host materials of the light-emitting layers.

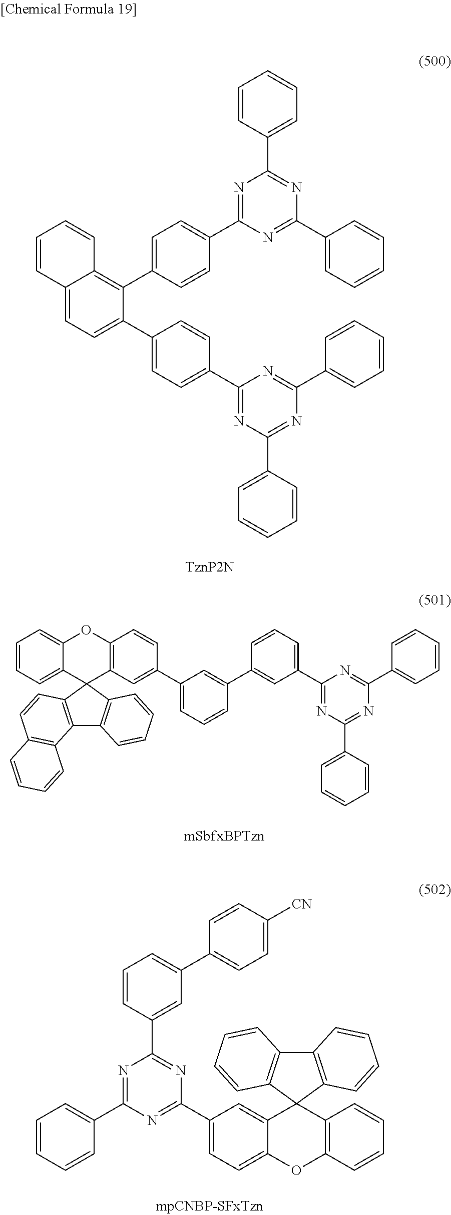 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1 ; c1ccc(-c2nc(-c3ccccc3)nc(-c3cccc(-c4cccc(-c5ccc6c(c5)C5(c7ccccc7O6)c6ccccc6-c6c5ccc5ccccc65)c4)c3)n2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1]

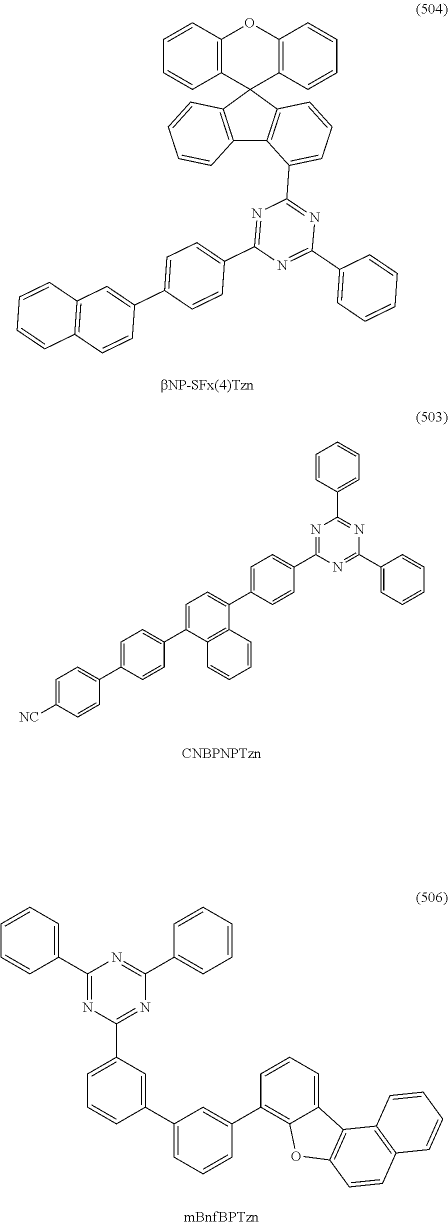 [SMILES: c1ccc(-c2nc(-c3ccc(-c4ccc5ccccc5c4)cc3)nc(-c3cccc4c3-c3ccccc3C43c4ccccc4Oc4ccccc43)n2)cc1 ; N#Cc1ccc(-c2ccc(-c3ccc(-c4ccc(-c5nc(-c6ccccc6)nc(-c6ccccc6)n5)cc4)c4ccccc34)cc2)cc1 ; c1ccc(-c2nc(-c3ccccc3)nc(-c3cccc(-c4cccc(-c5cccc6c5oc5ccc7ccccc7c56)c4)c3)n2)cc1]

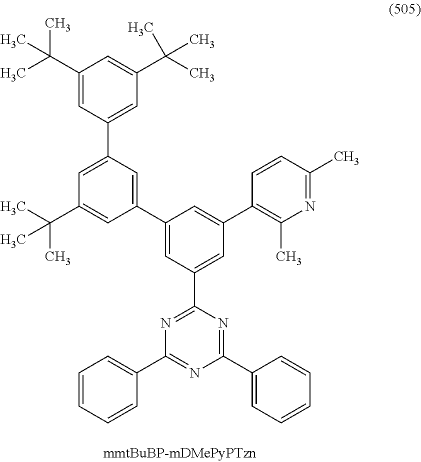 [SMILES: Cc1ccc(-c2cc(-c3cc(-c4cc(C(C)(C)C)cc(C(C)(C)C)c4)cc(C(C)(C)C)c3)cc(-c3nc(-c4ccccc4)nc(-c4ccccc4)n3)c2)c(C)n1]

The material that can be used for the electron-transport layer included in the light-emitting unit on the anode side preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes. The above substance is preferably an organic compound having a π-electron deficient heteroaromatic ring. The organic compound having a π-electron deficient heteroaromatic ring is preferably one or more of an organic compound having a heteroaromatic ring including an azole ring, an organic compound having a heteroaromatic ring including a pyridine ring, an organic compound having a heteroaromatic ring including a diazine ring, and an organic compound having a triazine ring, and is particularly preferably an organic compound having a triazine ring, for example.

As the electron-transport organic compound that can be used for the electron-transport layer included in the light-emitting unit on the anode side, an electron-transport material described later can be used. In particular, an organic compound having a heteroaromatic ring including a diazine ring, an organic compound having a heteroaromatic ring including a pyridine ring, and an organic compound having a triazine ring are preferable because of having high reliability. In particular, the organic compound having a heteroaromatic ring including a diazine (pyrimidine or pyrazine) ring and the organic compound having a triazine ring have a high electron-transport property, leading to a reduction in driving voltage.

### <Intermediate Layer>

In the tandem light-emitting device of one embodiment of the present invention, the intermediate layer 160 preferably includes an organic compound having a phenanthroline ring.

The above-described organic compound having a phenanthroline ring preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The organic compound having a phenanthroline ring preferably has a phenanthroline ring and an aromatic ring. The aromatic ring is preferably a monocyclic aromatic ring, a polycyclic aromatic ring, or the like.

Examples of the monocyclic aromatic ring include a benzene ring, a pyrrole ring, a pyridine ring, and a pyrimidine ring. Preferable examples of the polycyclic aromatic ring include heteroaromatic rings such as a phenanthroline ring and a pyrrole ring, as well as aromatic hydrocarbon rings such as a naphthalene ring, a phenanthrene ring, a chrysene ring, a triphenylene ring, and a fluorene ring. It is particularly preferable that the organic compound have a plurality of such polycyclic aromatic rings to improve its heat resistance or electron-transport property.

The organic compound having a phenanthroline ring can be, for example, an organic compound having a heteroaromatic ring including a phenanthroline ring, such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), or 2-[4-(2-triphenylenyl)phenyl]-1,10-phenanthroline (abbreviation: pTpPPhen), and is preferably PnNPhen represented by Structural Formula (200) below, mPPhen2P represented by Structural Formula (201) below, or the like.

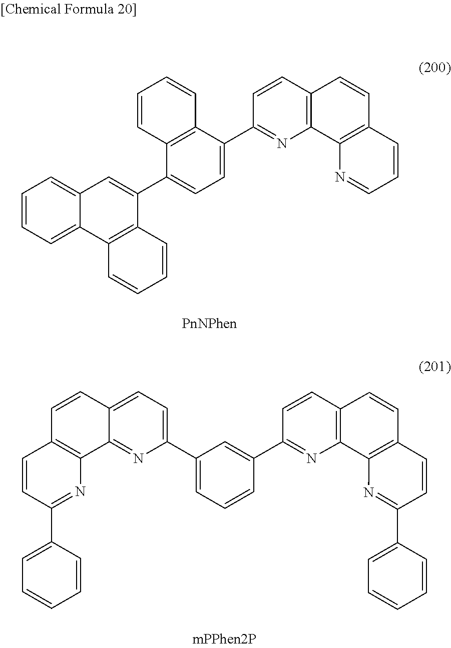 [SMILES: c1ccc2c(c1)cc(-c1ccc(-c3ccc4ccc5cccnc5c4n3)c3ccccc13)c1ccccc12 ; c1ccc(-c2ccc3ccc4ccc(-c5cccc(-c6ccc7ccc8ccc(-c9ccccc9)nc8c7n6)c5)nc4c3n2)cc1]

In the light-emitting device of one embodiment of the present invention, the intermediate layer can have any structure as long as it includes the organic compound having a phenanthroline ring and can inject electrons and holes respectively into the light-emitting unit on the anode side and the light-emitting unit on the cathode side, which are in contact with the intermediate layer, by voltage application between the first electrode and the second electrode. Note that the intermediate layer 160 preferably has a stacked-layer structure of a first layer 161 including an organic compound and a second layer 162 positioned closer to the cathode than the first layer is, as illustrated in FIG. 1A.

The first layer preferably includes a metal or a metal compound in addition to the organic compound. The metal or a metal of the metal compound is preferably an alkali metal (Group 1 element) such as Li, an alkaline earth metal (Group 2 element) such as Mg or Ca, a Group 3 element including Y and lanthanoids such as Eu and Yb, a Group 11 element such as Cu, Ag, or Au, a Group 12 element such as Zn, or an earth metal (Group 13 element) such as Al or In.

The first layer may have a stacked-layer structure of a layer including an organic compound and a layer that includes a metal or a metal compound and is positioned closer to the cathode than the layer including an organic compound is. Alternatively, the first layer may be a mixed layer of an organic compound and a metal or a metal compound. The first layer is preferably the mixed layer, in which case it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a distribution different from that of the organic compound; thus, the analysis results of diffusion and mixing can be distinguished from each other.

In the case where the metal or the metal compound is detected over a region having a thickness greater than or equal to 10 nm, preferably greater than or equal to 15 nm, further preferably greater than or equal to 20 nm when the first layer is analyzed in the thickness direction, the first layer can be regarded as including a mixed layer in which the organic compound and the metal or the metal compound are mixed.

The metal or a metal of the metal compound is preferably, among others, a substance exhibiting a donor property with respect to the organic compound having a phenanthroline ring. Examples of the substance exhibiting a donor property with respect to the organic compound having a phenanthroline ring include metals belonging to Groups 1 and 2; lithium or a lithium compound is particularly preferable. Specifically, Li, lithium fluoride (LiF), lithium oxide (Li₂O), 8-quinolinolato-lithium (abbreviation: Liq), or the like is preferable. In the case where the first layer includes the organic compound having a phenanthroline ring and the substance exhibiting a donor property with respect to the organic compound having a phenanthroline ring, electrons are generated by charge separation, and the electrons are injected into the light-emitting unit on the anode side through the organic compound having a phenanthroline ring when voltage is applied between the first and second electrodes. Thus, the light-emitting device of one embodiment of the present invention can have a low driving voltage.

The organic compound having a phenanthroline ring is preferably an organic compound having a phenanthroline ring having an electron-donating substituent, as well as the above-described organic compound. The phenanthroline ring is likely to interact with the metal or the like, and when the organic compound having such a phenanthroline ring further has an electron-donating group, the phenanthroline ring can have a higher electron density and become more likely to interact with the metal or the metal compound. In particular, the use of a metal belonging to Group 3, 11, 12, or 13 as the metal or a metal of the metal compound makes it possible to provide a tandem light-emitting device which is inhibited from having an increase in driving voltage and which has favorable characteristics.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

Specific examples of the organic compound having a phenanthroline ring having an electron-donating substituent are shown in Structural Formulae (203) to (210). In addition, specific examples of an organic compound that is not an organic compound having a phenanthroline ring but can be used for the intermediate layer are shown in Structural Formulae (211) to (213).

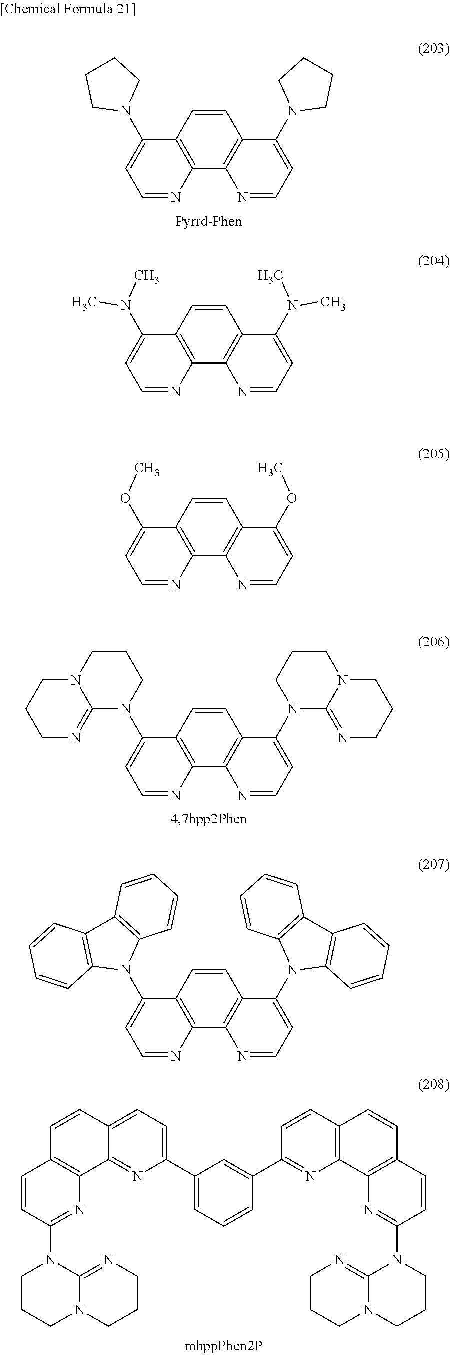

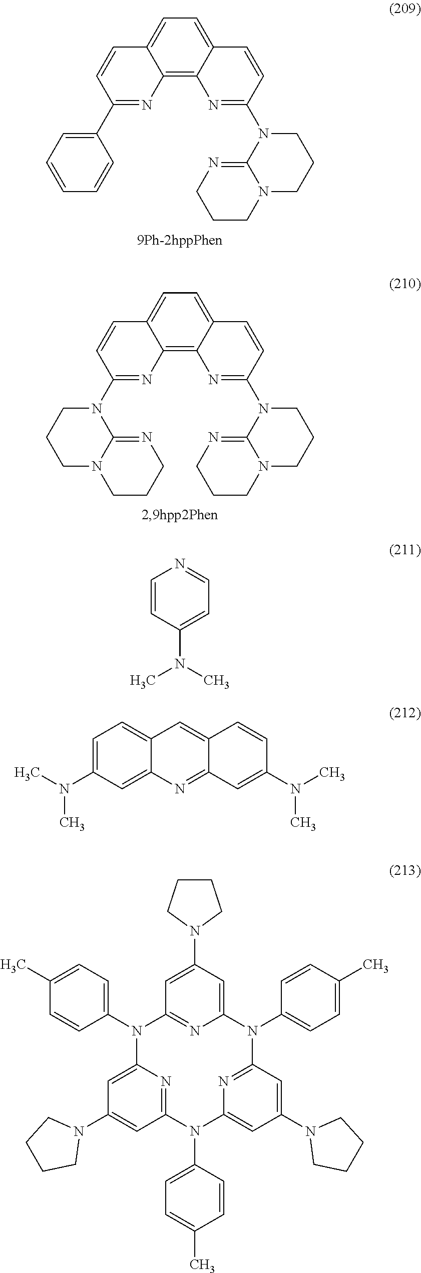

Note that the first layer preferably includes a Group 1 or Group 2 element, especially lithium or a lithium compound, and the organic compound having a phenanthroline ring having an electron-donating substituent, in which case the tandem light-emitting device can have a lower driving voltage and higher reliability. Moreover, the first layer preferably includes a Group 1 or Group 2 element, especially lithium or a lithium compound, and the organic compound having a phenanthroline ring having an electron-donating substituent, in which case it is possible to inhibit an increase in driving voltage due to processing of an organic compound layer of the light-emitting device by a photolithography method.

Among organic compounds having a phenanthroline ring, an organic compound having a 1,10-phenanthroline ring, the two nitrogen atoms of which can be coordinated to a metal, is particularly preferably used as the organic compound having a phenanthroline ring in the intermediate layer having the above-described structure to facilitate interaction with the metal or the metal compound.

In the case where an electron-donating group is introduced to a 1,10-phenanthroline ring, the electron-donating group is preferably substituted at the 4- and 7-positions of the 1,10-phenanthroline ring. Introducing electron-donating groups to the 4- and 7-positions of the 1,10-phenanthroline ring can increase the electron density of the nitrogen atoms at the 1- and 10-positions, thereby facilitating the interaction with the metal or the metal compound.

The first layer may further include a different organic compound other than the organic compound having a phenanthroline ring. The different organic compound preferably has an electron-transport property and particularly preferably includes two or more heteroaromatic rings bonded or fused to each other. The two or more heteroaromatic rings preferably have three or more heteroatoms in total. The first layer including such an organic compound can improve the heat resistance, the electron-transport property, and the like.

The second layer 162 preferably includes a hole-transport organic compound. The second layer 162 preferably further includes a substance exhibiting an acceptor property, and the substance exhibiting an acceptor property is preferably an organic compound exhibiting an acceptor property with respect to the hole-transport organic compound. The substance exhibiting an acceptor property is particularly preferably an organic compound having at least one of a halogen group and a cyano group, further preferably an organic compound having at least one of fluorine and a cyano group. Note that it is further preferable that the total number of halogen groups (fluorines) and cyano groups of the organic compound be four or more.

In the case where the second layer 162 includes the hole-transport organic compound and the substance exhibiting an acceptor property with respect to the hole-transport organic compound, holes are generated by charge separation, and the holes are injected into the light-emitting unit on the cathode side through the hole-transport organic compound when voltage is applied between the first and second electrodes. Thus, the light-emitting device of one embodiment of the present invention can have a low driving voltage.

The intermediate layer may include a third layer 163 between the first layer 161 and the second layer 162.

The third layer 163 includes an electron-transport substance and has functions of smoothly transferring and receiving electrons between the first layer 161 and the second layer 162 to reduce the driving voltage, and reducing the interaction between the first layer 161 and the second layer 162 to improve the reliability, for example.

The thickness of the third layer 163 is preferably greater than or equal to 1 nm and less than or equal to 10 nm, further preferably greater than or equal to 2 nm and less than or equal to 5 nm, in which case an increase in driving voltage can be inhibited.

The light-emitting device of one embodiment of the present invention that has the above structure can have high current efficiency, low energy loss, and favorable characteristics. A display apparatus of one embodiment of the present invention that includes such a light-emitting device can achieve low power consumption, high reliability, high-luminance display, and high visibility.

The first electrode 101 includes the anode. The first electrode 101 may have a stacked-layer structure, in which case a layer in contact with the organic compound layer 103 functions as the anode. The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the composite material forming the first layer 161 (also referred to as a p-type layer) in the above intermediate layer 160 is used for the layer (typically the hole-injection layer) in contact with the anode.

The hole-injection layer 111 is provided in contact with the anode and has a function of facilitating injection of holes into the organic compound layer 103 (the first light-emitting unit 501). The hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds each having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as a molybdenum oxide, a vanadium oxide, a ruthenium oxide, a tungsten oxide, or a manganese oxide can be used, other than the above-described organic compounds. Alternatively, the hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example. The substance having an acceptor property can extract electrons from an adjacent hole-transport layer (or hole-transport material) by application of an electric field.

The hole-injection layer 111 is preferably formed using a composite material containing any of the aforementioned materials having an acceptor property and a hole-transport substance.

As the hole-transport substance used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the hole-transport substance used for the composite material preferably has a hole mobility higher than or equal to 1×10⁻⁶ cm²/Vs. The hole-transport substance used in the composite material is preferably a compound having a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring including at least one of a pyrrole ring, a furan ring, and a thiophene ring is preferable; specifically, a carbazole ring, a dibenzothiophene ring, or a ring in which an aromatic ring or a heteroaromatic ring is further fused to a carbazole ring or a dibenzothiophene ring is preferable.

Such a hole-transport substance further preferably has any of a carbazole ring, a dibenzofuran ring, a dibenzothiophene ring, and an anthracene ring. In particular, an aromatic amine compound having a substituent that has a dibenzofuran ring or a dibenzothiophene ring, an aromatic monoamine compound having a naphthalene ring, or an aromatic monoamine compound in which a 9-fluorenyl group is bonded to nitrogen of an amine through an arylene group may be used. Note that the hole-transport substance preferably has an N,N-bis(4-biphenyl)amino group to enable fabricating a light-emitting device having a long lifetime.

Specific examples of the hole-transport substance include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-([2,1′-binaphthyl]-6-yl)triphenylamine (abbreviation: BBAαNβNB), 4,4′-diphenyl-4″-([2,1′-binaphthyl]-7-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-([2,2′-binaphthyl]-6-yl)triphenylamine (abbreviation: BBA(βN2)B), 4,4′-diphenyl-4″-([2,2′-binaphthyl]-7-yl)triphenylamine (abbreviation: BBA(βN2)B-03), 4,4′-diphenyl-4″-([1,2′-binaphthyl]-4-yl)triphenylamine (abbreviation: BBAβNαNB), 4,4′-diphenyl-4″-([1,2′-binaphthyl]-5-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, PSiCzCz, and 9′-[3-(triphenylsilyl)phenyl]-9′H-9,3′:6′,9″-tercarbazole (abbreviation: PSiCzGI).

Examples of the aromatic amine compound that can be used as the hole-transport substance include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer (the first hole-transport layer 112_1 or the second hole-transport layer 112_2) includes a hole-transport organic compound. The hole-transport organic compound preferably has a hole mobility higher than or equal to 1×10⁻⁶ cm²/Vs. Other than the above-described organic compound having a triarylamine skeleton and a fluorene ring, the hole-transport organic compound can also be used as needed.

Examples of the aforementioned hole-transport organic compound include the following compounds: compounds each having a triarylamine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds each having a carbazole ring, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-9H,9′H-3,3′-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, and N,N-bis(9,9-dimethyl-9H-fluoren-2-yl)-9,9′-spirobi-9H-fluoren-1-amine; compounds each having a thiophene ring, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds each having a furan ring, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compounds each having a triarylamine skeleton and the compounds each having a carbazole ring are preferable because these compounds are highly reliable and have a high hole-transport property to contribute to a reduction in driving voltage. Any of the organic compounds given as examples of the hole-transport substance that is used for the composite material in the hole-injection layer 111 can also be suitably used as the material included in the hole-transport layer 112 (the first hole-transport layer 112_1 and the second hole-transport layer 112_2).

The light-emitting layer (the first light-emitting layer 113_1 and the second light-emitting layer 1132) preferably includes a light-emitting substance and a host material. The light-emitting layers may additionally include another material. At least one of the light-emitting layers includes a TADF material as the light-emitting substance.

The first light-emitting layer 113_1 and the second light-emitting layer 113_2 preferably emit light of similar colors. In a full-color display apparatus, red, green, and blue pixels are often used: in a light-emitting device used in a red pixel, both the first light-emitting layer 113_1 and the second light-emitting layer 113_2 emit red light; in a light-emitting device used in a green pixel, both of the two light-emitting layers emit green light; and in a light-emitting device used in a blue pixel, both of the two light-emitting layers emit blue light, for example. In order that the first light-emitting layer 113_1 and the second light-emitting layer 113_2 can emit light of similar colors, specifically, a difference in maximum peak wavelength between the emission spectrum (fluorescence spectrum) of the compound as the light-emitting substance included in the first light-emitting layer 113_1 and the emission spectrum of the compound as the light-emitting substance included in the second light-emitting layer 113_2 is preferably less than or equal to 30 nm, further preferably less than or equal to 20 nm, still further preferably less than or equal to 10 nm. Note that it is further preferable that the first light-emitting layer 113_1 and the second light-emitting layer 113_2 include the same light-emitting substance.

The light-emitting substance may be a fluorescent substance, a phosphorescent substance, a substance exhibiting thermally activated delayed fluorescence (TADF), or any other light-emitting substance.

For example, in the case where red, green, and blue pixels are used to achieve a full-color display apparatus, a TADF material can be used for any of the red, green, and blue pixels, a fluorescent substance can be used for another pixel, and a phosphorescent substance can be used for the other pixel. Alternatively, TADF material can be used for any of the red, green, and blue pixels, and a phosphorescent substance can be used for the other pixel(s). Further alternatively, a TADF material can be used for any of the red, green, and blue pixels, and a fluorescent substance can be used for the other pixel(s). Such a structure makes it possible to offer a display apparatus with high efficiency.

Examples of the fluorescent substance that can be used as the light-emitting substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N″-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability. A compound obtained by substituting deuterium for part of hydrogen in any of these compounds can also be used.

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G) or 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), can be suitably used. A compound obtained by substituting deuterium for part of hydrogen in any of these compounds can also be used.

Examples of the material that can be used when a phosphorescent substance is used as the light-emitting substance in the light-emitting layer are as follows.

The examples include organometallic iridium complexes each having a 4H-triazole skeleton, such as tris{2-[5-(2-methylphenyl)-4-(2,6-dimethylphenyl)-4H-1,2,4-triazol-3-yl-κN²]phenyl-KC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); organometallic iridium complexes each having a 1H-triazole skeleton, such as tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), and tris[4-(3-biphenyl)-5-isopropyl-3-phenyl-4H-1,2,4-triazolato]iridium(III) (abbreviation: [Ir(iPrptz-3b)₃]); organometallic iridium complexes each having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-KC)iridium(III) (abbreviation: CNImIr); organometallic complexes each having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in each of which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI). These compounds emit blue phosphorescent light and have an emission peak in the wavelength range from 450 nm to 520 nm. A compound obtained by substituting deuterium for part of hydrogen in any of these compounds can also be used.

The examples also include organometallic iridium complexes each having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes each having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes each having a pyridine ring, such as tris(2-phenylpyridinato-N,C²′)iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]), and tris{2-[5-(methyl-d₃)-4-phenyl-2-pyridinyl-κN]phenyl-κC}iridium(III) (abbreviation: Ir(5m4dppy-d₃)₃); rare earth metal complexes such as tris(acetylacetonato)(monophenanthroline)terbium(III) (abbreviation: [Tb(acac)₃(Phen)]); and platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′:3′,1″-terphenyl]-2′-yl)-2-pyridinyl-κN]phenyl-κC²}-2-pyridinyl-κN)phenolato-κO]platinum(II) (abbreviation: Pt(4tButpppypyp-mmtBup)). These are mainly compounds that emit green phosphorescent light and have an emission peak at a wavelength longer than 500 nm and shorter than or equal to 600 nm. Note that organometallic iridium complexes each having a pyrimidine ring have distinctively high reliability or emission efficiency and thus are particularly preferable. A compound obtained by substituting deuterium for part of hydrogen in any of these compounds can also be used.

Other examples include organometallic iridium complexes each having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes each having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes each having a pyridine ring, such as tris(1-phenylisoquinolinato-N,C²)iridium(III) (abbreviation: [Ir(piq)₃]), bis(1-phenylisoquinolinato-N,C²)iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes each having a pyrazine ring can provide red light emission with favorable chromaticity. A compound obtained by substituting deuterium for part of hydrogen in any of these compounds can also be used.

Besides the above phosphorescent compounds, known phosphorescent compounds may be selected and used.

As the host material in the light-emitting layer, any of various carrier-transport materials such as later-described materials having an electron-transport property and/or the above-described materials having a hole-transport property, and the TADF materials can be used in addition to the above organic compounds.

The electron-transport material is preferably an organic compound having a π-electron deficient heteroaromatic ring. Examples of the organic compound having a π-electron deficient heteroaromatic ring include an organic compound having a heteroaromatic ring including an azole ring, an organic compound having a heteroaromatic ring including a pyridine ring, an organic compound having a heteroaromatic ring including a diazine ring, and an organic compound having a triazine ring.

Among the above organic compounds, the organic compound having a heteroaromatic ring including a diazine ring (a pyrimidine ring, a pyrazine ring, or a pyridazine ring), the organic compound having a heteroaromatic ring including a pyridine ring, and the organic compound having a triazine ring are preferable because of their high reliability. In particular, the organic compound having a heteroaromatic ring including a diazine (pyrimidine or pyrazine) ring and the organic compound having a triazine ring have a high electron-transport property to contribute to a reduction in driving voltage. A benzofuropyrimidine ring, a benzothienopyrimidine ring, a benzofuropyrazine ring, and a benzothienopyrazine ring are preferable because of their high acceptor properties and high reliability.

Preferable examples of the organic compound having a π-electron deficient heteroaromatic ring include the following organic compounds: organic compounds each having an azole ring, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS); organic compounds each having a heteroaromatic ring including a pyridine ring, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), and 2-[4-(2-triphenylenyl)phenyl]-1,10-phenanthroline (abbreviation: pTpPPhen); the above-mentioned organic compounds each having a heteroaromatic ring including a diazine ring; and the above-mentioned organic compounds each having a triazine ring. An organic compound having a heteroaromatic ring including a diazine ring, an organic compound having a heteroaromatic ring including a pyridine ring, and an organic compound having a triazine ring are preferable because of their high reliability. In particular, the organic compound having a heteroaromatic ring including a diazine (pyrimidine or pyrazine) ring and the organic compound having a triazine ring have a high electron-transport property to contribute to a reduction in driving voltage.

As the TADF material that can be used as the host material, the above materials mentioned as the TADF material that can be used as the light-emitting substance can also be used. When a fluorescent substance or a phosphorescent substance is used as the light-emitting substance and the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably has an aromatic ring, and still further preferably has a fused aromatic ring or a fused heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene ring is suitably used as the host material. The use of a substance having an anthracene ring as the host material for the fluorescent substance makes it possible to obtain a light-emitting layer with high emission efficiency and high durability. Among the substances having an anthracene ring, a substance having a diphenylanthracene ring, in particular, a substance having a 9,10-diphenylanthracene ring, is chemically stable and thus is preferably used as the host material. The host material preferably has a carbazole ring to have higher hole-injection and hole-transport properties; further preferably, the host material has a benzocarbazole ring in which a benzene ring is further fused to a carbazole ring, because the HOMO level of the host material having a benzocarbazole ring is higher than that of the compound having a carbazole ring by approximately 0.1 eV and the host material having a benzocarbazole ring is thus easier for holes to enter than the compound having a carbazole ring. In particular, the host material suitably has a dibenzocarbazole ring, because the HOMO level of the host material having a dibenzocarbazole ring is higher than that of the compound having a carbazole ring by approximately 0.1 eV, the host material having a dibenzocarbazole ring is thus easier for holes to enter than the compound having a carbazole ring, and the host material having a dibenzocarbazole ring has a higher hole-transport property and higher heat resistance than the compound having a carbazole ring. Accordingly, a substance that has both a 9,10-diphenylanthracene ring and a carbazole ring (or a benzocarbazole or dibenzocarbazole ring) is further preferable as the host material. Note that in terms of the hole-injection and hole-transport properties described above, instead of a carbazole ring, a benzofluorene ring or a dibenzofluorene ring may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthryl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix an electron-transport material with a hole-transport material. By mixing the electron-transport material with the hole-transport material, the transport property of the light-emitting layer can be easily adjusted and a recombination region can be easily controlled. The weight ratio of the content of the hole-transport material to the content of the electron-transport material is 1:19 to 19:1, preferably 1:9 to 9:1, further preferably 3:7 to 7:3.

Note that a phosphorescent substance can be used as part of the mixed material. When a fluorescent substance is used as a light-emitting substance, a phosphorescent substance can be used as an energy donor for supplying excitation energy to the fluorescent substance.

These mixed materials may form an exciplex. These mixed materials are preferably selected so as to form an exciplex that exhibits emission of light whose wavelength overlaps with the wavelength of the lowest-energy absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

The first electron-transport layer 1141 is a layer including an electron-transport substance. The electron-transport substance preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes. The above substance is preferably an organic compound having a π-electron deficient heteroaromatic ring. The organic compound having a π-electron deficient heteroaromatic ring is preferably one or more of an organic compound having a heteroaromatic ring including an azole ring, an organic compound having a heteroaromatic ring including a pyridine ring, an organic compound having a heteroaromatic ring including a diazine ring, and an organic compound having a triazine ring, for example, and is particularly preferably the organic compound having a triazine ring.

As the electron-transport organic compound that can be used in the first electron-transport layer 114_1, any of the aforementioned organic compounds that can be used as the electron-transport organic compound that serves as the host material in the first light-emitting layer 113_1 and the second light-emitting layer 113_2 can be used. Among the above organic compounds, the organic compound having a heteroaromatic ring including a diazine ring, the organic compound having a heteroaromatic ring including a pyridine ring, and the organic compound having a triazine ring are preferable because of having high reliability. In particular, the organic compound having a heteroaromatic ring including a diazine (pyrimidine or pyrazine) ring and the organic compound having a triazine ring have a high electron-transport property to contribute to a reduction in driving voltage.

The second electron-transport layer 114_2 is, as described above, a layer including the organic compound having a triazine ring. Since the details have already been described, the description is omitted here.

Note that the first electron-transport layer 114_1 preferably includes the organic compound having a triazine ring to reduce power consumption. In particular, the first electron-transport layer 114_1 preferably includes the same organic compound having a triazine ring as the organic compound having a triazine ring that is included in the second electron-transport layer 114_2, which inhibits the complication of a manufacturing apparatus and is advantageous also in terms of raw material procurement cost.

In the case where the first electron-transport layer 1141 includes an organic compound having no triazine ring, the light-emitting device can have favorable characteristics owing to easy control of carrier transport. The organic compound having no triazine ring is preferably an organic compound having a heteroaromatic ring including a pyridine ring or an organic compound having a heteroaromatic ring including a diazine (pyrimidine or pyrazine) ring.

The electron-injection layer 115 has a function of reducing a barrier for electron injection from the second electrode 102 to promote electron injection and can be formed using a Group 1 metal or a Group 2 metal, or an oxide, a halide, or a carbonate of any of these metals, for example. Alternatively, a composite material including the electron-transport material described above and a material having a property of donating electrons to the electron-transport material can also be used. As examples of the material having an electron-donating property, a Group 1 metal, a Group 2 metal, an oxide of any of these metals, and the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (Li₂O), can be used. Alternatively, a rare earth metal compound like erbium fluoride (ErF₃) can be used. Electride may also be used for the electron-injection layer 115. Examples of the electride include a substance in which electrons are added at high concentration to a calcium oxide-aluminum oxide. The electron-injection layer 115 can be formed using the substance that can be used for the electron-transport layer.

A composite material in which an organic compound and an electron donor (donor) are mixed may also be used for the electron-injection layer 115. Such a composite material is excellent in an electron-injection property and an electron-transport property because electrons are generated in the organic compound by the electron donor. In this case, the organic compound is preferably a material that is excellent in transporting the generated electrons. Specifically, any of the above-described substances for forming the electron-transport layer can be used, for example. As the electron donor, a substance showing an electron-donating property with respect to an organic compound can be used. Specifically, it is preferable to use an alkali metal, an alkaline earth metal, or a rare earth metal, such as lithium, sodium, cesium, magnesium, calcium, erbium, or ytterbium. It is also preferable to use an alkali metal oxide or an alkaline earth metal oxide, such as a lithium oxide, a calcium oxide, or a barium oxide. Alternatively, a Lewis base such as a magnesium oxide can be used. Further alternatively, an organic compound such as tetrathiafulvalene (abbreviation: TTF) can be used.

The second electrode 102 includes the cathode. The second electrode 102 may have a stacked-layer structure, in which case a layer in contact with the organic compound layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. Specific examples thereof include alkali metals, alkaline earth metals, rare earth metals, compounds thereof, and complexes thereof, such as lithium fluoride (LiF), cesium fluoride (CsF), calcium fluoride (CaF₂), 8-quinolinolato-lithium (abbreviation: Liq), and ytterbium (Yb), and electrides. Examples of an electride include substances in which electrons are added at high concentration to a calcium oxide-aluminum oxide. Note that a mixture of two or more of these materials may be used as a cathode material. In the case where the second electrode 102 has a stacked-layer structure, a material having high conductivity can be used for the layer(s) other than the cathode, regardless of the work function.

Note that the second electron-transport layer 114_2 is preferably in contact with the second electrode 102. When the second electron-transport layer 114_2 is in contact with the second electrode 102, the light-emitting device can have excellent electron-injection and electron-transport properties, a low driving voltage, and low power consumption.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

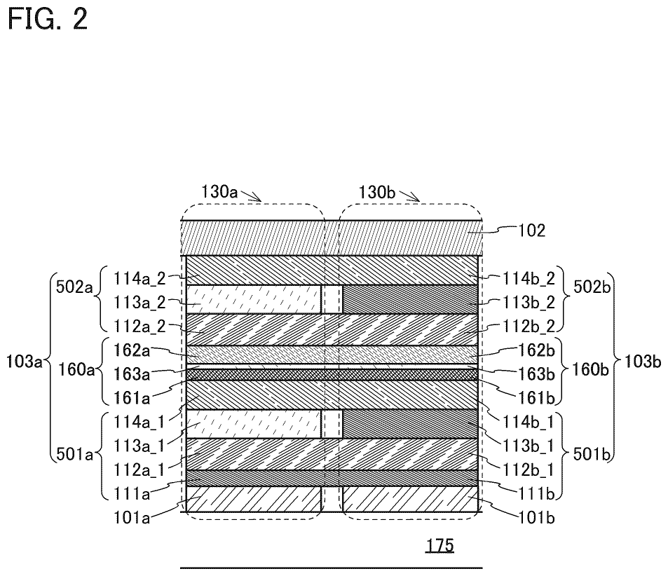

FIG. 2 illustrates two adjacent light-emitting devices (a light-emitting device 130a and a light-emitting device 130b) included in the display apparatus of one embodiment of the present invention. The light-emitting device 130a and the light-emitting device 130b emit light of different colors. Note that in order that a plurality of light-emitting devices can emit light of different colors, specifically, a difference in maximum peak wavelength between the electroluminescence spectra of the light-emitting devices is greater than 30 nm.

The light-emitting device 130a includes an organic compound layer 103a between a first electrode 101a and the second electrode 102 over an insulating layer 175. The organic compound layer 103a has a structure in which a first light-emitting unit 501a and a second light-emitting unit 502a are stacked with an intermediate layer 160a therebetween. Although FIG. 2 illustrates an example in which the two light-emitting units are stacked, three or more light-emitting units may be stacked. The first light-emitting unit 501a includes a hole-injection layer 111a, a first hole-transport layer 112a_1, a first light-emitting layer 113a_1, and a first electron-transport layer 114a_1. The intermediate layer 160a includes a second layer 162a, a third layer 163a, and a first layer 161a. The third layer 163a may be present or absent. The second light-emitting unit 502a includes a second hole-transport layer 112a_2, a second light-emitting layer 113a_2, and a second electron-transport layer 114a_2.

The light-emitting device 130b includes an organic compound layer 103b between a first electrode 101b and the second electrode 102 over the insulating layer 175. The organic compound layer 103b has a structure in which a first light-emitting unit 501b and a second light-emitting unit 502b are stacked with an intermediate layer 160b therebetween. Although FIG. 2 illustrates an example in which the two light-emitting units are stacked, three or more light-emitting units may be stacked. The first light-emitting unit 501b includes a hole-injection layer 111b, a first hole-transport layer 112b_1, a first light-emitting layer 113b_1, and a first electron-transport layer 114b_1. The intermediate layer 160b includes a second layer 162b, a third layer 163b, and a first layer 161b. The third layer 163b may be present or absent. The second light-emitting unit 502b includes a second hole-transport layer 112b_2, a second light-emitting layer 113b_2, and a second electron-transport layer 114b_2.

The first hole-transport layer 112a_1 and the second hole-transport layer 112a_2 each have a stacked-layer structure. In the stacked-layer structure, the layer in contact with the light-emitting layer is formed using a material whose LUMO level is higher than the LUMO level of a material included in the light-emitting layer (at least the host material, preferably the material included in the light-emitting layer, the material having the highest constituent ratio among the materials included in the light-emitting layer, or the material having the highest LUMO level among the materials included in the light-emitting layer).

The second electron-transport layer 114a_2 and the second electron-transport layer 114b_2 preferably include an organic compound having a triazine ring. The first layer 161a and the first layer 161b each include an organic compound having a phenanthroline ring.

The first light-emitting layer 113a_1 and the second light-emitting layer 113a_2 preferably emit light of similar colors. The light-emitting substance included in the first light-emitting layer 113a_1 and the light-emitting substance included in the second light-emitting layer 113a_2 are preferably compounds whose emission spectra have a difference in maximum peak wavelength less than or equal to 30 nm, further preferably less than or equal to 20 nm, still further preferably less than or equal to 10 nm. It is further preferable that the first light-emitting layer 113a_1 and the second light-emitting layer 113a_2 include the same light-emitting substance. The first light-emitting layer 113b_1 and the second light-emitting layer 113b_2 preferably emit light of similar colors. The light-emitting substance included in the first light-emitting layer 113b_1 and the light-emitting substance included in the second light-emitting layer 113b_2 are preferably compounds whose emission spectra have a difference in maximum peak wavelength less than or equal to 30 nm, further preferably less than or equal to 20 nm, still further preferably less than or equal to 10 nm. It is further preferable that the first light-emitting layer 113b_1 and the second light-emitting layer 113b_2 include the same light-emitting substance.

It is preferable that the first light-emitting layer 113a_1 and the first light-emitting layer 113b_1 be separated from each other and the second light-emitting layer 113a_2 and the second light-emitting layer 113b_2 be separated from each other. It is preferable that the emission color(s) of the first light-emitting layer 113a_1 and the second light-emitting layer 113a_2 be different from the emission color(s) of the first light-emitting layer 113b_1 and the second light-emitting layer 113b_2. It is preferable that the light-emitting substance included in the first light-emitting layer 113a_1 and the light-emitting substance included in the first light-emitting layer 113b_1 be different from each other and the light-emitting substance included in the second light-emitting layer 113a_2 and the light-emitting substance included in the second light-emitting layer 113b_2 be different from each other.

Note that each of the pairs of the hole-injection layers 111a and 111b, the first hole-transport layers 112a_1 and 112b_1, the first electron-transport layers 114a_1 and 114b_1, the intermediate layers 160a and 160b (the second layers 162a and 162b, the third layers 163a and 163b, and the first layers 161a and 161b), the second hole-transport layers 112a_2 and 112b_2, and the second electron-transport layers 114a_2 and 114b_2 may be one continuous layer or may be separate layers independent of each other between the light-emitting device 130a and the light-emitting device 130b. When these layers are continuous layers, the light-emitting devices can be fabricated with high productivity at low cost. When the layers are separate layers between the light-emitting devices, the layers can be formed using materials suitable for their emission colors, thereby enabling the light-emitting devices or a display apparatus to have favorable characteristics. In particular, the second electron-transport layer 114a_2 and the second electron-transport layer 114b_2 are preferably one continuous layer, in which case both the light-emitting device 130a and the light-emitting device 130b can have favorable characteristics.

The second electron-transport layer 114a_2 and the second electron-transport layer 114b_2 being one continuous layer means that the second electron-transport layer 114a_2 and the second electron-transport layer 114b_2 are made of the same material. That is, when the second electron-transport layer 114a_2 and the second electron-transport layer 114b_2 are made of the same material, both the light-emitting device 130a and the light-emitting device 130b can have favorable characteristics. It is further preferable that the second electron-transport layer 114a_2 and the second electron-transport layer 114b_2 have similar structures, and it is still further preferable that the second electron-transport layer 114a_2 and the second electron-transport layer 114b_2 have the same structure.

Furthermore, in the case where the light-emitting substances included in the first light-emitting layers 113a_1 and 113b_1 are different from each other and the light-emitting substances included in the second light-emitting layers 113a_2 and 113b_2 are different from each other (e.g., in the case where the first light-emitting layer 113a_1 and the second light-emitting layer 113a_2 are blue fluorescent layers and the first light-emitting layer 113b_1 and the second light-emitting layer 113b_2 are green phosphorescent layers, in the case where the first light-emitting layer 113a_1 and the second light-emitting layer 113a_2 are blue fluorescent layers and the first light-emitting layer 113b_1 and the second light-emitting layer 113b_2 are red phosphorescent layers, or in the case where the first light-emitting layer 113a_1 and the second light-emitting layer 113a_2 are green phosphorescent layers and the first light-emitting layer 113b_1 and the second light-emitting layer 113b_2 are red phosphorescent layers), the light-emitting layers of the light-emitting devices 130a and 130b have different carrier balances. Therefore, in order to improve the performance of each of the light-emitting devices 130a and 130b, it is usually necessary to select and use an appropriate intermediate layer and an appropriate electron-transport layer for each light-emitting device. However, even when the second electron-transport layers 114a_2 and 114b_2 have the same structure, the use of the organic compound having a triazine ring in the second electron-transport layers 114a_2 and 114b_2 and the use of the organic compound having a phenanthroline ring in the first layers 161a and 161b can improve the performance of each of the light-emitting devices 130a and 130b. That is, both the productivity and the performance can be improved. Note that the first layers 161a and 161b may have the same structure.

Note that one continuous layer is a so-called common layer formed across the light-emitting devices 130a and 130b.

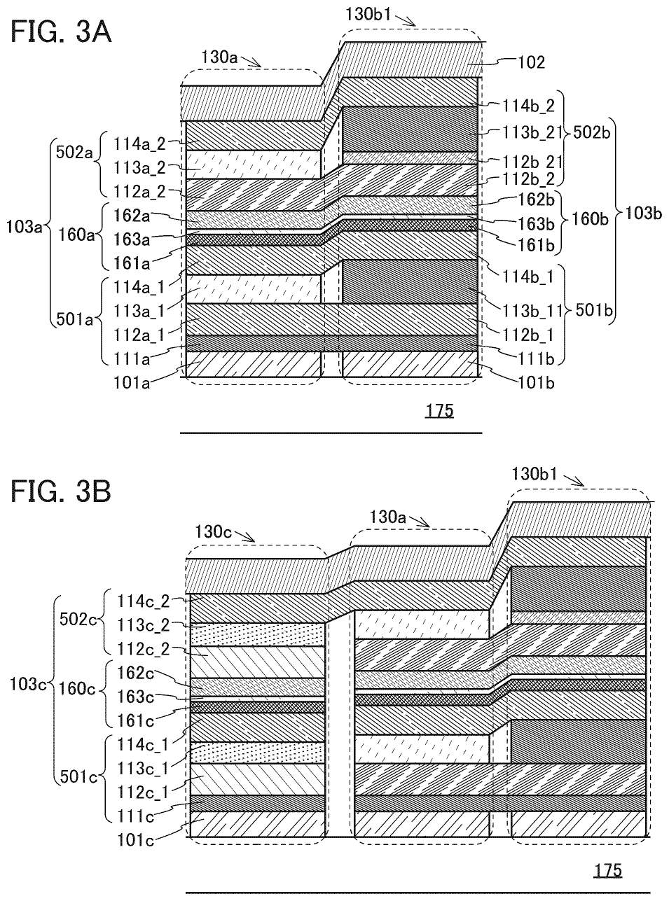

FIG. 3A is a modification example of FIG. 2. The light-emitting devices 130a and 130b emit light of different colors and thus have different optical path lengths between the electrodes for amplification of emitted light using a microcavity structure. In a light-emitting device 130b1, the distance between the electrodes can be adjusted by thickening light-emitting layers such as a light-emitting layer 113b_11 and a light-emitting layer 113b_21. Alternatively, the optical path length may be changed by thickening or adding a functional layer such as a hole-transport layer 112b_21.

FIG. 3B illustrates three adjacent light-emitting devices (the light-emitting device 130a, the light-emitting device 130b1, and a light-emitting device 130c) included in a display apparatus of one embodiment of the present invention. The light-emitting devices 130a, 130b1, and 130c emit light of different colors.

The light-emitting device 130c includes an organic compound layer 103c between a first electrode 101c and the second electrode 102 over the insulating layer 175. The organic compound layer 103c has a structure in which a first light-emitting unit 501c and a second light-emitting unit 502c are stacked with an intermediate layer 160c therebetween. Although FIG. 3B illustrates an example in which the two light-emitting units are stacked, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 160c includes a second layer 162c, a third layer 163c, and a first layer 161c. The third layer 163c may be present or absent. The second light-emitting unit 502c includes a second hole-transport layer 112c_2, a second light-emitting layer 113c_2, and a second electron-transport layer 114c_2.

It is assumed here that the light-emitting device 130c emits light whose wavelength is shorter than those of light from the light-emitting devices 130a and 130bl. The distance between the electrodes in the light-emitting device 130c is adjusted by the thicknesses of the first light-emitting layer 113c_1 and the second light-emitting layer 113c_2, which are smaller than those of the light-emitting layers in the other two light-emitting devices.

The second electron-transport layer 114c_2 includes the organic compound having a triazine ring. The first layer 161c includes the organic compound having a phenanthroline ring.

The first light-emitting layer 113c_1 and the second light-emitting layer 113c_2 preferably emit light of similar colors. The light-emitting substance included in the first light-emitting layer 113c_1 and the light-emitting substance included in the second light-emitting layer 113c_2 are preferably compounds whose emission spectra have a difference in maximum peak wavelength less than or equal to 30 nm, further preferably less than or equal to 20 nm, still further preferably less than or equal to 10 nm. It is further preferable that the first light-emitting layer 113c_1 and the second light-emitting layer 113c_2 include the same light-emitting substance.

It is preferable that the first light-emitting layer 113a_1 and the first light-emitting layer 113c_1 be separated from each other and the second light-emitting layer 113a_2 and the second light-emitting layer 113c_2 be separated from each other. It is preferable that the emission color(s) of the first light-emitting layer 113a_1 and the second light-emitting layer 113a_2 be different from the emission color(s) of the first light-emitting layer 113c_1 and the second light-emitting layer 113c_2. It is preferable that the light-emitting substance included in the first light-emitting layer 113a_1 and the light-emitting substance included in the first light-emitting layer 113c_1 be different from each other and the light-emitting substance included in the second light-emitting layer 113a_2 and the light-emitting substance included in the second light-emitting layer 113c_2 be different from each other.

Note that each of the pairs of the hole-injection layers 111a and 111c, the first hole-transport layers 112a_1 and 112c_1, the first electron-transport layers 114a_1 and 114c_1, the intermediate layers 160a and 160c (the second layers 162a and 162c, the third layers 163a and 163c, and the first layers 161a and 161c), and the second hole-transport layers 112a_2 and 112c_2 in this example are separate layers independent of each other between the light-emitting device 130a and the light-emitting device 130c, and the second electron-transport layers 114a_2 and 114c_2 in this example are a continuous layer. In this manner, one light-emitting device may include both continuous and separate layers. This allows the light-emitting device or the display apparatus to balance productivity and characteristics. In particular, the second electron-transport layer 114a_2 and the second electron-transport layer 114c_2 are preferably one continuous layer, in which case both the light-emitting device 130a and the light-emitting device 130c can have favorable characteristics.

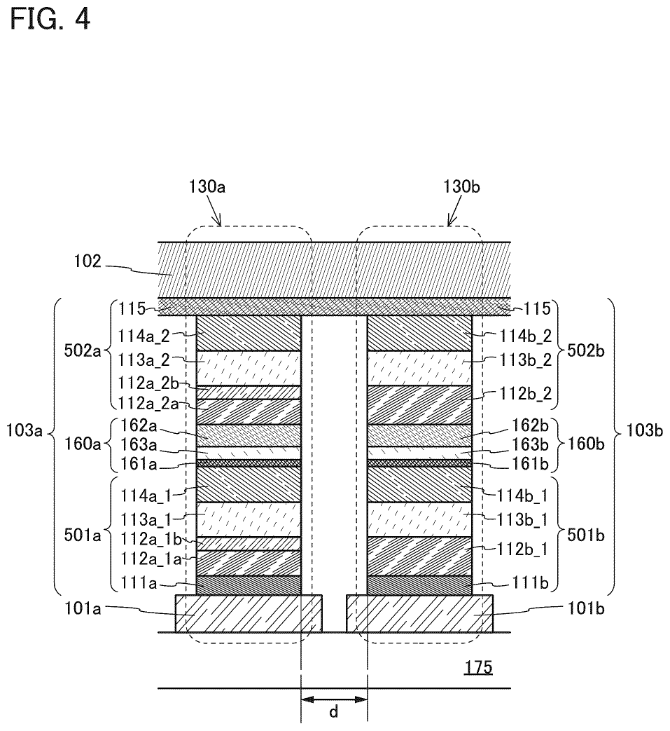

A light-emitting device of one embodiment of the present invention will be described with reference to FIG. 4. FIG. 4 is a schematic view of light-emitting devices, which are modification examples of the light-emitting devices illustrated in FIG. 2 and FIGS. 3A and 3B. The light-emitting devices 130a and 130b are two adjacent light-emitting devices that are formed over the same insulating surface and included in a light-emitting apparatus.

The light-emitting device 130a is located over an insulating layer 175 and includes a first electrode 101a that includes an anode, a second electrode 102 that includes a cathode, and an organic compound layer 103a. The organic compound layer 103a is located between the first electrode 101a and the second electrode 102. In the organic compound layer 103a, a first light-emitting unit 501a and a second light-emitting unit 502a are stacked with an intermediate layer 160a sandwiched therebetween.

The first light-emitting unit 501a includes a first hole-transport layer 112a_1 (a hole-transport layer 112a_1a and a hole-transport layer 112a_1b), a first light-emitting layer 113a_1, and a first electron-transport layer 114a_1. The intermediate layer 160a includes a first layer 161a and a second layer 162a. The second light-emitting unit 502a includes a second hole-transport layer 112a_2 (a hole-transport layer 112a_2a and a hole-transport layer 112a_2b), a second light-emitting layer 113a_2, a second electron-transport layer 114a_2, and an electron-injection layer 115. It can be said that the intermediate layer 160a is positioned between the first light-emitting layer 113a_1 and the second light-emitting layer 113a_2.

In the light-emitting device 130a, the first light-emitting unit 501a preferably includes a hole-injection layer 111a. The intermediate layer 160a can include a third layer 163a between the first layer 161a and the second layer 162a. In the case where the surface of the light-emitting unit on the anode side is in contact with the intermediate layer 160a like that of the second light-emitting unit 502a, the second layer 162a of the intermediate layer 160a, which is positioned on the cathode side, can also function as a hole-injection layer of the second light-emitting unit 502a, and thus, providing the hole-injection layer 111 in such a light-emitting unit is optional. That is, the hole-injection layer 111 is provided as needed for the required performance of the light-emitting device.

Here, the light-emitting device 130b may have a structure different from that of the light-emitting device 130a. For example, the light-emitting device 130b illustrated in FIG. 4 is different from the light-emitting device 130a in the structures of the first hole-transport layer 112a_1 and the second hole-transport layer 112a_2. In the case where different light-emitting materials are used for the light-emitting layers of the light-emitting devices 130a and 130b, layer structures suitable for the respective light-emitting materials are preferably formed. Through structural optimization for each light-emitting device, the characteristics of the light-emitting apparatus as a whole can be improved.

The light-emitting device 130b is located over the insulating layer 175 and includes a first electrode 101b that includes an anode, the second electrode 102 that includes the cathode, and an organic compound layer 103b. The organic compound layer 103b is located between the first electrode 101b and the second electrode 102. In the organic compound layer 103b, a first light-emitting unit 501b and a second light-emitting unit 502b are stacked with an intermediate layer 160b sandwiched therebetween.

The first light-emitting unit 501b includes a first light-emitting layer 113b_1. The intermediate layer 160b includes a first layer 161b and a second layer 162b. The second light-emitting unit 502b includes a second light-emitting layer 113b_2 and the electron-injection layer 115. The above structure can be regarded as a structure in which the intermediate layer 160b is located between the first light-emitting layer 113b_1 and the second light-emitting layer 113b_2.

In the light-emitting device 130b, the first light-emitting unit 501b preferably includes a hole-injection layer 111b, a first hole-transport layer 112b_1, and a first electron-transport layer 114b_1 in addition to the first light-emitting layer 113b_1. The second light-emitting unit 502b preferably includes a second hole-transport layer 112b_2 and a second electron-transport layer 114b_2 in addition to the second light-emitting layer 113b_2 and the electron-injection layer 115. The intermediate layer 160b can include the third layer 163b between the first layer 161b and the second layer 162b. In the case where the surface of the light-emitting unit on the anode side is in contact with the intermediate layer 160b like that of the second light-emitting unit 502b, the second layer 162b of the intermediate layer 160b, which is positioned on the cathode side, can also function as a hole-injection layer of the second light-emitting unit 502b, and thus, providing the hole-injection layer 111 in such a light-emitting unit is optional. That is, the hole-injection layer 111 is provided as needed for the required performance of the light-emitting device.

The light-emitting apparatus of one embodiment of the present invention does not necessarily need to include a light-emitting device having the structure of the light-emitting device 130b and may include a plurality of light-emitting devices having only the structure of the light-emitting device 130a. In the case where the light-emitting devices in the light-emitting apparatus have the same structure, the complexity of the manufacturing apparatus can be reduced.

Although FIG. 4 illustrates an example in which each of the organic compound layers includes two light-emitting units, one embodiment of the present invention is not limited to this example. Each of the organic compound layers may include three or more light-emitting units. When a plurality of light-emitting units are stacked between a pair of electrodes with an intermediate layer sandwiched between the plurality of light-emitting units, the light-emitting device can perform high-luminance light emission with the current density kept low and can have high reliability. In addition, the light-emitting device can have low power consumption.

The light-emitting device 130, the light-emitting device 130a, or the light-emitting device 130b may be fabricated by a lithography method, for example. In other words, part of the organic compound layer in each of the light-emitting devices 130, 130a, and 130b can be fabricated through a processing step by a lithography method. In the case of the light-emitting device fabricated using a lithography method, at least the first light-emitting layer 113_1 or the second light-emitting layer 1132 and the layer(s) that is/are closer to the first electrode 101 than the light-emitting layer is are formed by processing at the same time; consequently, their end portions are aligned or substantially aligned in the perpendicular direction.

The light-emitting device of one embodiment of the present invention that has the structure illustrated in FIG. 4 can have high current efficiency, low energy loss, and favorable characteristics. A display apparatus of one embodiment of the present invention that includes such a light-emitting device can achieve low power consumption, high reliability, high-luminance display, and high visibility. This embodiment can be freely combined with any of the other embodiments.

The structure illustrated in FIG. 4 has a significant effect when used for the tandem light-emitting device of one embodiment of the present invention fabricated by side-by-side patterning. With the tandem structure fabricated by side-by-side patterning, red-, green-, and blue-light-emitting devices have different layer structures in which layers are stacked, and a layer structure is further stacked on another layer structure in each light-emitting device, which involves use of many kinds of materials or a large amount of materials, as described later. In view of the problems, a structure in which the same fused rings are included, a structure in which the same fused rings are bonded at different positions, or a structure in which structurally isomeric fused rings are included is employed for the plurality of layers as described above, thereby achieving the adjustment of T_{g} and the effect on physical properties, such as adjustment of the carrier-transport properties, in addition to a reduction in raw material costs or simplification of synthesis steps. Furthermore, by using such materials for the tandem light-emitting device of one embodiment of the present invention fabricated by side-by-side patterning, a light-emitting apparatus suitable for mass production can be formed.

### Embodiment 2

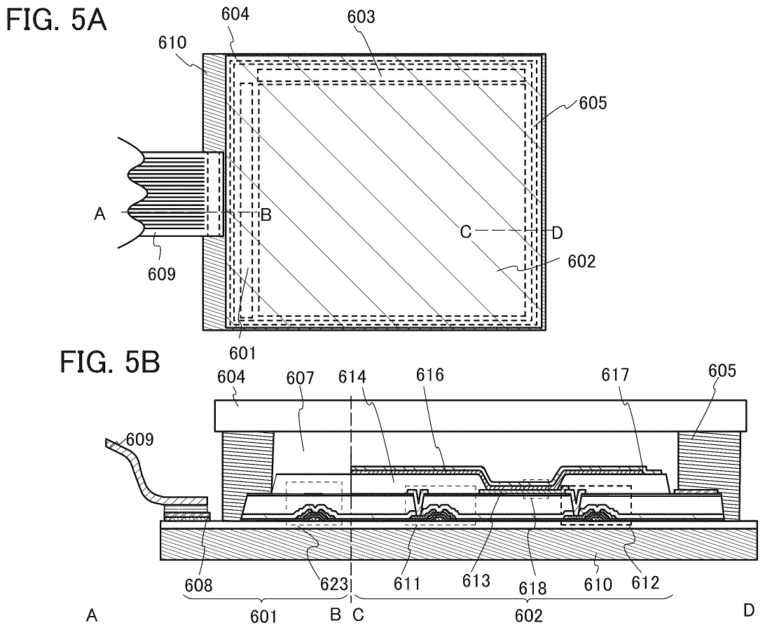

In this embodiment, a display apparatus manufactured using the light-emitting device described in Embodiment 1 is described with reference to FIGS. 5A and 5B. Note that FIG. 5A is a top view of the display apparatus, and FIG. 5B is a cross-sectional view taken along the lines A-B and C-D in FIG. 5A. This display apparatus includes a driver circuit portion (source line driver circuit) 601, a pixel portion 602, and a driver circuit portion (gate line driver circuit) 603, which are to control light emission of the light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display apparatus in this specification includes, in its category, not only the display apparatus itself but also the display apparatus provided with the FPC or the PWB.

Next, a cross-sectional structure is described with reference to FIG. 5B. The driver circuit portions and the pixel portion are formed over an element substrate 610; FIG. 5B illustrates the source line driver circuit 601, which is a driver circuit portion, and one pixel in the pixel portion 602.

The element substrate 610 may be a substrate formed of glass, quartz, an organic resin, a metal, an alloy, or a semiconductor or a plastic substrate formed of fiber reinforced plastic (FRP), polyvinyl fluoride (PVF), polyester, or an acrylic resin.

The structure of transistors used in the pixels and the driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and the driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which no grain boundary can be observed between the adjacent crystal parts.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of each pixel is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with a CMOS circuit, a PMOS circuit, or an NMOS circuit. Although a driver integrated type in which the driver circuit is formed over the substrate is described in this embodiment, the driver circuit is not necessarily formed over the substrate, and can be formed outside.

The pixel portion 602 includes a plurality of pixels including a switching FET 611, a current controlling FET 612, and a first electrode 613 electrically connected to a drain of the current controlling FET 612. One embodiment of the present invention is not limited to the structure, and the pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an organic compound layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). For the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film including silicon, an indium oxide film including zinc oxide at 2 wt % to 20 wt %, a titanium nitride film, a chromium film, a tungsten film, a Zn film, a Pt film, or the like, a stack of a titanium nitride film and a film including aluminum as its main component, a stack of three layers of a titanium nitride film, a film including aluminum as its main component, and a titanium nitride film, or the like can be used.

The organic compound layer 616 is formed by any of a variety of methods such as an evaporation method using an evaporation mask, an ink-jet method, and a spin coating method. The organic compound layer 616 has the structure described in Embodiment 1. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the organic compound layer 616, and the second electrode 617. The light-emitting device is the light-emitting device described in Embodiment 1. In the display apparatus of this embodiment, the pixel portion, which includes a plurality of light-emitting devices, may include both the light-emitting device described in Embodiment 1 and a light-emitting device having a different structure.

The sealing substrate 604 is bonded to the element substrate 610 with the sealing material 605, so that a light-emitting device 618 is provided in the space 607 surrounded by the element substrate 610, the sealing substrate 604, and the sealing material 605. The space 607 may be filled with a filler and may be filled with an inert gas (such as nitrogen or argon), or the sealing material. It is preferable that the sealing substrate be provided with a recessed portion and a drying agent be provided in the recessed portion, in which case deterioration due to the influence of moisture can be inhibited.

An epoxy-based resin or glass frit is preferably used for the sealing material 605. It is desirable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, an acrylic resin, or the like can be used.

Although not illustrated in FIGS. 5A and 5B, a protective film may be provided over the second electrode 617. As the protective film, an organic resin film or an inorganic insulating film may be formed. The protective film may be formed so as to cover an exposed portion of the sealing material 605.

The protective film can be formed using a material that does not easily transmit an impurity such as water. Thus, diffusion of an impurity such as water from the outside into the inside can be effectively inhibited.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a film formation method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display apparatus manufactured using the light-emitting device described in Embodiment 1 can be obtained.

The display apparatus in this embodiment is manufactured using the light-emitting device described in Embodiment 1 and thus can have favorable characteristics. Specifically, since the light-emitting device described in Embodiment 1 has high emission efficiency, the display apparatus can achieve low power consumption. Since the light-emitting device described in Embodiment 1 has high reliability, the display apparatus can be highly reliable. In addition, since the light-emitting device described in Embodiment 1 can have favorable chromaticity and high color purity, the display apparatus can achieve high display quality.

This embodiment can be freely combined with any of the other embodiments.

### Embodiment 3

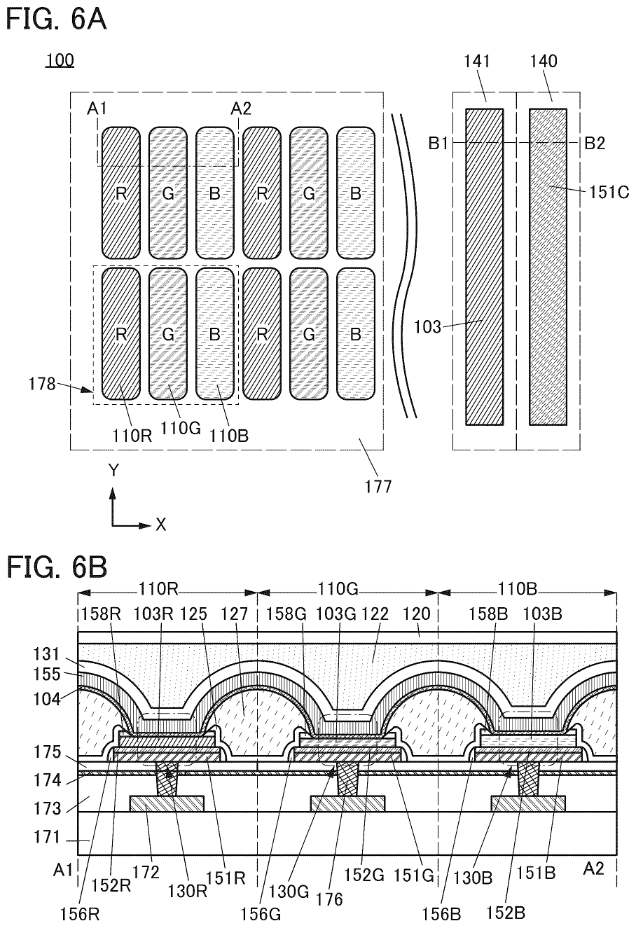

As illustrated in FIGS. 6A and 6B, a plurality of light-emitting devices 130 are formed over the insulating layer 175 to constitute a display apparatus. In this embodiment, the display apparatus of one embodiment of the present invention will be described in detail.

A display apparatus 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 6A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 6A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 6B is an example of a cross-sectional view along the dashed-dotted line A1-A2 in FIG. 6A. As illustrated in FIG. 6B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 6B illustrates cross sections of a plurality of inorganic insulating layers 125 and a plurality of insulating layers 127, the inorganic insulating layers 125 are preferably connected to each other and the insulating layers 127 are preferably connected to each other when the display apparatus 100 is seen from above. That is, the inorganic insulating layer 125 and the insulating layer 127 preferably include opening portions over first electrodes.

In FIG. 6B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom emission type.

The light-emitting device 130R has a structure described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and a common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, the stacked-layer structure of the organic compound layer 103R and the common layer 104 corresponds to the organic compound layer 103.

The light-emitting device 130G has a structure described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, the stacked-layer structure of the organic compound layer 103G and the common layer 104 corresponds to the organic compound layer 103.

The light-emitting device 130B has a structure described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, the stacked-layer structure of the organic compound layer 103B and the common layer 104 corresponds to the organic compound layer 103.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an EL film and processing the EL film by a lithography method.

In the display apparatus of one embodiment of the present invention, the first electrode (pixel electrode) of the light-emitting device preferably has a stacked-layer structure. For example, in the example illustrated in FIG. 6B, the first electrode of the light-emitting device 130 is a stack of the conductive layer 151 (the conductive layer 151R, the conductive layer 151G, and the conductive layer 151B) and the conductive layer 152 (the conductive layer 152R, the conductive layer 152G, and the conductive layer 152B). In the case where the display apparatus 100 is of a top-emission type and the pixel electrode of the light-emitting device 130 functions as the anode, for example, the conductive layer 151 preferably has high reflectance for visible light, and the conductive layer 152 preferably has a visible-light-transmitting property and a high work function. In the case where the display apparatus 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 with high reflectance for visible light and the conductive layer 152 with a high work function, the light-emitting device 130 can have high light extraction efficiency and a low driving voltage.

In the case where the conductive layer 151 has high reflectance for visible light, the visible light reflectance of the conductive layer 151 is preferably higher than or equal to 40% and lower than or equal to 100%, or higher than or equal to 70% and lower than or equal to 100%, for example. When used as an electrode having a visible-light-transmitting property, the conductive layer 152 preferably has a visible light transmittance higher than or equal to 40%, for example.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, an indium tin oxide, an indium zinc oxide, zinc oxide, zinc oxide containing gallium, titanium oxide, an indium zinc oxide containing gallium, an indium zinc oxide containing aluminum, an indium tin oxide containing silicon, an indium zinc oxide containing silicon, and the like. In particular, an indium tin oxide containing silicon can be suitably used for the conductive layer 152 because of having a work function higher than or equal to 4.0 eV, for example.

The conductive layer 151 and the conductive layer 152 may each be a stack of a plurality of layers including different materials. In that case, one layer of the stack of the conductive layer 151 may include one of materials that can be used for the conductive layer 152, or one layer of the stack the conductive layer 152 may include one of materials that can be used for the conductive layer 151. In the case where the conductive layer 151 is a stack of two or more layers, for example, a layer in contact with the conductive layer 152 can be formed using any of the materials that can be used for the conductive layer 152.

The conductive layer 151 or the conductive layer 152 preferably has a tapered side surface. Specifically, the side surface of the conductive layer 151 or the conductive layer 152 preferably has a tapered shape with a taper angle less than 90°. In addition, an end portion of an insulating layer 156 (an insulating layer 156R, an insulating layer 156G, or an insulating layer 156B) may also have a tapered shape. Specifically, the end portion of the insulating layer 156 has a tapered shape with a taper angle less than 90°, in which case a component with higher coverage can be provided along a side surface of the insulating layer 156.

The conductive layer 151 may be formed using silver or an alloy containing silver. Silver has a feature of higher reflectance for visible light than titanium. In addition, silver has a feature of being less likely to be oxidized than aluminum, and silver oxide has a feature of lower electrical resistivity than aluminum oxide. Thus, the conductive layer 151 formed using silver or an alloy containing silver can favorably increase the visible light reflectance of the conductive layer 151 and inhibit an increase in the electrical resistance of the pixel electrode due to oxidation. Here, as the alloy containing silver, an alloy of silver, palladium, and copper (also referred to as Ag—Pd—Cu or APC) can be used, for example.

For example, in the case where the light-emitting device 130 has a microcavity structure, use of silver or an alloy containing silver, i.e., a material with high reflectance for visible light, for the conductive layer 151 can favorably increase the light extraction efficiency of the display apparatus 100.

When the conductive layer 152 has a stacked-layer structure, the visible light reflectance (e.g., reflectance for light with a predetermined wavelength longer than or equal to 400 nm and shorter than 750 nm) of the stacked-layer structure is made different from that of the conductive layer 151, so that a microcavity structure can be formed in combination with the conductive layer 151.

The conductive layer 151 or 152 having a stacked-layer structure of a plurality of layers as described above can improve the characteristics of the display apparatus. For example, the display apparatus 100 can have high light extraction efficiency and high reliability.

The conductive layer 151 can be formed by a lithography method. Specifically, first, a conductive film to be the conductive layer 151 is formed. Next, a resist mask is formed over the conductive film to be the conductive layer 151. Then, the conductive film in the region not overlapping with the resist mask is removed by etching. Here, when the conductive film is processed under conditions where the resist mask is easily recessed (reduced in size) as compared to the case where the conductive layer 151 is formed such that the side surface does not have a tapered shape (i.e., the conductive layer 151 is formed to have a perpendicular side surface), the side surface of the conductive layer 151 can have a tapered shape.

The conductive layer 152 may be processed by a lithography method at the same time as the conductive layer 151. In that case, a side surface of the conductive layer 152 can also have a tapered shape.

Here, when the conductive film is processed under conditions where the resist mask is easily recessed (reduced in size), the conductive film might be easily processed in the horizontal direction. That is, the etching sometimes might become isotropic as compared to the case where the conductive layer 151 is formed to have a perpendicular side surface.

In the case where the conductive layer 151 is a stack of a plurality of layers formed of different materials, the plurality of layers sometimes differ in processability in the horizontal direction.

In view of the above, the insulating layer 156 is provided as illustrated in FIG. 6B, inhibiting occurrence of corrosion in the conductive layer 151. Thus, the display apparatus 100 can be manufactured by a method with a high yield. Moreover, the display apparatus 100 can have high reliability since generation of defects is inhibited therein.

Here, the insulating layer 156 preferably has a curved surface as illustrated in FIG. 6B. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the display apparatus 100 can be fabricated by a high-yield method. Moreover, the display apparatus 100 can have high reliability since generation of defects is inhibited therein.

The structure described in this embodiment can be used in combination with any of the structures described in other embodiments as appropriate.

### Embodiment 4

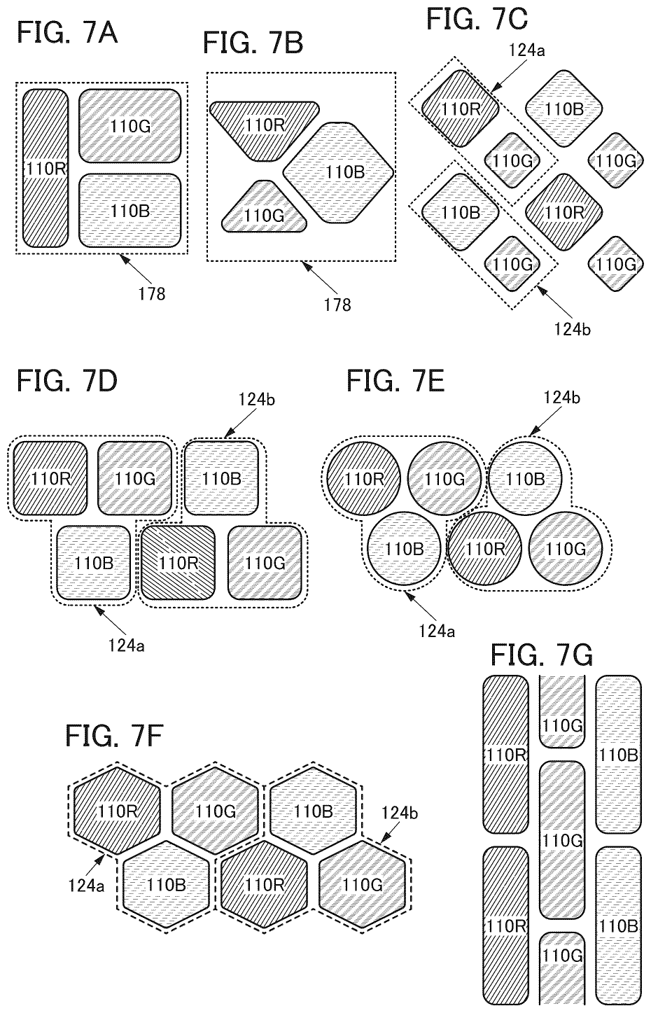

In this embodiment, the light-emitting apparatus of one embodiment of the present invention will be described with reference to FIGS. 7A to 7G and FIGS. 8A to 81.

### [Pixel Layout]

In this embodiment, pixel layouts different from that in FIG. 6A will be mainly described. There is no particular limitation on the subpixel layout, and a variety of methods can be employed. Examples of the subpixel layout include stripe layout, S-stripe layout, matrix layout, delta layout, Bayer layout, and PenTile layout.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 7A employs S-stripe layout. The pixel 178 illustrated in FIG. 7A includes three subpixels, the subpixel 110R, the subpixel 110G, and the subpixel 110B.

The pixel 178 illustrated in FIG. 7B includes the subpixel 110R whose top surface has a rough trapezoidal or rough triangle shape with rounded corners, the subpixel 110G whose top surface has a rough trapezoidal or rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 7C employ PenTile layout. FIG. 7C illustrates an example in which the pixels 124a including the subpixels 110R and 110G and the pixels 124b including the subpixels 110G and 110B are alternately arranged.

The pixels 124a and 124b illustrated in FIGS. 7D to 7F employ delta layout. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 7D illustrates an example where the top surface of each subpixel has a rough tetragonal shape with rounded corners. FIG. 7E illustrates an example where the top surface of each subpixel is circular. FIG. 7F illustrates an example where the top surface of each subpixel has a rough hexagonal shape with rounded corners.

In FIG. 7F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 7G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 7A to 7G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R emitting red light, and the subpixel 110R may be the subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Therefore, the resist film is insufficiently cured in some cases depending on the upper temperature limit of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

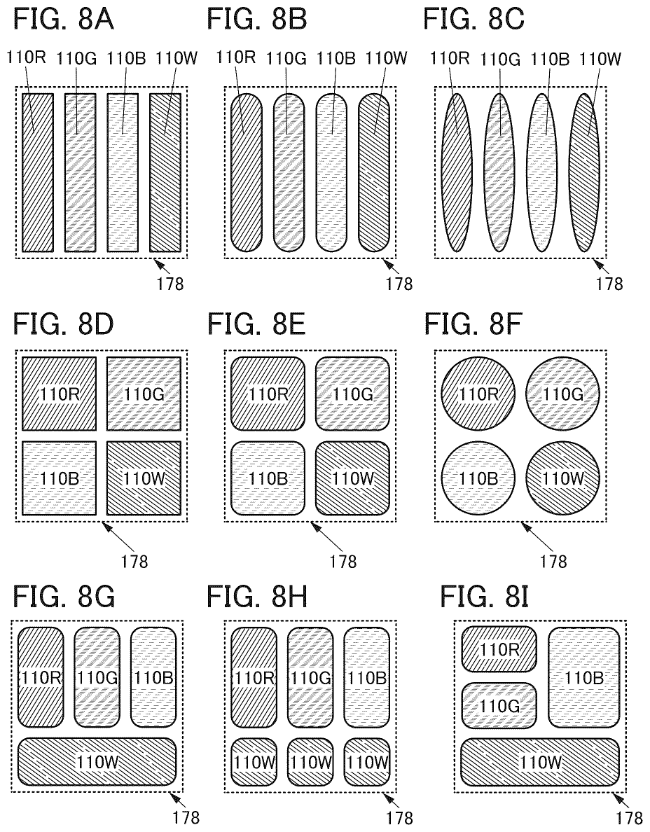

As illustrated in FIGS. 8A to 8I, the pixel can include four types of subpixels.

The pixels 178 illustrated in FIGS. 8A to 8C employ stripe layout.

FIG. 8A illustrates an example where each subpixel has a rectangular top surface shape. FIG. 8B illustrates an example where each subpixel has a top surface shape formed by combining two half circles and a rectangle. FIG. 8C illustrates an example where each subpixel has an elliptical top surface shape.

The pixels 178 illustrated in FIGS. 8D to 8F employ matrix layout.

FIG. 8D illustrates an example where each subpixel has a square top surface shape. FIG. 8E illustrates an example where each subpixel has a substantially square top surface shape with rounded corners. FIG. 8F illustrates an example where each subpixel has a circular top surface shape.

FIGS. 8G and 8H each illustrate an example where one pixel 178 is composed of two rows and three columns.

The pixel 178 illustrated in FIG. 8G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 8H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 8H enables dust that would be produced in the fabrication process, for example, to be removed efficiently. Thus, a light-emitting apparatus having high display quality can be provided.

In the pixel 178 illustrated in each of FIGS. 8G and 8H, the subpixels 110R, 110G, and 110B are arranged in a stripe layout, whereby the display quality can be improved.

FIG. 8I illustrates an example where one pixel 178 is composed of three rows and two columns.

The pixel 178 illustrated in FIG. 8I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 8I, the subpixels 110R, 110G, and 110B are arranged in what is called an S-stripe layout, whereby the display quality can be improved.

The pixel 178 illustrated in each of FIGS. 8A to 8I is composed of four kinds of subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with the other embodiments or the examples. In this specification, in the case where a plurality of structure examples are shown in one embodiment, the structure examples can be combined as appropriate.

### Embodiment 5

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

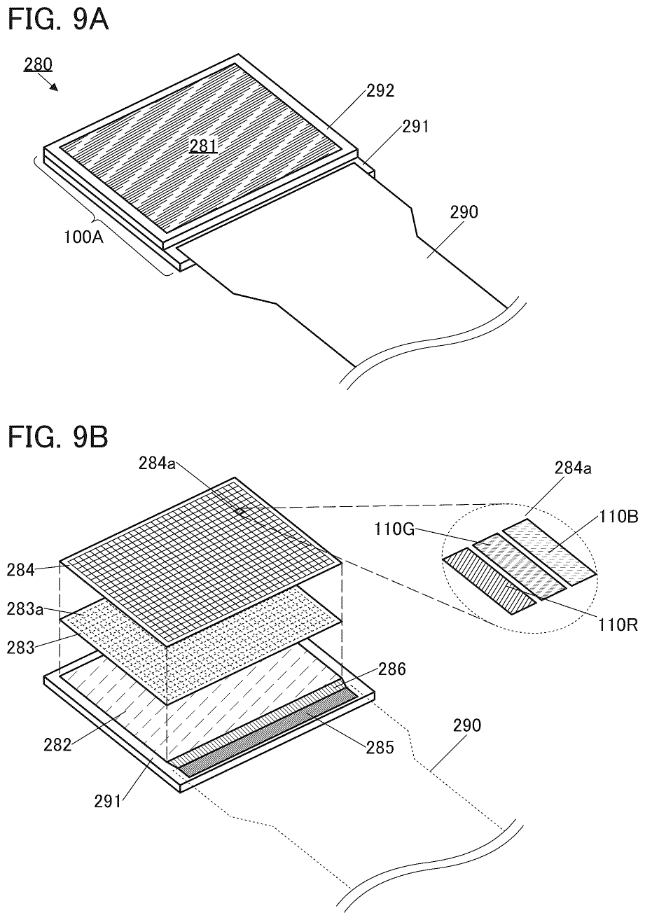

FIG. 9A is a perspective view of a display module 280. The display module 280 includes a display apparatus 100A and an FPC 290. Note that the display apparatus included in the display module 280 is not limited to the display apparatus 100A and may be any of display apparatuses 100B, 100C, 100D, 100D2, 100E, and 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 9B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 9B. The pixels 284a can employ any of the structures described in the above embodiments. FIG. 9B illustrates an example where the pixel 284a has a structure similar to that of the pixel 178 illustrated in FIG. 6A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

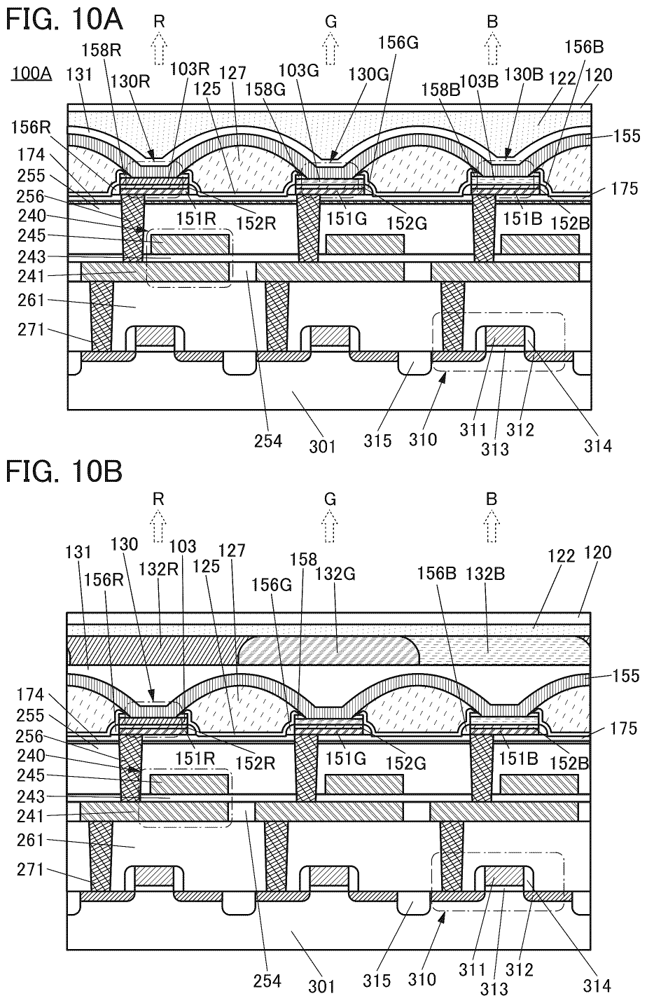

The display apparatus 100A illustrated in FIG. 10A includes a substrate 301, the light-emitting devices 130R, 130G, and 130B, a capacitor 240, and a transistor 310.

The substrate 301 corresponds to the substrate 291 in FIGS. 9A and 9B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover a side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with a side surface of the conductive layer 151R. The insulating layer 156G is provided to include a region overlapping with a side surface of the conductive layer 151G. The insulating layer 156B is provided to include a region overlapping with a side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the organic compound layer 103R of the light-emitting device 130R. A sacrificial layer 158G is positioned over the organic compound layer 103G of the light-emitting device 130G. A sacrificial layer 158B is positioned over the organic compound layer 103B of the light-emitting device 130B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B with the common electrode 155 therebetween. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 9A.

FIG. 10B illustrates a variation example of the display apparatus 100A illustrated in FIG. 10A. The display apparatus illustrated in FIG. 10B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 10B, the light-emitting device 130 can emit white light, for example. The coloring layer 132R, the coloring layer 132G, and the coloring layer 132B can transmit red light, green light, and blue light, respectively, for example.

### [Display Apparatus 100B]

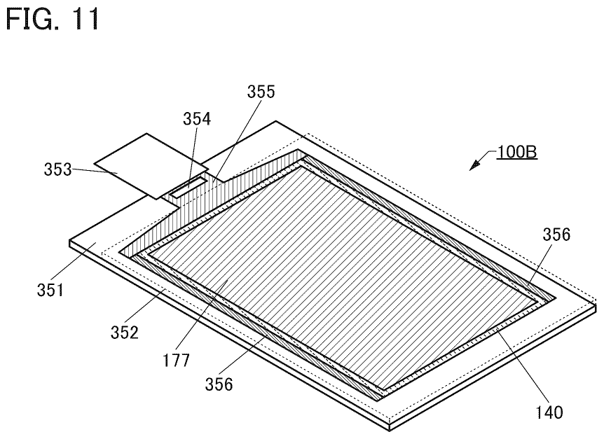

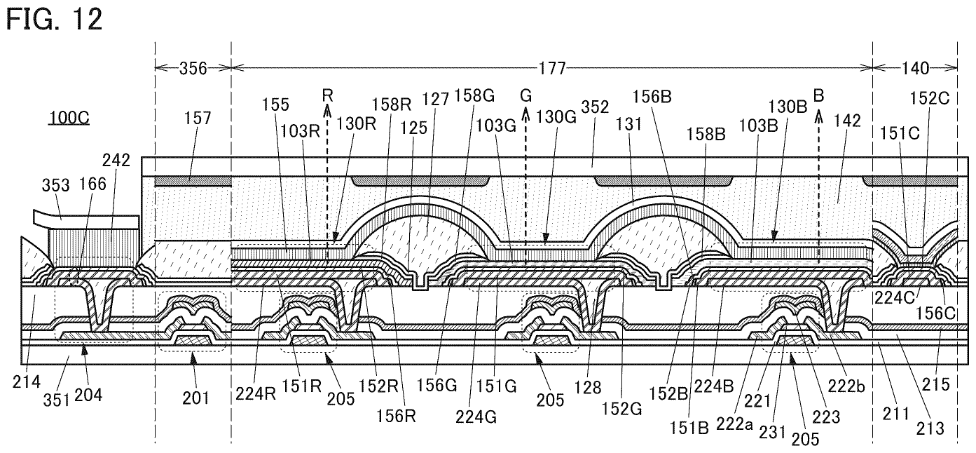

FIG. 11 is a perspective view of the display apparatus 100B, and FIG. 12 is a cross-sectional view of the display apparatus 100C.

In the display apparatus 100B, a substrate 352 and a substrate 351 are bonded to each other. In FIG. 11, the substrate 352 is denoted by a dashed line.

The display apparatus 100B includes the pixel portion 177, the connection portion 140, a circuit 356, a wiring 355, and the like. FIG. 11 illustrates an example where an IC 354 and an FPC 353 are mounted on the display apparatus 100B. Thus, the structure illustrated in FIG. 11 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 11 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 12 illustrates an example of cross sections of part of a region including the FPC 353, part of the circuit 356, part of the pixel portion 177, part of the connection portion 140, and part of a region including an end portion of the display apparatus 100C.

### [Display Apparatus 100C]

The display apparatus 100C illustrated in FIG. 12 includes a transistor 201, a transistor 205, the light-emitting device 130R that emits red light, the light-emitting device 130G that emits green light, the light-emitting device 130B that emits blue light, and the like between the substrate 351 and the substrate 352.

The above embodiment can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B with the common electrode 155 therebetween. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 12, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 12 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 12, the insulating layer 156C is provided to include a region overlapping with a side surface of the conductive layer 151C.

The display apparatus 100C has a top-emission structure. Light from the light-emitting device is emitted toward the substrate 352. For the substrate 352, a material with a high visible-light-transmitting property is preferably used. The pixel electrode includes a material that reflects visible light, and the common electrode 155 includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one, or two or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

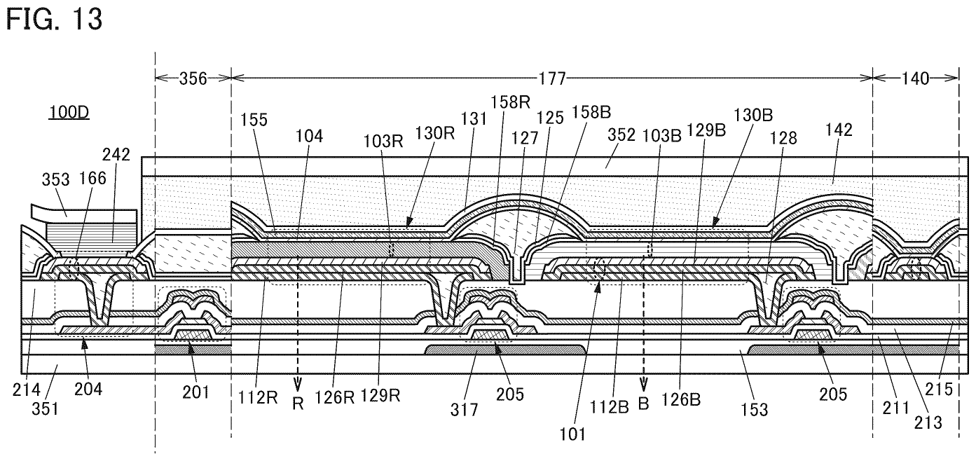

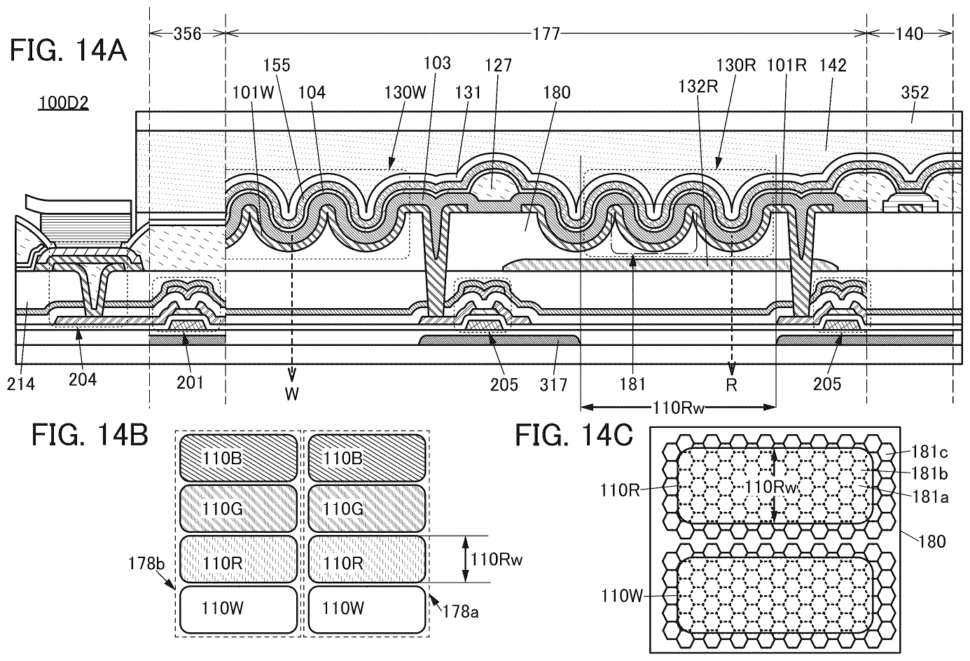

The display apparatus 100D illustrated in FIG. 13 differs from the display apparatus 100C illustrated in FIG. 12 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 13 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the common electrode 155.

Although not illustrated in FIG. 13, the light-emitting device 130G is also provided.

Although FIG. 13 and the like illustrate an example where the top surface of the layer 128 includes a flat portion, the shape of the layer 128 is not particularly limited.

### [Display Apparatus 100D2]

The display apparatus 100D2 illustrated in FIG. 14A is an example of a bottom-emission display apparatus different from the display apparatus 100D illustrated in FIG. 13. The display apparatus 100D2 is different from the display apparatus 100D in including an organic resin layer 180. Note that in the drawings, reference numerals of some of the components that are shown in FIG. 13 are omitted; for the details of the components, the description made with reference to FIG. 13 can be referred to.

FIG. 14B shows a top-view layout of the pixels 178 (pixels 178a and 178b) each including the subpixels 110 (the subpixels 110R, 110G, 110B, and 110W), and FIG. 14C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 14A, the organic resin layer 180 is provided over the insulating layer 214. As illustrated in FIG. 14C and the region surrounded by the dashed-dotted line in FIG. 14A, the organic resin layer 180 includes a depressed portion 181 (depressed portions 181a and 181b) having a curved surface at least in a region where the subpixel is formed. Note that the depressed portion 181 outside the light-emitting region, like a depressed portion 181c, may also be provided. With the depressed portion 181c, light emission caused in a region overlapping with the light-blocking layer 317 or light that has progressed to the region overlapping with the light-blocking layer 317 can be refracted and extracted from the light-emitting region, whereby emission efficiency can be improved.

A plurality of the depressed portions 181 may be formed in a matrix. The depressed portions 181a and 181b may be provided in contact with each other or may be provided to have a flat surface therebetween.

Although the top-view shape and the cross-sectional shape of the depressed portion are hexagonal (FIG. 14C) and semicircular (FIG. 14A), respectively, other shapes may be employed as needed. Examples of the top-view shape of the depressed portion include polygons such as a triangle, a tetragon (including a rectangle and a square), and a pentagon; these polygons with rounded corners; an ellipse; and a circle.

An insulating layer including an organic material can be used as the organic resin layer 180. Examples of a material that can be used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For example, the organic resin layer 180 can be formed using a resin that can be used as a color filter transmitting red, blue, or green light and absorbing light of the other colors or a resin that contains carbon black as a pigment and functions as a black matrix.

The first electrode 101 (a first electrode 101R and a first electrode 101W) is over the organic resin layer 180, the organic compound layer 103 is over the first electrode 101, and the common electrode 155 is over the organic compound layer 103. End portions of the first electrode 101 and the organic compound layer 103 may be covered with the insulating layer 127.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. The common layer 104 formed over the organic compound layer 103 also has a depressed portion along the depressed portion of the organic compound layer 103. The common electrode 155 formed over the common layer 104 also has a depressed portion along the depressed portion of the common layer 104. That is, the depressed portions of the organic resin layer 180, the first electrode 101, the organic compound layer 103, common layer 104, and the common electrode 155 overlap with each other.

The common layer 104 is over the organic compound layer 103 and the insulating layer 127, and the common electrode 155 is over the common layer 104. The protective layer 131 is provided over the common electrode 155 and bonded to the substrate 352 with the adhesive layer 142.

Although FIG. 14A illustrates the light-emitting device 130R and a light-emitting device 130W and does not illustrate the light-emitting devices 130G and 130B, the light-emitting devices 130G and 130B are also provided.

The light-emitting device of one embodiment of the present invention including the above-described organic resin layer 180 has a structure described in the above embodiment. Accordingly, an organic semiconductor device with a low driving voltage and favorable characteristics can be provided.

### [Display Apparatus 100E]

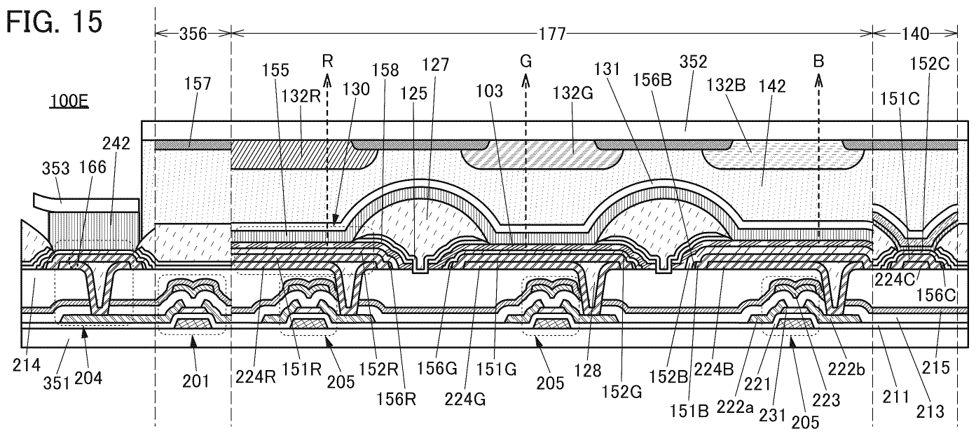

The display apparatus 100E illustrated in FIG. 15 is a variation example of the display apparatus 100C illustrated in FIG. 12 and differs from the display apparatus 100C mainly in including the coloring layers 132R, 132G, and 132B.

In the display apparatus 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display apparatus 100E, the coloring layer 132R, the coloring layer 132G, and the coloring layer 132B can transmit red light, green light, and blue light, respectively, for example. Note that in the display apparatus 100E, the coloring layers 132R, 132G, and 132B may be provided between the protective layer 131 and the adhesive layer 142.

### [Display Apparatus 100E2]

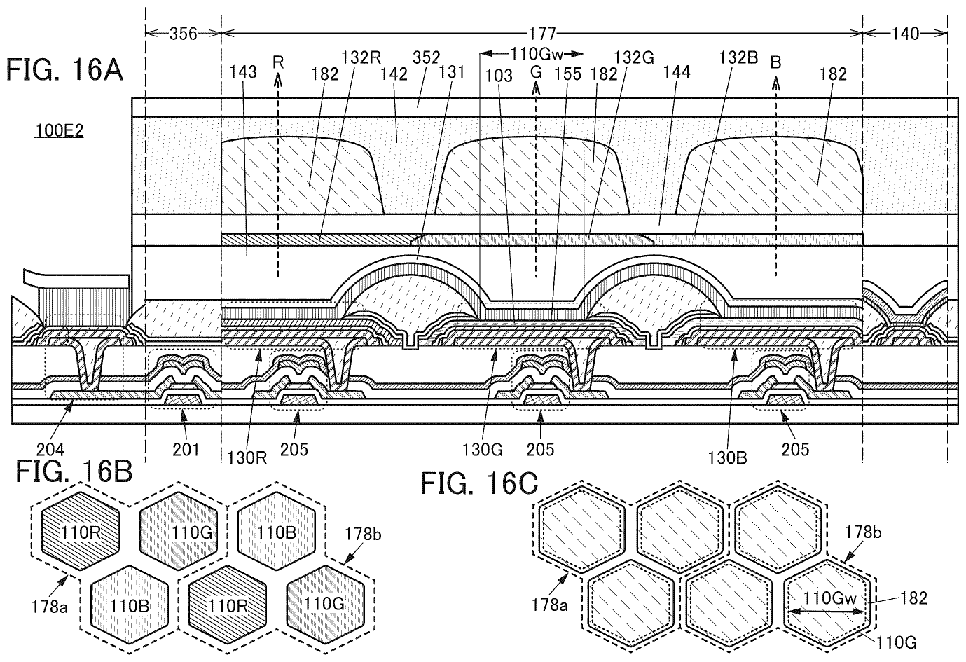

The display apparatus 100E2 illustrated in FIG. 16A is a variation example of the display apparatus 100E illustrated in FIG. 15 and includes microlenses 182 over the coloring layers 132R, 132G, and 132B. Note that in the drawings, reference numerals of some of the components that are shown in FIG. 15 are omitted; for the details of the components, the description made with reference to FIG. 15 can be referred to.

FIG. 16B shows a top-view layout of the pixels 178 (pixels 178a and 178b) each including the subpixels 110 (subpixels 110R, 110G, and 110B), and FIG. 16C shows a top view of the microlenses 182 in a region where the subpixels 110R, 110G, and 110B of the pixels 178 are formed. Note that the width of the region where the common electrode 155 and the organic compound layer 103 are in contact with each other corresponds to a width 110Gw in the light-emitting region of the subpixel 110G.

In the display apparatus 100E2 illustrated in FIG. 16A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 16C, the microlens 182 is preferably provided for each of the subpixels in the region where the subpixels are formed.

Although the top-view shape of the microlens 182 is hexagonal in FIG. 16C, a different shape may be employed as needed. Examples of the top-view shape of the microlens 182 include polygons such as a triangle, a tetragon (including a rectangle and a square), and a pentagon; these polygons with rounded corners; an ellipse; and a circle.

The microlenses 182 can be formed using a material similar to that for the organic resin layer 180.

The microlens is suitably used in the light-emitting device of one embodiment of the present invention (e.g., a light-emitting device or a tandem light-emitting device fabricated by side-by-side patterning using the above-described fused heteroaromatic ring containing nitrogen). Since the microlens can condense light and increase light extraction efficiency, the light emission performance of the whole display apparatus can be increased in combination with the microcavity effect described above. Furthermore, the use of the protective layer 131 or the sealing film over the protective layer 131 improves characteristics and resistance to impurities, which is preferable.

When a region between two adjacent microlenses overlaps with a region between two adjacent light-emitting devices as illustrated in FIGS. 16A to 16C, the effect of the microlenses can be enhanced. It is also suitable that a region where two adjacent coloring layers (e.g., 132B and 132G) overlap with each other, the region between the microlenses, and the region between the light-emitting devices overlap with each other. It is also preferable that the insulating layer 127 overlap with the region where the coloring layers overlap with each other, the region between the microlenses, and the region between the light-emitting devices. The regions preferably overlap with the protective layer 131 or the sealing film over the protective layer 131. Although the region between the microlenses might serve as a path through which impurities enter the light-emitting device, the protective layer 131 or the sealing film can inhibit entry of impurities.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances in this embodiment each include the display apparatus of one embodiment of the present invention in a display portion. The display apparatus of one embodiment of the present invention has high display performance and can be easily increased in resolution and definition. Thus, the display apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display apparatus of one embodiment of the present invention can have high resolution, and thus can be favorably used for an electronic appliance having a relatively small display portion. Examples of such an electronic appliance include watch-type and bracelet-type information terminals (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

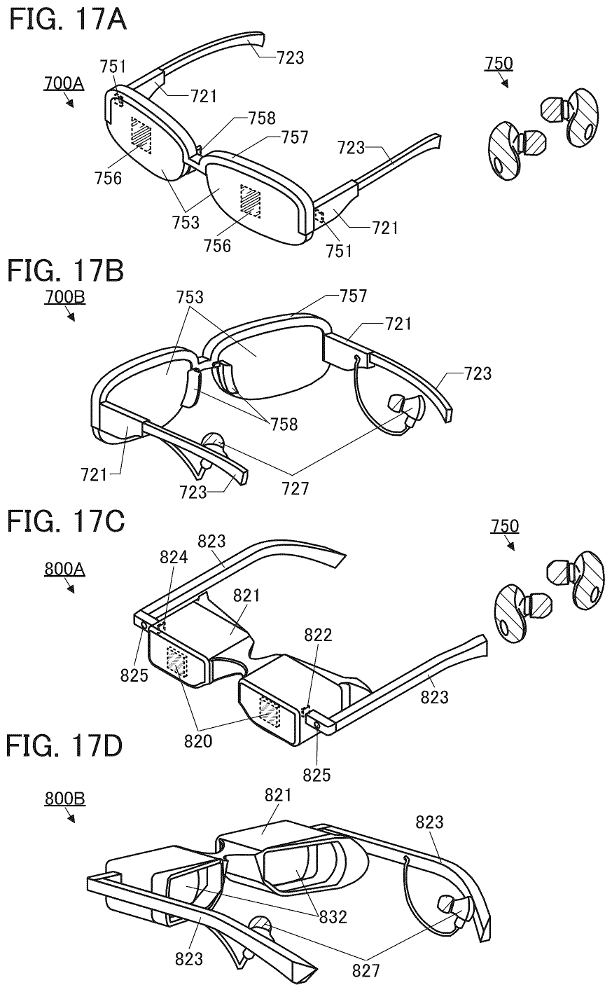

Examples of wearable devices capable of being worn on a head are described with reference to FIGS. 17A to 17D.

An electronic appliance 700A illustrated in FIG. 17A and an electronic appliance 700B illustrated in FIG. 17B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 17C and an electronic appliance 800B illustrated in FIG. 17D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 17B includes earphone portions 727. Part of a wiring that connects the earphone portion 727 and the control portion may be positioned inside the housing 721 or the wearing portion 723.

Similarly, the electronic appliance 800B illustrated in FIG. 17D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

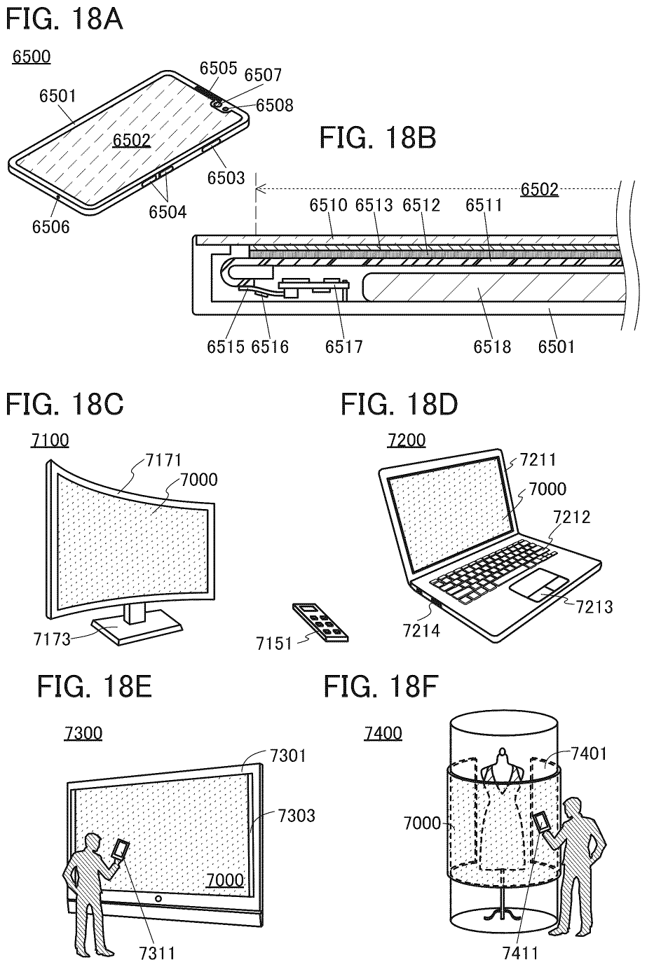

An electronic appliance 6500 illustrated in FIG. 18A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic appliance is obtained.

FIG. 18B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 18C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, a highly reliable electronic appliance is obtained.

Operation of the television device 7100 illustrated in FIG. 18C can be performed with an operation switch provided in the housing 7171 and a separate remote control 7151.

FIG. 18D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic appliance is obtained.

FIGS. 18E and 18F illustrate examples of digital signage that can be used for store windows, showcases, and the like.

Digital signage 7300 illustrated in FIG. 18E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 18F illustrates digital signage 7400 attached to a cylindrical pillar 7401. The digital signage 7400 includes the display portion 7000 provided along a curved surface of the pillar 7401.

In FIGS. 18E and 18F, the display apparatus of one embodiment of the present invention can be used in the display portion 7000. Thus, a highly reliable electronic appliance is obtained.

A larger area of the display portion 7000 can increase the amount of information that can be provided at a time. The larger display portion 7000 attracts more attention, so that the effectiveness of the advertisement can be increased, for example.

Specifically, in the case where the display apparatus of one embodiment of the present invention is used for the digital signage 7300 illustrated in FIG. 18E and the digital signage 7400 illustrated in FIG. 18F that display advertisements and the like, the display apparatus being a light-transmitting panel can increase the flexibility of representation in advertising. A light-transmitting display apparatus can be manufactured, for example, by using a wiring and a support member each of which is formed of a conductive film that transmits visible light and adjusting the distance between pixel electrodes. When the pillar 7401 is formed of tempered glass or the like, the pillar 7401 can also be used as a show case.

The tandem light-emitting device of one embodiment of the present invention in addition to the wiring and the support member each of which is formed of the conductive film that transmits visible light can increase the luminance per pixel. That is, favorable display can be performed even when the aperture ratio of the display apparatus is decreased; thus, the light-transmitting property of the display portion of the display apparatus can be increased. Accordingly, such a structure is suitably used in the light-transmitting display apparatus of one embodiment of the present invention.

As illustrated in FIGS. 18E and 18F, it is preferable that the digital signage 7300 or the digital signage 7400 can work with an information terminal 7311 or an information terminal 7411, such as a smartphone that a user has, through wireless communication.

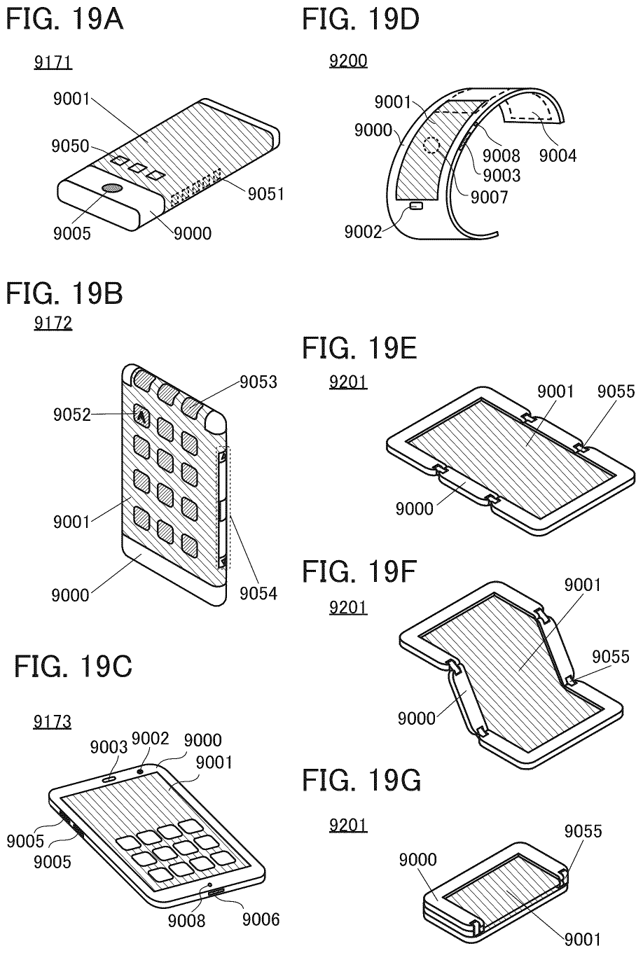

Electronic appliances illustrated in FIGS. 19A to 19G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 19A to 19G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 19A to 19G are described in detail below.

FIG. 19A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 19A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 19B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 19C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 19D is a perspective view of a watch-type portable information terminal 9200. The portable information terminal 9200 can be used as a Smartwatch (registered trademark), for example. The portable information terminal 9200 may include the operation key 9005 as a button for operation on the left side surface of the housing 9000 and the sensor 9007 on the bottom surface of the housing 9000. Although the housing 9000 having a curved bangle shape is illustrated as an example, a belt or the like may be used in combination with the housing 9000 to make the portable information terminal 9200 wearable. The display surface of the display portion 9001 is curved, and an image can be displayed on the curved display surface. A power storage device 9004 may have a curved shape along the housing 9000. The power storage device 9004 has flexibility and can be bent in accordance with a change in shape when the user puts on or takes off the portable information terminal 9200. Note that a charge control IC connected to the power storage device 9004 may be provided. In particular, the tandem light-emitting device of one embodiment of the present invention has low power consumption and can be driven for a long time when used in the display portion 9001. Since the tandem light-emitting device of one embodiment of the present invention has high emission efficiency, high visibility can be obtained even when used outdoors. Furthermore, for example, mutual communication between the portable information terminal 9200 and a headset capable of wireless communication can be performed, and thus hands-free calling is possible. The portable information terminal 9200 can perform mutual data transmission wirelessly with another information terminal and can be charged with wireless power feeding. Note that the connection terminal 9006 may be provided in the housing 9000 so that data transmission and charging operation may be performed by wire.

FIGS. 19E to 19G are perspective views of a foldable portable information terminal 9201. FIG. 19E is a perspective view illustrating the portable information terminal 9201 that is opened. FIG. 19G is a perspective view illustrating the portable information terminal 9201 that is folded. FIG. 19F is a perspective view illustrating the portable information terminal 9201 that is shifted from one of the states in FIGS. 19E and 19G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

In this example, light-emitting devices B-1, B-2, and B-3, light-emitting devices G-1, G-2, and G-3, and light-emitting devices R-1 and R-2 were fabricated, and the characteristics of the light-emitting devices were evaluated. Some of the light-emitting devices are light-emitting devices of embodiments of the present invention. In addition, power consumption of a display apparatus including the light-emitting devices of embodiments of the present invention was estimated.

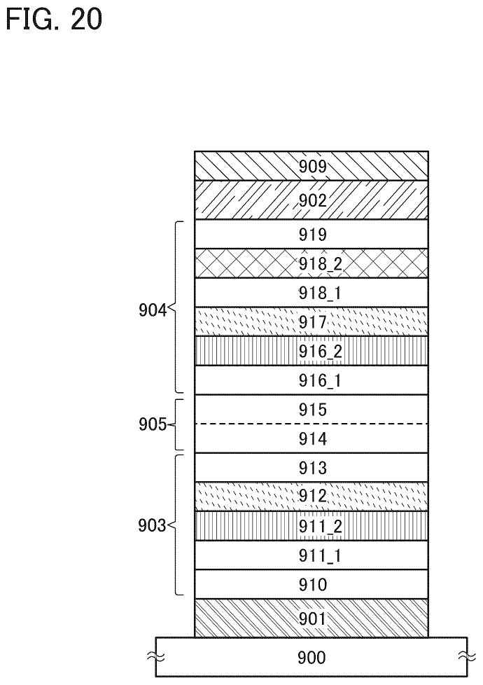

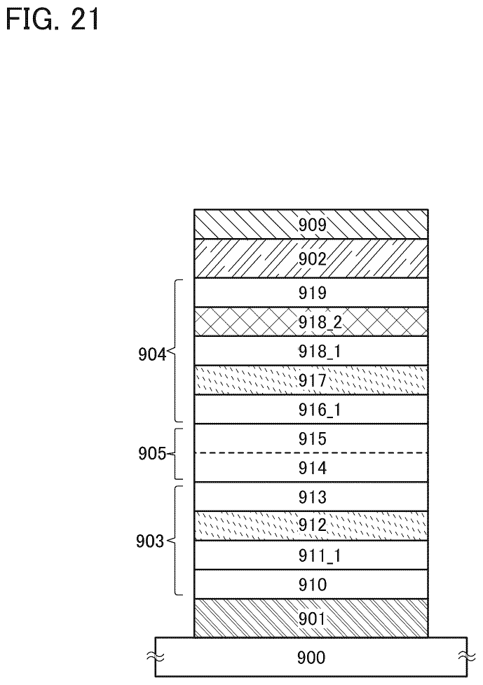

The light-emitting devices each have a tandem structure in which, as illustrated in FIG. 20 or FIG. 21, a first EL layer 903, an intermediate layer 905, a second EL layer 904, and a second electrode 902 are stacked over a first electrode 901 formed over a substrate 900 that is a glass substrate. A cap layer 909 is provided over the second electrode. FIG. 20 illustrates the structure of each of the light-emitting devices B-1 to B-3 and the light-emitting device G-1, and FIG. 21 illustrates the structure of each of the light-emitting devices G-2 and G-3 and the light-emitting devices R-1 and R-2.

As illustrated in FIG. 20, the first EL layer 903 of each of the light-emitting devices B-1 to B-3 and the light-emitting device G-1 has a structure in which a hole-injection layer 910, a first hole-transport layer 911 (a first hole-transport layer 911_1 and a first hole-transport layer 9112), a first light-emitting layer 912, and a first electron-transport layer 913 are stacked in this order. The second EL layer 904 thereof has a structure in which a second hole-transport layer 916 (a second hole-transport layer 916_1 and a second hole-transport layer 916_2), a second light-emitting layer 917, a second electron-transport layer 918 (a second electron-transport layer 918_1 and a second electron-transport layer 918_2), and an electron-injection layer 919 are stacked in this order.

Meanwhile, as illustrated in FIG. 21, the first EL layer 903 of each of the light-emitting devices G-2 and G-3 and the light-emitting devices R-1 and R-2 has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices, the intermediate layer 905 includes an electron-injection buffer region 914 and a layer 915 including an electron-relay region and a charge-generation region.

The light-emitting devices B-1 to B-3 are blue-light-emitting devices. The light-emitting device B-1 is the light-emitting device of one embodiment of the present invention in which a TADF material is used for the first light-emitting layer 912 and the second light-emitting layer 917. The light-emitting devices B-2 and B-3 are each a light-emitting device in which a fluorescent substance is used for the first light-emitting layer 912 and the second light-emitting layer 917. In each of the light-emitting devices B-1 and B-2, the second electron-transport layer 918_2 includes an organic compound having a triazine ring. In the light-emitting device B-3, on the other hand, the second electron-transport layer 918_2 does not include an organic compound having a triazine ring.

The light-emitting devices G-1 to G-3 are green-light-emitting devices. The light-emitting device G-1 is the light-emitting device of one embodiment of the present invention in which a TADF material is used for the first light-emitting layer 912 and the second light-emitting layer 917. The light-emitting devices G-2 and G-3 are each a light-emitting device in which a fluorescent substance is used for the first light-emitting layer 912 and the second light-emitting layer 917. In each of the light-emitting devices G-1 and G-2 the second electron-transport layer 918_2 includes an organic compound having a triazine ring. In the light-emitting device G-3, on the other hand, the second electron-transport layer 918_2 does not include an organic compound having a triazine ring.

The light-emitting devices R-1 and R-2 are red-light-emitting devices in which a phosphorescent substance is used for the first light-emitting layer 912 and the second light-emitting layer 917. In the light-emitting device R-1, the second electron-transport layer 918_2 includes an organic compound having a triazine ring. In the light-emitting device R-2, on the other hand, the second electron-transport layer 9182 does not include an organic compound having a triazine ring.

The light-emitting devices were each fabricated by a continuous vacuum process. Structural formulae of organic compounds used for the light-emitting devices are shown below.

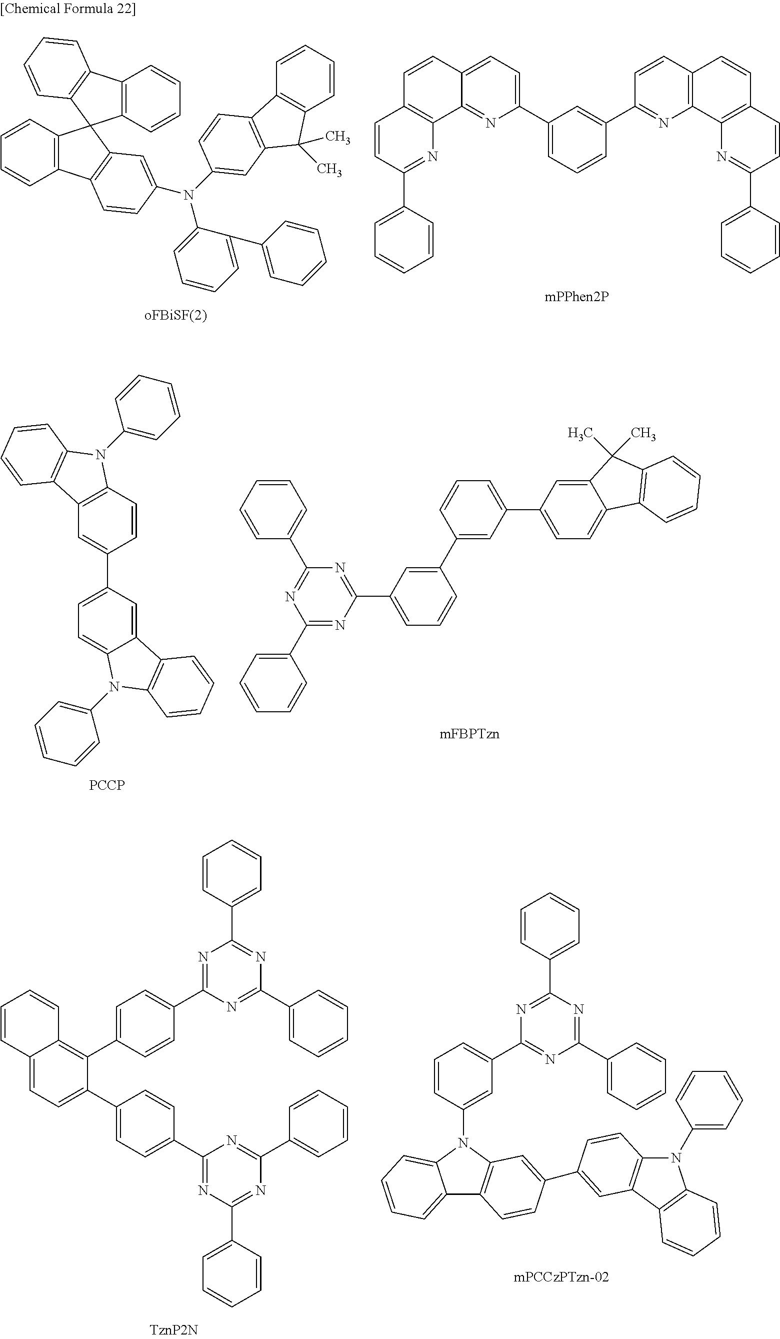

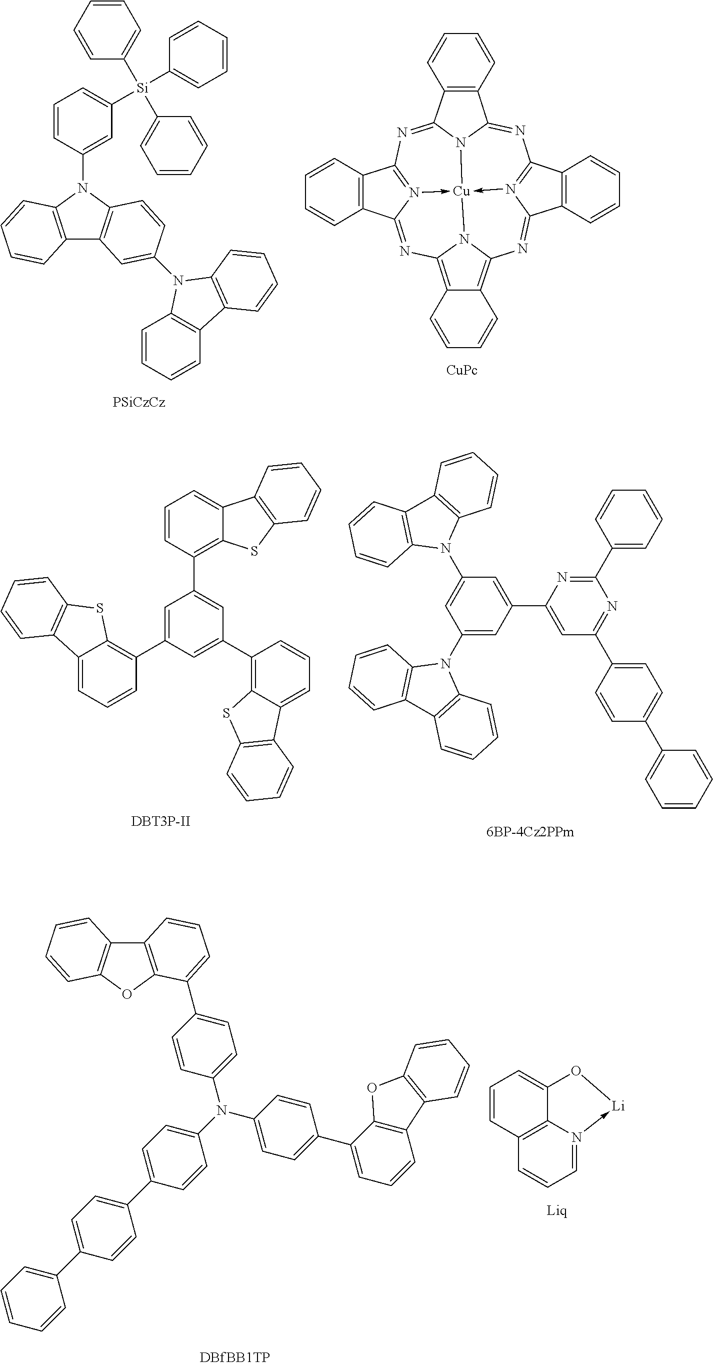

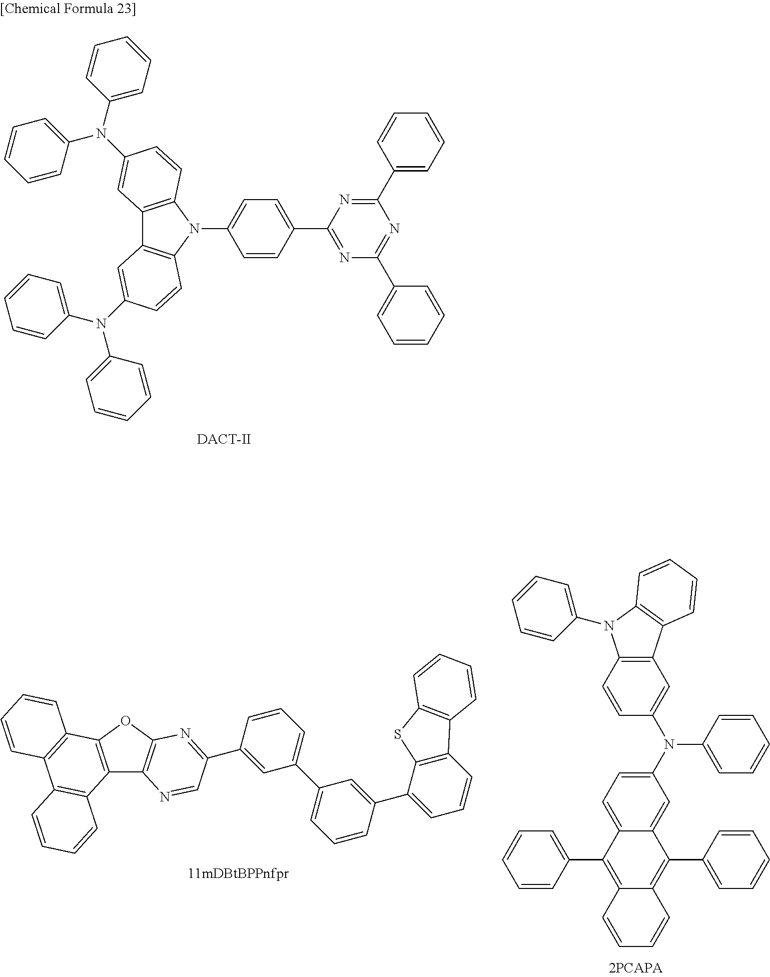

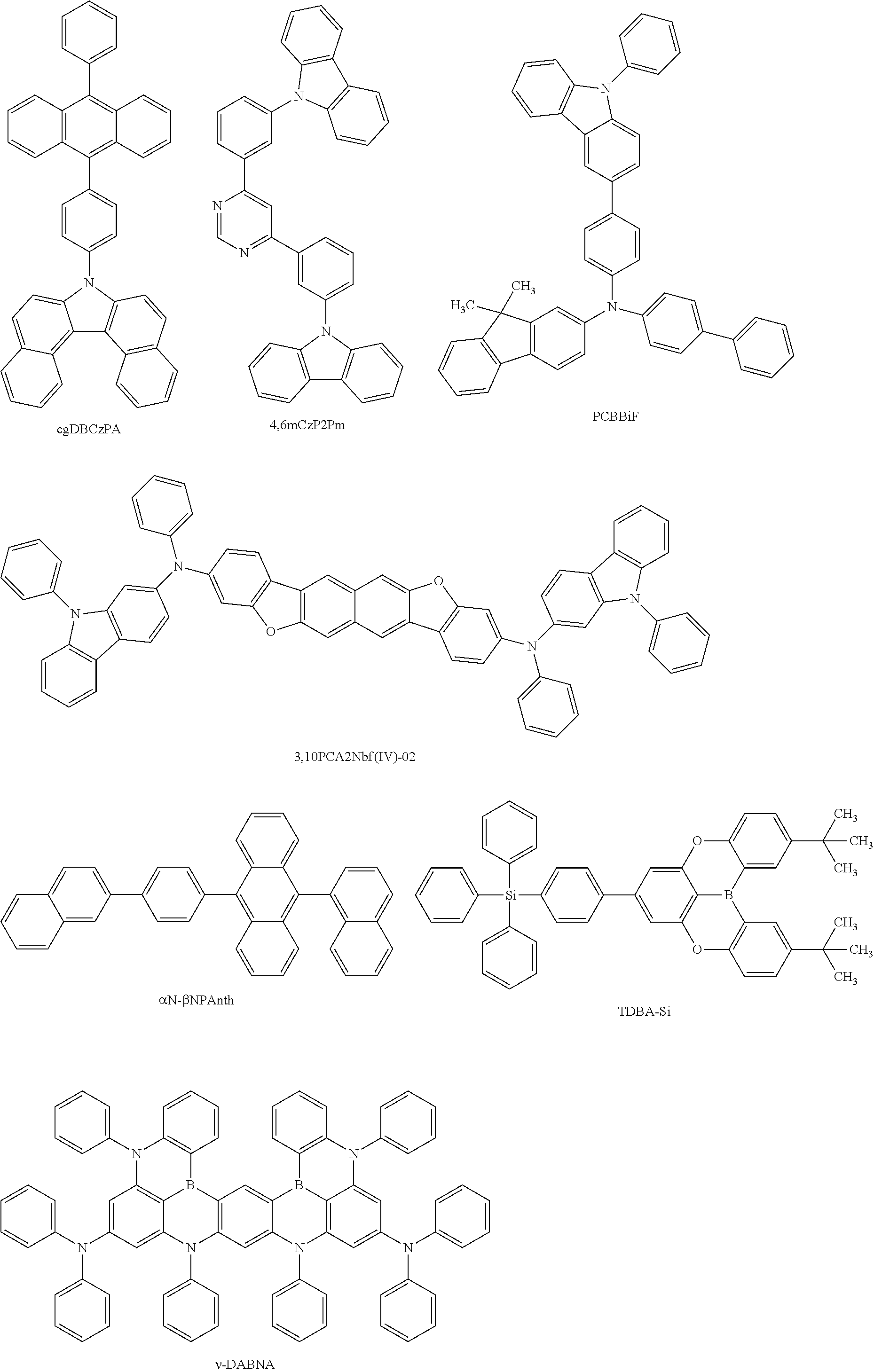

### <Fabrication Method of Light-Emitting Device B-1>

First, as a reflective electrode, silver (Ag) was deposited over a glass substrate to a thickness of 100 nm by a sputtering method, and then, as a transparent electrode, an indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the substrate was washed with water, and baking was performed at 200° C. for one hour.

After that, the substrate was transferred into a vacuum evaporation apparatus where the pressure was reduced to approximately 1×10⁻⁴ Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed over the first electrode 901 by co-evaporation of N-(biphenyl-2-yl)-N-(9,9-dimethylfluoren-2-yl)-9,9′-spirobi[9H-fluoren]-2-amine (abbreviation: oFBiSF(2)) as an organic compound having a triarylamine skeleton and a fluorene ring that is a polycyclic aromatic ring and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layers 911_1 and 911_2) was formed over the hole-injection layer 910. By an evaporation method using resistance heating, the first hole-transport layer 911_1 was formed by evaporation of oFBiSF(2) as an organic compound having a triarylamine skeleton and a fluorene ring that is a polycyclic aromatic ring to a thickness of 65 nm, and then the first hole-transport layer 9112 was formed over the first hole-transport layer 911_1 by evaporation of 9-[3-(triphenylsilyl)phenyl]-3,9′-bi-9H-carbazole (abbreviation: PSiCzCz) as an organic compound having a carbazole ring that is a π-electron rich heteroaromatic ring and having no triarylamine skeleton to a thickness of 5 nm.

Next, the first light-emitting layer 912 was formed over the first hole-transport layer 911. The first light-emitting layer 912 was formed by co-evaporation of [4-(2,12-di-tert-butyl-5,9-dioxa-13b-boranaphtho[3,2,1-de]anthracen-7-yl)phenyl]triphenylsilane (abbreviation: TDBA-Si) and N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: ν-DABNA) at a weight ratio of 1.0:0.015 to a thickness of 25 nm by an evaporation method using resistance heating.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) as an organic compound having a triazine ring to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) as an organic compound having a phenanthroline ring and lithium oxide (abbreviation: Li₂O) at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF(2) and a fluorine-containing material having an electron-acceptor property with a molecular weight of 672 (OCHD-003) were deposited by co-evaporation at a weight ratio of 1:0.15 to a thickness of 10 nm by an evaporation method using resistance heating. Thus, the layer 915 including the electron-relay region was formed.

Next, the second EL layer 904 was provided over the intermediate layer 905.

First, the second hole-transport layer 916 (the second hole-transport layers 916_1 and 916_2) was formed. After the second hole-transport layer 9161 was formed by evaporation of oFBiSF(2) to a thickness of 55 nm, the second hole-transport layer 9162 was formed over the second hole-transport layer 916_1 by evaporation of PSiCzCz to a thickness of 5 nm.

Next, the second light-emitting layer 917 was formed over the second hole-transport layer 916 by co-evaporation of TDBA-Si and ν-DABNA at a weight ratio of 1.0:0.015 to a thickness of 25 nm by an evaporation method using resistance heating.

Then, the second electron-transport layer 918 (the second electron-transport layers 918_1 and 918_2) was formed over the second light-emitting layer 917. By an evaporation method using resistance heating, the second electron-transport layer 9181 was formed by evaporation of 2-[3′-(9,9-dimethyl-9H-fluoren-2-yl)biphenyl-3-yl]-4,6-diphenyl-1,3,5-triazine (abbreviation: mFBPTzn) as an organic compound having a triazine ring to a thickness of 10 nm, and then the second electron-transport layer 918_2 was formed by co-evaporation of 2,2′-(1,2-naphthalenediyldi-4,1-phenylene)bis[4,6-diphenyl-1,3,5-triazine](abbreviation: TznP2N) as an organic compound having a triazine ring and 8-quinolinolato-lithium (abbreviation: Liq) at a volume ratio of 1:1 to a thickness of 25 nm.

Next, the electron-injection layer 919 was formed over the second electron-transport layer 918 by evaporation of Liq to a thickness of 1 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device B-1 was fabricated.

### <Fabrication Method of Light-Emitting Device B-2>

The light-emitting device B-2 is different from the light-emitting device B-1 in the structures of the first and second light-emitting layers 912 and 917 and the first and second hole-transport layers 911 and 916. Other components were fabricated in a manner similar to that for the light-emitting device B-1.

Specifically, the first and second light-emitting layers 912 and 917 of the light-emitting device B-2 were each formed by co-evaporation of 9-(1-naphthyl)-10-[4-(2-naphthyl)phenyl]anthracene (abbreviation: αN-βNPAnth) and N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02) at a weight ratio of 1:0.015 to a thickness of 25 nm by an evaporation method using resistance heating.

The first hole-transport layer 911 of the light-emitting device B-2 was formed in the following manner: by an evaporation method using resistance heating, the first hole-transport layer 911_1 was formed by evaporation of oFBiSF(2) to a thickness of 50 nm, and then the first hole-transport layer 911_2 was formed over the first hole-transport layer 911_1 by evaporation of N,N-bis[4-(dibenzofuran-4-yl)phenyl]-4-amino-p-terphenyl (abbreviation: DBfBB1TP) that has a triarylamine skeleton to a thickness of 10 nm.

The second hole-transport layer 916 of the light-emitting device B-2 was formed in the following manner: by an evaporation method using resistance heating, the second hole-transport layer 916_1 was formed by evaporation of oFBiSF(2) to a thickness of 45 nm, and then the second hole-transport layer 9162 was formed over the second hole-transport layer 916_1 by evaporation of DBfBB1TP to a thickness of 10 nm.

### <Fabrication Method of Light-Emitting Device B-3>

The light-emitting device B-3 is different from the light-emitting device B-2 in the structure of the second electron-transport layer 918. Other components were fabricated in a manner similar to that for the light-emitting device B-2.

Specifically, the second electron-transport layer 918 of the light-emitting device B-3 was formed over the second light-emitting layer 917 in the following manner: by an evaporation method using resistance heating, the second electron-transport layer 918_1 was formed by evaporation of mFBPTzn to a thickness of 10 nm, and then the second electron-transport layer 918_2 was formed by co-evaporation of 4-[3,5-bis(9H-carbazol-9-yl)phenyl]-2-phenyl-6-(biphenyl-4-yl)pyrimidine (abbreviation: 6BP-4Cz2PPm) as an organic compound having no triazine ring and Liq at a volume ratio of 1:1 to a thickness of 25 nm.

Table 1 lists the structures of the light-emitting devices B-1 to B-3.

TABLE 1

| | | | |
|---|---|---|---|
| Thickness | Light-emitting device | Light-emitting device | Light-emitting device |
| (nm) | B-1 | B-2 | B-3 |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| Second electron-transport layer 918_1 | 10 | mFBPTzn | |
|---|---|---|---|
| Second light-emitting layer 917 | 25 | TDBA-Si:ν-DABNA | αN-βNPAnth:3,10PCA2Nbf(IV)-02 |
| | | (1.0:0.015) | (1:0.015) |
| Second hole-transport layer 916_2 | — | PSiCzCz (5 nm) | DBfBB1TP (10 nm) |
| Second hole-transport layer 916_1 | — | oFBiSF(2) (55 nm) | oFBISF(2) (45 nm) |
| Charge-generation region | 10 | oFBiSF(2):OCHD-003 (1:0.15) | |
| Electron-relay region | 2 | CuPc | |
| Electron-injection buffer region 914 | 5 | mPPhen2P:Li₂O (1:0.02) | |
| First electron-transport layer 913 | 10 | mPCCzPTzn-02 | |
| First light-emitting layer 912 | 25 | TDBA-Si:ν-DABNA | αN-βNPAnth:3,10PCA2Nbf(IV)-02 |
| | | (1.0:0.015) | (1:0.015) |
| First hole-transport layer 911_2 | — | PSiCzCz (5 nm) | DBfBB1TP (10 nm) |
| First hole-transport layer 911_1 | — | oFBISF(2) (65 nm) | oFBISF(2) (50 nm) |

| | | |
|---|---|---|
| Hole-injection layer 910 | 10 | oFBiSF(2):OCHD-003 (1:0.03) |
| First electrode 901 | 85 | ITSO |
| | 100 | Ag |

### <Fabrication Method of Light-Emitting Device G-1>

The light-emitting device G-1 is different from the light-emitting device B-1 in the structures of the first and second light-emitting layers 912 and 917 and the first and second hole-transport layers 911 and 916. Other components were fabricated in a manner similar to that for the light-emitting device B-1.

Specifically, the first and second light-emitting layers 912 and 917 of the light-emitting device G-1 were each formed by co-evaporation of 4,6-bis[3-(9H-carbazol-9-yl)phenyl]pyrimidine (abbreviation: 4,6mCzP2Pm) and 3,6-bis(diphenylamino)-9-[4-(4,6-diphenyl-1,3,5-triazin-2-yl)phenyl]-9H-carbazole (abbreviation: DACT-II) at a weight ratio of 0.8:0.2 to a thickness of 40 nm.

The first hole-transport layer 911 of the light-emitting device G-1 was formed in the following manner: by an evaporation method using resistance heating, the first hole-transport layer 911_1 was formed by evaporation of oFBiSF(2) to a thickness of 75 nm, and then the first hole-transport layer 911_2 was formed over the first hole-transport layer 911_1 by evaporation of 9,9′-diphenyl-9H,9′H-3,3′-bicarbazole (abbreviation: PCCP) as an organic compound having a carbazole skeleton that is a π-electron rich heteroaromatic ring and having no triarylamine skeleton to a thickness of 10 nm.

The second hole-transport layer 916 of the light-emitting device G-1 was formed in the following manner: by an evaporation method using resistance heating, the second hole-transport layer 916_1 was formed by evaporation of oFBiSF(2) to a thickness of 40 nm, and then the second hole-transport layer 9162 was formed over the second hole-transport layer 916_1 by evaporation of PCCP to a thickness of 10 nm.

### <Fabrication Method of Light-Emitting Device G-2>

The light-emitting device G-2 is different from the light-emitting device G-1 in the structures of the first and second light-emitting layers 912 and 917 and the first and second hole-transport layers 911 and 916. Other components were fabricated in a manner similar to that for the light-emitting device G-1.

Specifically, the first and second light-emitting layers 912 and 917 of the light-emitting device G-2 were each formed by co-evaporation of 7-[4-(10-phenyl-9-anthryl)phenyl]-7H-dibenzo[c,g]carbazole (abbreviation: cgDBCzPA) and N-(9,10-diphenyl-2-anthryl)-N,9-diphenyl-9H-carbazol-3-amine (abbreviation: 2PCAPA) at a weight ratio of 1:0.05 to a thickness of 40 nm.

In the first hole-transport layer 911 of the light-emitting device G-2, the first hole-transport layer 911_2 was not provided. The first hole-transport layer 911 (i.e., the first hole-transport layer 9111) was formed by evaporation of oFBiSF(2) as an organic compound having a triarylamine skeleton and a fluorene ring that is a polycyclic aromatic ring to a thickness of 80 nm by an evaporation method using resistance heating.

In the second hole-transport layer 916 of the light-emitting device G-2, the second hole-transport layer 916_2 was not provided. The second hole-transport layer 916 (i.e., the second hole-transport layer 916_1) was formed by evaporation of oFBiSF(2) to a thickness of 50 nm by an evaporation method using resistance heating.

### <Fabrication Method of Light-Emitting Device G-3>

The light-emitting device G-3 is different from the light-emitting device G-2 in the structure of the second electron-transport layer 918. Other components were fabricated in a manner similar to that for the light-emitting device G-2.

Specifically, the second electron-transport layer 918 of the light-emitting device G-3 was formed over the second light-emitting layer 917 in the following manner: by an evaporation method using resistance heating, the second electron-transport layer 9181 was formed by evaporation of mFBPTzn to a thickness of 10 nm, and then the second electron-transport layer 9182 was formed by co-evaporation of 6BP-4Cz2PPm as an organic compound having no triazine ring and Liq at a volume ratio of 1:1 to a thickness of 25 nm.

Table 2 lists the structures of the light-emitting devices G-1 to G-3.

TABLE 2

| | | | |
|---|---|---|---|
| Thickness | Light-emitting device | Light-emitting device | Light-emitting device |
| (nm) | G-1 | G-2 | G-3 |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| Second electron-transport layer 918_1 | 10 | mFBPTzn | |
|---|---|---|---|
| Second light-emitting layer 917 | 40 | 4,6mCzP2Pm:DACT-II | cgDBCzPA:2PCAPA |
| | | (0.8:0.2) | (1:0.05) |
| Second hole-transport layer 916_2 | — | PCCP (10 nm) | — |
| Second hole-transport layer 916_1 | | oFBiSF(2) (40 nm) | oFBiSF(2) (50 nm) |
| Charge-generation region | 10 | oFBiSF(2):OCHD-003 (1:0.15) | |
| Electron-relay region | 2 | CuPc | |
| Electron-injection buffer region 914 | 5 | mPPhen2P:Li₂O (1:0.02) | |
| First electron-transport layer 913 | 10 | mPCCzPTzn-02 | |
| First light-emitting layer 912 | 40 | 4,6mCzP2Pm:DACT-II | cgDBCzPA:2PCAPA |
| | | (0.8:0.2) | (1:0.05) |
| First hole-transport layer 911_2 | — | PCCP (10 nm) | — |
| First hole-transport layer 911_1 | — | oFBiSF(2) (75 nm) | oFBiSF(2) (80 nm) |

| | | |
|---|---|---|
| Hole-injection layer 910 | 10 | oFBiSF(2):OCHD-003 (1:0.03) |
| First electrode 901 | 85 | ITSO |
| | 100 | Ag |

### <Fabrication Method of Light-Emitting Device R-1>

The light-emitting device R-1 is different from the light-emitting device B-1 in the structures of the first and second light-emitting layers 912 and 917 and the first and second hole-transport layers 911 and 916. Other components were fabricated in a manner similar to that for the light-emitting device B-1.

Specifically, the first and second light-emitting layers 912 and 917 of the light-emitting device R-1 were each formed by co-evaporation of 11-[3′-(dibenzothiophen-4-yl)biphenyl-3-yl]phenanthro[9′,10′:4,5]furo[2,3-b]pyrazine (abbreviation: 11mDBtBPPnfpr), N-(biphenyl-4-yl)-N-[4-(9-phenyl-9H-carbazol-3-yl)phenyl]-9,9-dimethyl-9H-fluoren-2-amine (abbreviation: PCBBiF), and OCPG-006 as a material that emits red phosphorescent light at a weight ratio of 0.7:0.3:0.05 to a thickness of 40 nm.

In the first hole-transport layer 911 of the light-emitting device R-1, the first hole-transport layer 911_2 was not provided. The first hole-transport layer 911 (i.e., the first hole-transport layer 9111) was formed by evaporation of oFBiSF(2) as an organic compound having a triarylamine skeleton and a fluorene ring that is a polycyclic aromatic ring to a thickness of 150 nm by an evaporation method using resistance heating.

In the second hole-transport layer 916 of the light-emitting device R-1, the second hole-transport layer 916_2 was not provided. The second hole-transport layer 916 (i.e., the second hole-transport layer 916_1) was formed by evaporation of oFBiSF(2) to a thickness of 65 nm by an evaporation method using resistance heating.

### <Fabrication Method of Light-Emitting Device R-2>

The light-emitting device R-2 is different from the light-emitting device R-1 in the structure of the second electron-transport layer 918_2. Other components were fabricated in a manner similar to that for the light-emitting device R-1.

Specifically, the second electron-transport layer 918_2 of the light-emitting device R-2 was formed by co-evaporation of 6BP-4Cz2PPm as an organic compound having no triazine ring and Liq at a volume ratio of 1:1 to a thickness of 25 nm by an evaporation method using resistance heating.

Table 3 lists the structures of the light-emitting devices R-1 and R-2.

TABLE 3

| | Thickness | | |
|---|---|---|---|
| | (nm) | Light-emitting device R-1 | Light-emitting device R-2 |
| Cap layer | 70 | DBT3P-II | |
| Second electrode 902 | 15 | Ag:Mg (1:0.1) | |
| Electron-injection layer 919 | 1 | Liq | |
| Second electron-transport layer 918_2 | 25 | TznP2N:Liq (1:1) | 6BP-4Cz2PPm:Liq (1:1) |

| | | |
|---|---|---|
| Second electron-transport layer 918_1 | 10 | mFBPTzn |
| Second light-emitting layer 917 | 40 | 11mDBtBPPnfpr:PCBBIF:OCPG-006 (0.7:0.3:0.05) |
| Second hole-transport layer 916_1 | 65 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | 11mDBtBPPnfpr:PCBBIF:OCPG-006 (0.7:0.3:0.05) |
| First hole-transport layer 911_1 | 150 | oFBiSF(2) |
| Hole-injection layer 910 | 10 | oFBiSF(2):OCHD-003 (1:0.03) |
| First electrode 901 | 85 | ITSO |
| | 100 | Ag |

### <Characteristics of Light-Emitting Devices>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices were measured.

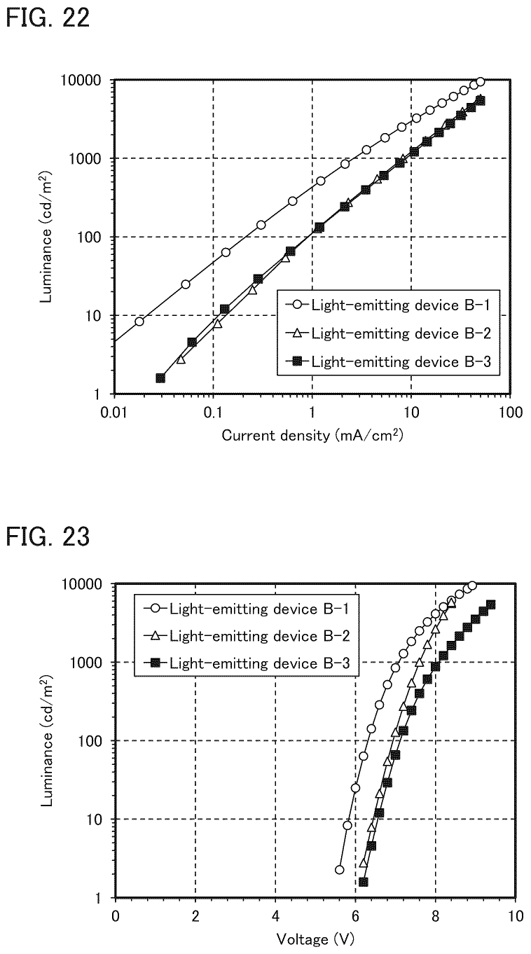

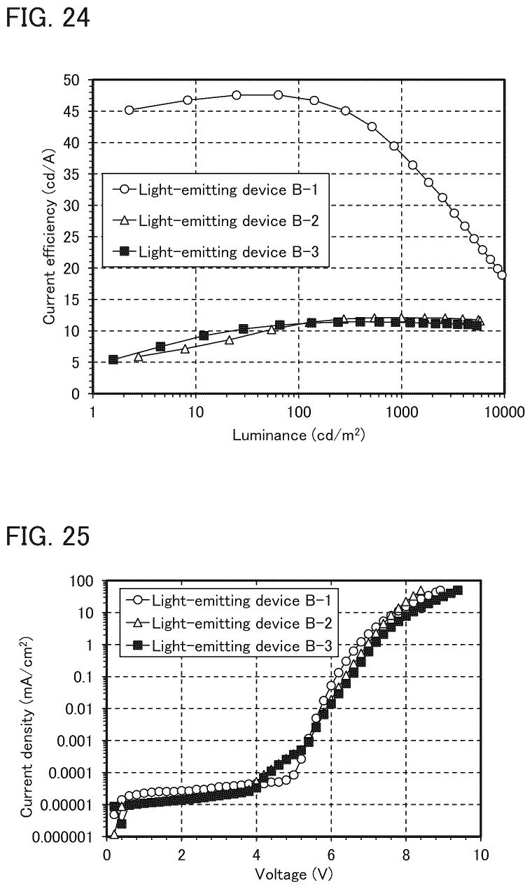

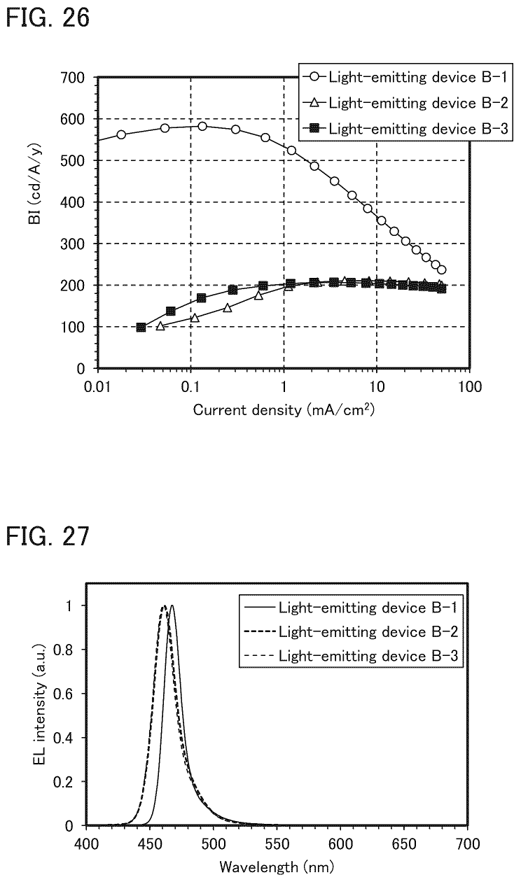

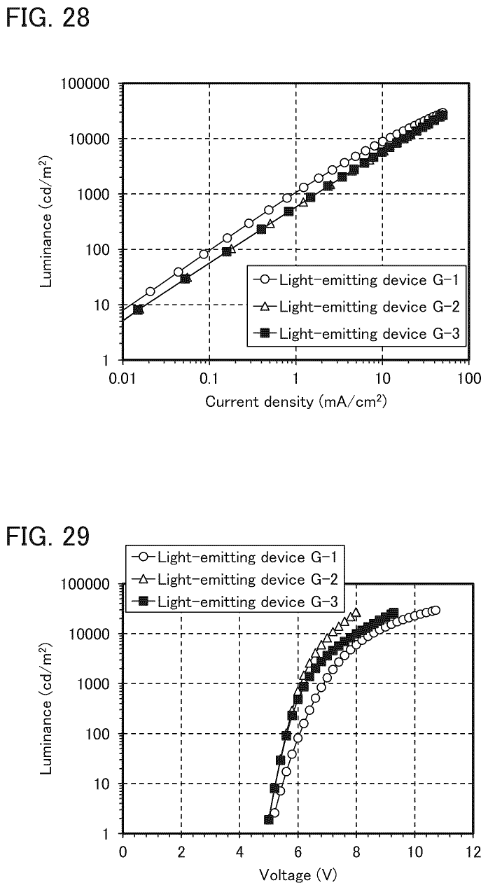

FIG. 22 shows luminance-current density characteristics of the light-emitting devices B-1 to B-3, FIG. 23 shows luminance-voltage characteristics thereof, FIG. 24 shows current efficiency-luminance characteristics thereof, FIG. 25 shows current density-voltage characteristics thereof, FIG. 26 shows blue index (BI)-current density characteristics thereof, and FIG. 27 shows electroluminescence spectra thereof.

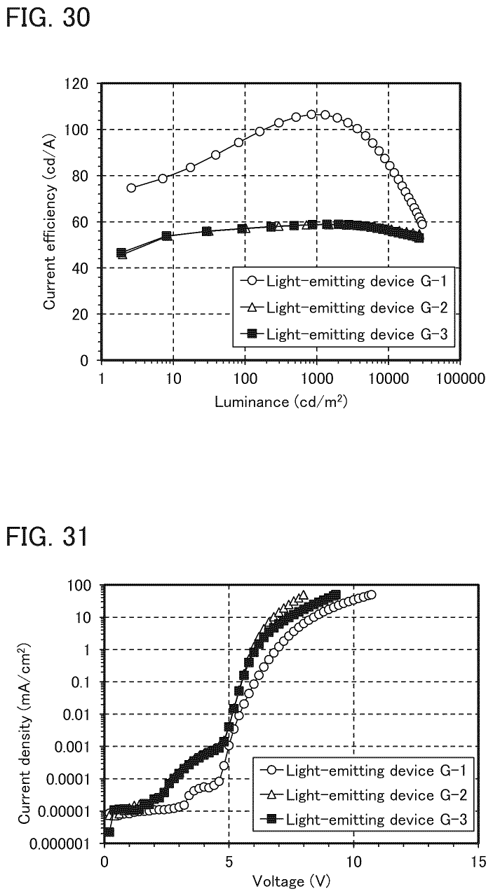

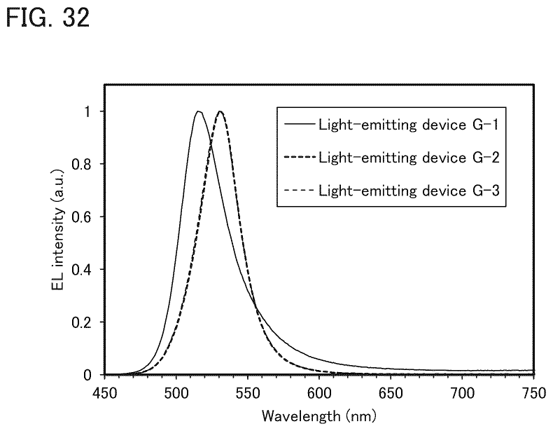

FIG. 28 shows luminance-current density characteristics of the light-emitting devices G-1 to G-3, FIG. 29 shows luminance-voltage characteristics thereof, FIG. 30 shows current efficiency-luminance characteristics thereof, FIG. 31 shows current density-voltage characteristics thereof, and FIG. 32 shows electroluminescence spectra thereof.

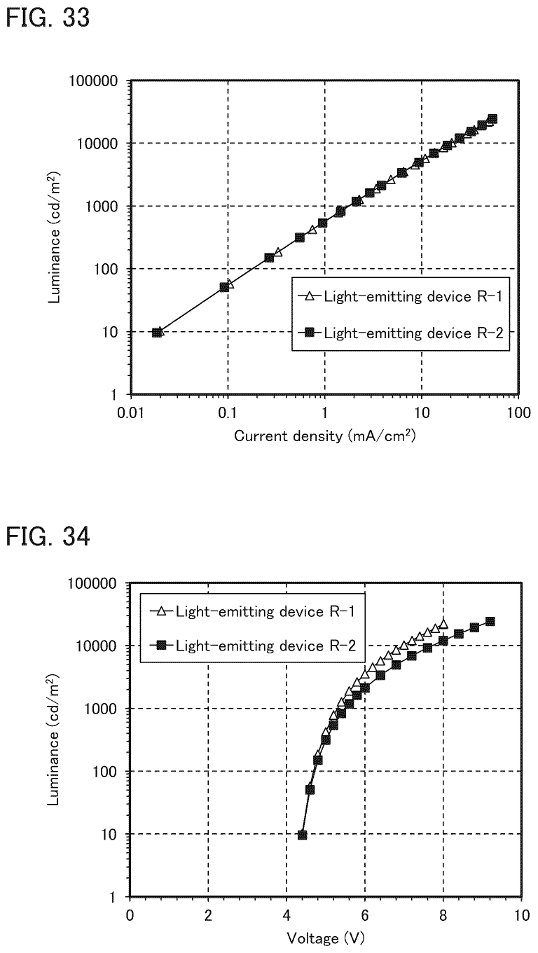

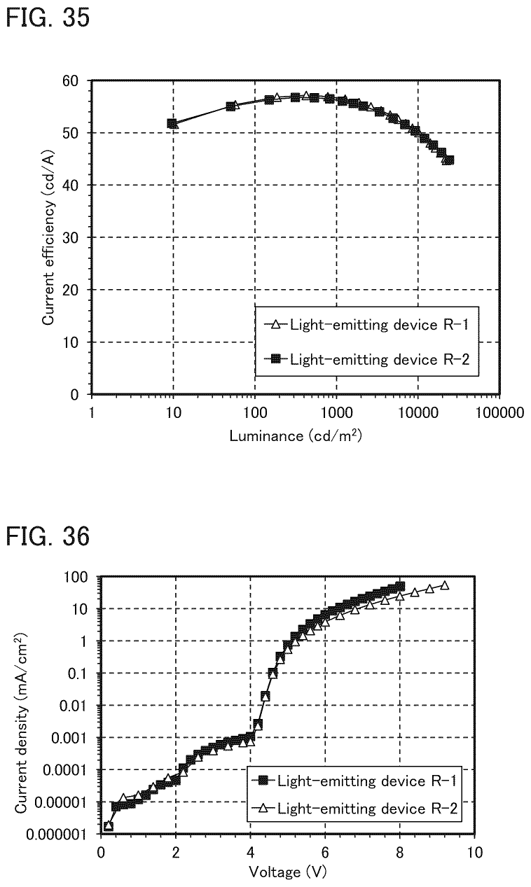

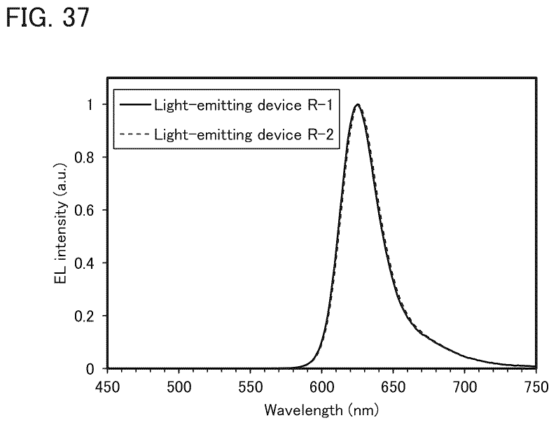

FIG. 33 shows luminance-current density characteristics of the light-emitting devices R-1 and R-2, FIG. 34 shows luminance-voltage characteristics thereof, FIG. 35 shows current efficiency-luminance characteristics thereof, FIG. 36 shows current density-voltage characteristics thereof, and FIG. 37 shows electroluminescence spectra thereof.

The blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to become higher. Blue light emission having a small y chromaticity value and high color purity enables expression of blue colors with a wide range of chromaticity in a display. Using blue light emission with high color purity reduces the luminance necessary for a display to express white, leading to lower power consumption of the display. Thus, BI, which is current efficiency based on a y chromaticity value as one of the indicators of color purity of blue, is suitably used as a means for showing efficiency of blue light emission. The light-emitting device with higher BI can be regarded as a blue-light-emitting device having higher efficiency for a display.

Table 4 shows the main characteristics of the light-emitting devices at a luminance of approximately 1000 cd/m². The luminance, CIE chromaticity, and electroluminescence spectra were measured at room temperature with a spectroradiometer (SR-UL1R, produced by TOPCON TECHNOHOUSE CORPORATION).

TABLE 4

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting device B-1 | 7.00 | 0.0858 | 2.14 | 0.126 | 0.081 | 846 | 39.5 | 486 |
| Light-emitting device B-2 | 7.60 | 0.330 | 8.25 | 0.137 | 0.0574 | 998 | 12.1 | 211 |
| Light-emitting device B-3 | 8.00 | 0.307 | 7.68 | 0.138 | 0.056 | 873 | 11.4 | 205 |
| Light-emitting device G-1 | 6.80 | 0.0317 | 0.791 | 0.221 | 0.677 | 843 | 107 | — |
| Light-emitting device G-2 | 6.00 | 0.0488 | 1.22 | 0.208 | 0.726 | 715 | 58.6 | — |
| Light-emitting device G-3 | 6.20 | 0.0591 | 1.48 | 0.207 | 0.726 | 868 | 58.7 | — |
| Light-emitting device R-1 | 5.20 | 0.0553 | 1.38 | 0.690 | 0.309 | 787 | 56.9 | — |
| Light-emitting device R-2 | 5.40 | 0.0585 | 1.46 | 0.692 | 0.308 | 826 | 56.5 | — |

According to FIG. 22 to FIG. 27 and the above table, the light-emitting device B-1 exhibited blue light emission originating from ν-DABNA, and the light-emitting devices B-2 and B-3 exhibited blue light emission originating from 3,10PCA2Nbf(IV)-02. Furthermore, it has been found that the light-emitting device B-1 has favorable emission characteristics. It has also been found that the light-emitting device B-1 has a lower driving voltage, higher current efficiency, and lower power consumption than the light-emitting devices B-2 and B-3. It has also been found that the light-emitting device B-1 has a BI value 2.5 times or more as high as BI values of the light-emitting devices B-2 and B-3, revealing its favorable efficiency as a blue-light-emitting device.

According to FIG. 28 to FIG. 32 and the above table, the light-emitting device G-1 exhibited green light emission originating from DACT-II, and the light-emitting devices G-2 and G-3 exhibited green light emission originating from 2PCAPA. Furthermore, it has been found that the light-emitting device G-1 has favorable emission characteristics. It has also been found that the light-emitting device G-1 has higher current efficiency than the light-emitting devices G-2 and G-3.

According to FIG. 33 to FIG. 37 and the above table, the light-emitting devices R-1 and R-2 exhibited red light emission originating from OCPG-006. Furthermore, it has been found that the light-emitting device R-1 has favorable emission characteristics. It has also been found that the light-emitting device R-1 has a lower driving voltage than the light-emitting device R-2.

<Calculation of S₁ Levels and T₁ Levels of Light-Emitting Substances>

Described here are calculation results of the S₁ levels and the T₁ levels of ν-DABNA, DACT-II, 3,10PCA2Nbf(IV)-02, αN-βNPAnth, 2PCAPA, and cgDBCzPA, which are the materials used for the light-emitting layers of the blue-light-emitting devices and the green-light-emitting devices, obtained by measuring PL spectra (hereinafter, also referred to as emission spectra) of the materials. For the calculation of each S₁ level, a PL spectrum (fluorescence spectrum) was measured at a measurement temperature of 10 K using a 50-nm-thick thin film of a sample formed over a quartz substrate, and the energy of an emission edge on a shorter wavelength side of the spectrum was regarded as the S₁ level. For the calculation of each T₁ level, a PL spectrum (phosphorescence spectrum) was measured at a measurement temperature of 10 K using a 50-nm-thick thin film of a sample formed over a quartz substrate, and the energy of an emission edge on a shorter wavelength side of the spectrum was regarded as the T₁ level. The measurement was performed with a PL microscope (LabRAM HR-PL, produced by HORIBA, Ltd.) and a He—Cd laser (wavelength: 325 nm) as excitation light. The emission edge was determined as the intersection between a tangent and the horizontal axis (representing wavelength) or the baseline. The tangent was drawn at a point at which the slope on a shorter wavelength side of the shortest-wavelength peak (or the shortest-wavelength shoulder peak) of the emission spectrum has the maximum absolute value.

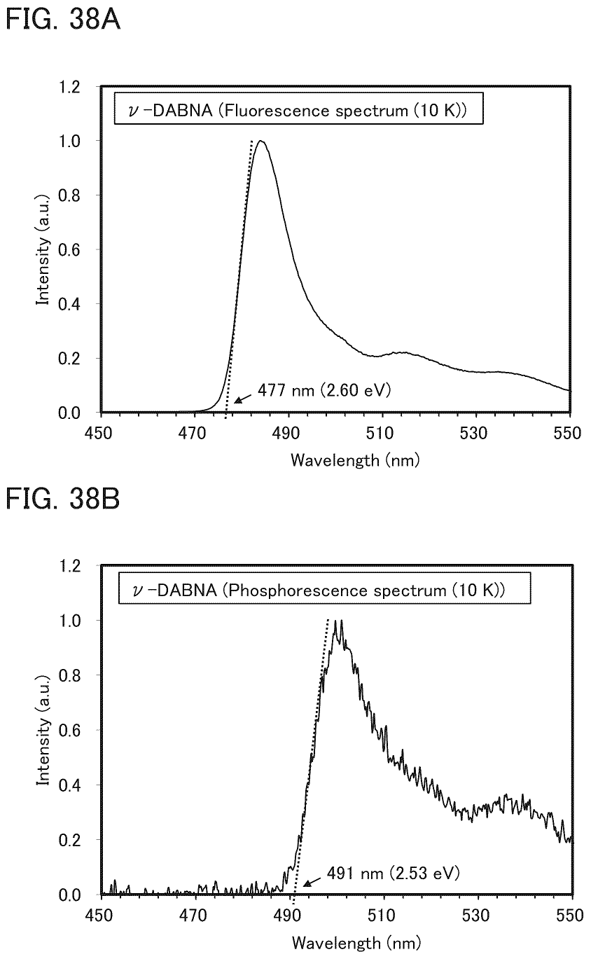

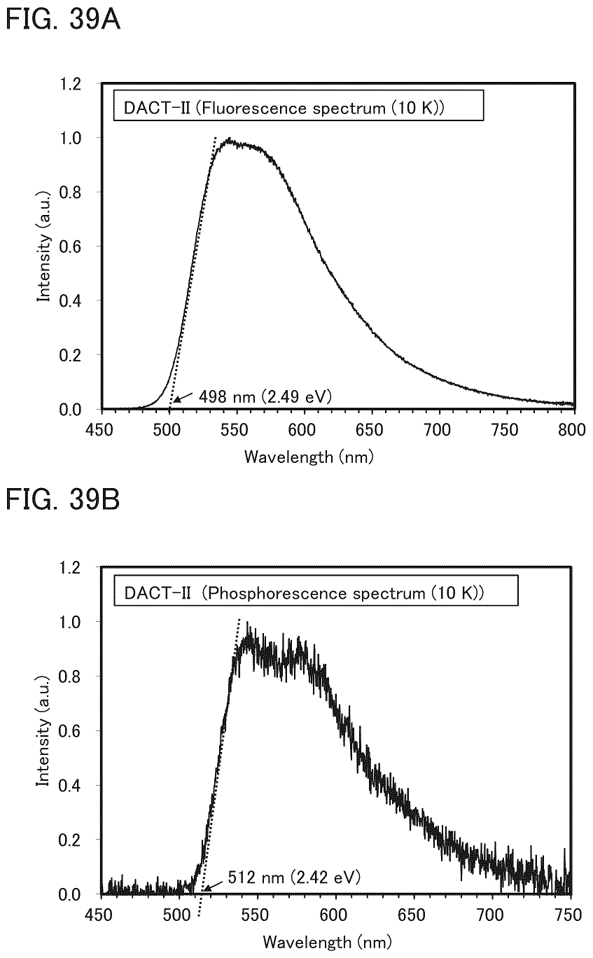

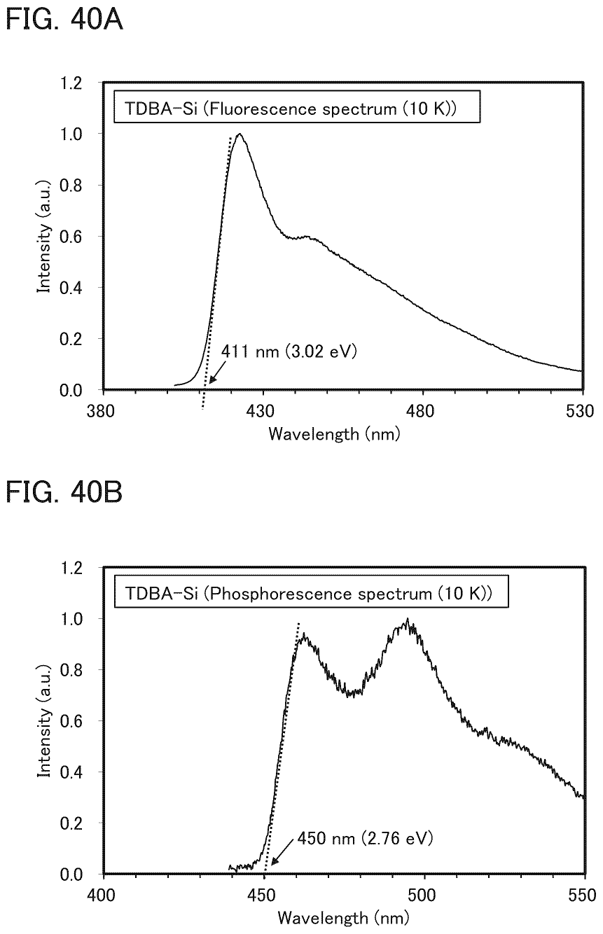

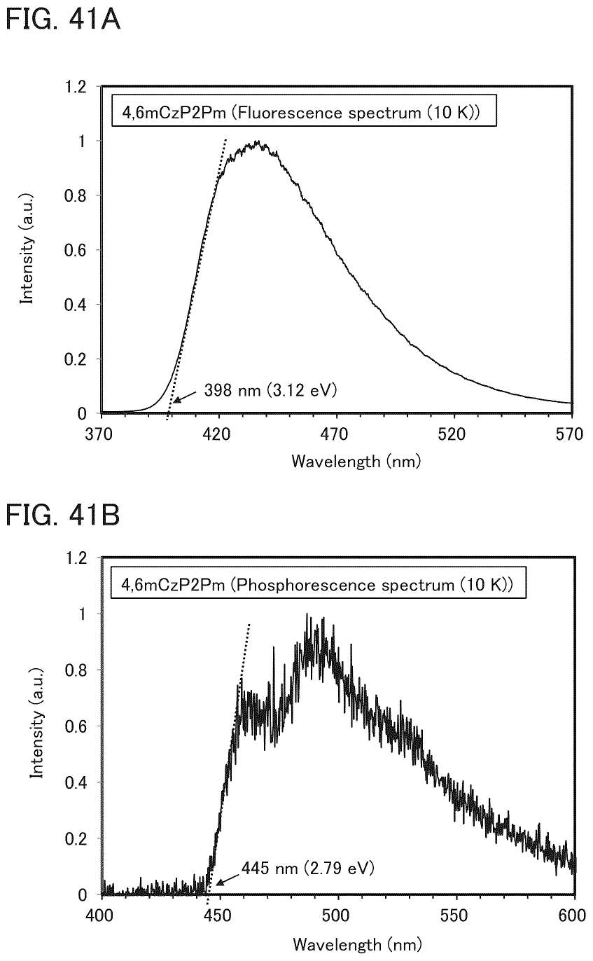

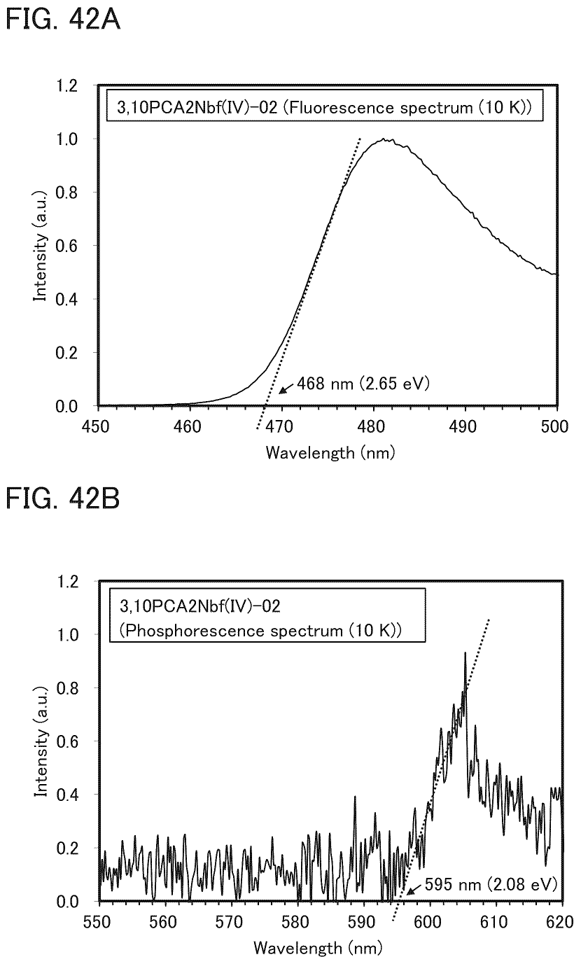

FIG. 38A shows the measurement result of the fluorescence spectrum (10 K) of ν-DABNA, and FIG. 38B shows the measurement result of the phosphorescence spectrum (10 K) of ν-DABNA. FIG. 39A shows the measurement result of the fluorescence spectrum (10 K) of DACT-II, and FIG. 39B shows the measurement result of the phosphorescence spectrum (10 K) of DACT-II. FIG. 40A shows the measurement result of the fluorescence spectrum (10 K) of TDBA-Si, and FIG. 40B shows the measurement result of the phosphorescence spectrum (10 K) of TDBA-Si. FIG. 41A shows the measurement result of the fluorescence spectrum (10 K) of 4,6mCzP2Pm, and FIG. 41B shows the measurement result of the phosphorescence spectrum (10 K) of 4,6mCzP2Pm. FIG. 42A shows the measurement result of the fluorescence spectrum (10 K) of 3,10PCA2Nbf(IV)-02, and FIG. 42B shows the measurement result of the phosphorescence spectrum (10 K) of 3,10PCA2Nbf(IV)-02.

As shown in FIG. 38A, a wavelength of an emission edge on a shorter wavelength side of the fluorescence spectrum (10 K) of ν-DABNA is 477 nm; thus, the S₁ level of ν-DABNA is calculated to be 2.60 eV. As shown in FIG. 38B, a wavelength of an emission edge on a shorter wavelength side of the phosphorescence spectrum (10 K) of ν-DABNA is 491 nm; thus, the T₁ level of ν-DABNA is calculated to be 2.53 eV. According to these results, a difference in wavelength of the emission edge on the shorter wavelength side between the fluorescence spectrum and the phosphorescence spectrum of ν-DABNA is found to be 14 nm, and an energy difference between the S₁ level and the T₁ level is calculated to be 0.07 eV.

As shown in FIG. 39A, a wavelength of an emission edge on a shorter wavelength side of the fluorescence spectrum (10 K) of DACT-II is 498 nm; thus, the S₁ level of DACT-II is calculated to be 2.49 eV. As shown in FIG. 39B, a wavelength of an emission edge on a shorter wavelength side of the phosphorescence spectrum (10 K) of DACT-II is 512 nm; thus, the T₁ level of DACT-II is calculated to be 2.42 eV. According to these results, a difference in wavelength of the emission edge on the shorter wavelength side between the fluorescence spectrum and the phosphorescence spectrum of DACT-II is found to be 14 nm, and an energy difference between the S₁ level and the T₁ level is calculated to be 0.07 eV.

As described above, the difference in wavelength of the emission edge on the shorter wavelength side between the fluorescence spectrum and the phosphorescence spectrum of each of ν-DABNA and DACT-II is less than or equal to 30 nm, which is extremely small. In addition, the energy difference between the S₁ level and the T₁ level of each of ν-DABNA and DACT-II is greater than 0 eV and less than or equal to 0.20 eV, which is extremely small. Thus, ν-DABNA and DACT-II can be regarded as substances capable of exhibiting thermally activated delayed fluorescence (TADF materials).

As shown in FIG. 40A, a wavelength of an emission edge on a shorter wavelength side of the fluorescence spectrum (10 K) of TDBA-S₁ is 411 nm; thus, the S₁ level of TDBA-S₁ is calculated to be 3.02 eV. As shown in FIG. 40B, a wavelength of an emission edge on a shorter wavelength side of the phosphorescence spectrum (10 K) of TDBA-S₁ is 450 nm; thus, the T₁ level of TDBA-S₁ is calculated to be 2.76 eV. According to these results, a difference in wavelength of the emission edge on the shorter wavelength side between the fluorescence spectrum and the phosphorescence spectrum of TDBA-S₁ is found to be 39 nm, and an energy difference between the S₁ level and the T₁ level is calculated to be 0.26 eV.

As shown in FIG. 41A, a wavelength of an emission edge on a shorter wavelength side of the fluorescence spectrum (10 K) of 4,6mCzP2Pm is 398 nm; thus, the S₁ level of 4,6mCzP2Pm is calculated to be 3.12 eV. As shown in FIG. 41B, a wavelength of an emission edge on a shorter wavelength side of the phosphorescence spectrum (10 K) of 4,6mCzP2Pm is 445 nm; thus, the T₁ level of 4,6mCzP2Pm is calculated to be 2.79 eV. According to these results, a difference in wavelength of the emission edge on the shorter wavelength side between the fluorescence spectrum and the phosphorescence spectrum of 4,6mCzP2Pm is found to be 47 nm, and an energy difference between the S₁ level and the T₁ level is calculated to be 0.33 eV.

As shown in FIG. 42A, a wavelength of an emission edge on a shorter wavelength side of the fluorescence spectrum (10 K) of 3,10PCA2Nbf(IV)-02 is 468 nm; thus, the S₁ level of 3,10PCA2Nbf(IV)-02 is calculated to be 2.65 eV. As shown in FIG. 42B, a wavelength of an emission edge on a shorter wavelength side of the phosphorescence spectrum (low temperature) of 3,10PCA2Nbf(IV)-02 is 595 nm; thus, the T₁ level of 3,10PCA2Nbf(IV)-02 is calculated to be 2.08 eV. According to these results, a difference in wavelength of the emission edge on the shorter wavelength side between the fluorescence spectrum and the phosphorescence spectrum of 3,10PCA2Nbf(IV)-02 is found to be 127 nm, and an energy difference between the S₁ level and the T₁ level is calculated to be 0.57 eV.

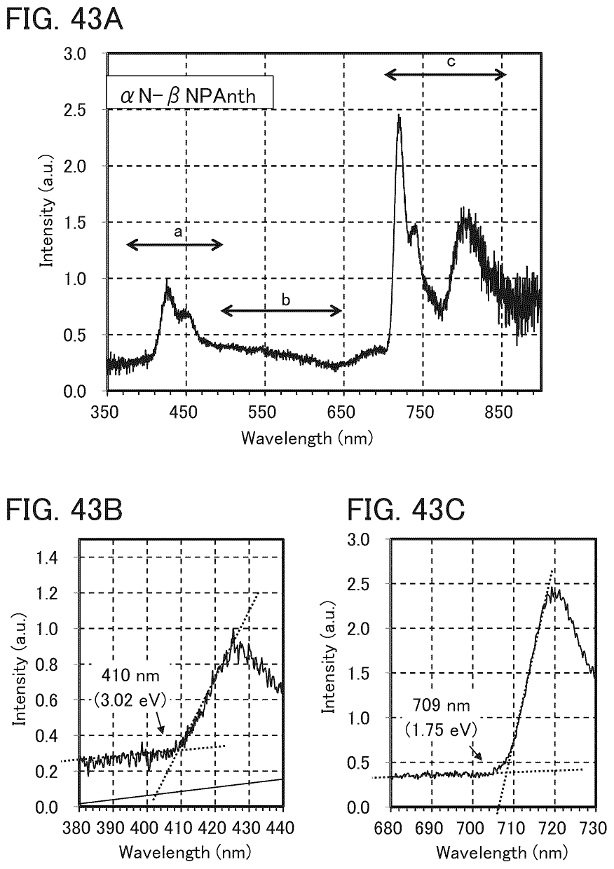

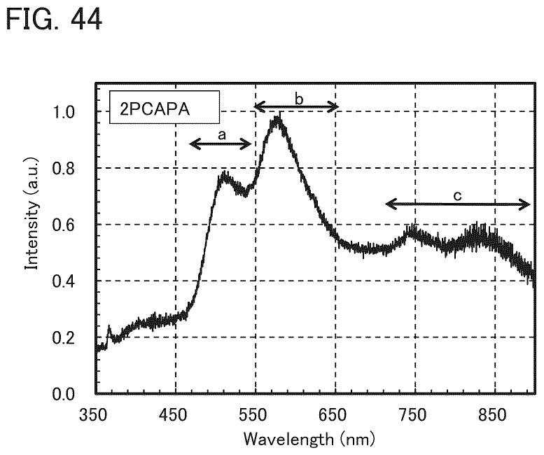

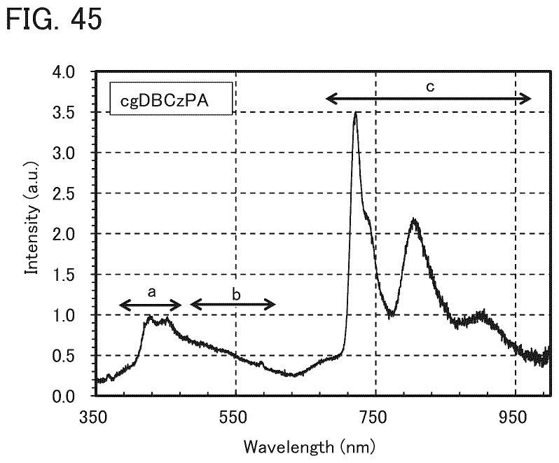

It is less likely to observe phosphorescence from αN-βNPAnth, 2PCAPA, and cgDBCzPA. Thus, to make phosphorescence observation easier, a triplet sensitizer was added. As the triplet sensitizer, tris(2-phenylpyridinato-N,C²)iridium(III) (abbreviation: Ir(ppy)₃) was used for αN-βNPAnth and cgDBCzPA, and (acetylacetonato)bis(4,6-diphenylpyrimidinato)iridium(III) (abbreviation: Ir(dppm)₂(acac)) was used for 2PCAPA. FIGS. 43A to 43C show the measurement result of the emission spectrum (10 K) of αN-βNPAnth. FIG. 44 shows the measurement result of the emission spectrum (10 K) of 2PCAPA. FIG. 45 shows the measurement result of the emission spectrum (10 K) of cgDBCzPA.

FIG. 43A shows the emission spectrum (10 K) of αN-βNPAnth in a wavelength region of from 350 nm to 900 nm. In FIG. 43A, a spectrum in a wavelength region a originates mainly from fluorescence of αN-βNPAnth, a spectrum in a wavelength region b originates mainly from phosphorescence of Ir(ppy)₃, and a spectrum in a wavelength region c originates mainly from phosphorescence of αN-βNPAnth. As shown in FIG. 43A, a wavelength of a peak (including a shoulder peak) on the shortest wavelength side of the fluorescence component (fluorescence spectrum) in the emission spectrum of αN-βNPAnth is 426 nm, and a wavelength of a peak (including a shoulder peak) on the shortest wavelength side of the phosphorescence component (phosphorescence spectrum) in the emission spectrum of αN-βNPAnth is 719 nm. FIG. 43B shows the fluorescence spectrum (10 K) of αN-βNPAnth in a wavelength region of from 380 nm to 440 nm. As shown in FIG. 43B, a wavelength of an emission edge on a shorter wavelength side of the fluorescence spectrum of αN-βNPAnth is 410 nm; thus, the S₁ level of αN-βNPAnth can be calculated to be 3.02 eV. FIG. 43C shows the phosphorescence spectrum (10 K) of αN-βNPAnth in a wavelength region of from 680 nm to 730 nm. As shown in FIG. 43C, a wavelength of an emission edge on a shorter wavelength side of the phosphorescence spectrum of αN-βNPAnth is 709 nm; thus, the T₁ level of αN-βNPAnth can be calculated to be 1.75 eV. According to these results, a difference in wavelength of the emission edge on the shorter wavelength side between the fluorescence spectrum and the phosphorescence spectrum of αN-βNPAnth is found to be 299 nm, and an energy difference between the S₁ level and the T₁ level is calculated to be 1.28 eV.

In FIG. 44, a spectrum in a wavelength region a originates mainly from fluorescence of 2PCAPA, a spectrum in a wavelength region b originates mainly from phosphorescence of Ir(dppm)₂(acac), and a spectrum in a wavelength region c originates mainly from phosphorescence of 2PCAPA. As shown in FIG. 44, a wavelength of a peak (including a shoulder peak) on the shortest wavelength side of the fluorescence component in the emission spectrum of 2PCAPA is around 516 nm, and a wavelength of a peak (including a shoulder peak) on the shortest wavelength side of the phosphorescence component in the emission spectrum of 2PCAPA is around 746 nm. According to these results, 2PCAPA can be regarded as a fluorescent substance whose energy difference between the S₁ level and the T₁ level is greater than 0.20 eV.

In FIG. 45, a spectrum in a wavelength region a originates mainly from fluorescence of cgDBCzPA, a spectrum in a wavelength region b originates mainly from phosphorescence of Ir(ppy)₃, and a spectrum in a wavelength region c originates mainly from phosphorescence of cgDBCzPA. As shown in FIG. 45, a wavelength of a peak (including a shoulder peak) on the shortest wavelength side of the fluorescence component (fluorescence spectrum) in the emission spectrum of cgDBCzPA is 426 nm, and a wavelength of a peak (including a shoulder peak) on the shortest wavelength side of the phosphorescence component (phosphorescence spectrum) in the emission spectrum of cgDBCzPA is around 721 nm. According to these results, cgDBCzPA can be regarded as a fluorescent substance whose energy difference between the S₁ level and the T₁ level is greater than 0.20 eV.

As described above, each of TDBA-Si, 4,6mCzP2Pm, 3,10PCA2Nbf(IV)-02, αN-βNPAnth, 2PCAPA, and cgDBCzPA has an energy difference between the S₁ level and the T₁ level greater than 0.20 eV. Accordingly, these materials can be regarded not as substances capable of exhibiting thermally activated delayed fluorescence (TADF materials) but as fluorescent substances.

Moreover, the above results reveal that, in each of the light-emitting layers of the light-emitting device B-1, the T₁ level of TDBA-S₁ as a host material is higher than the T₁ level of ν-DABNA as a TADF material, and the wavelength of the emission edge on the shorter wavelength side of the phosphorescence spectrum of TDBA-S₁ is shorter than the wavelength of the emission edge on the shorter wavelength side of the phosphorescence spectrum of ν-DABNA. The above results also reveal that, in each of the light-emitting layers of the light-emitting device G-1, the T₁ level of 4,6mCzP2Pm as a host material is higher than the T₁ level of DACT-II as a TADF material, and the wavelength of the emission edge on the shorter wavelength side of the phosphorescence spectrum of 4,6mCzP2Pm is shorter than the wavelength of the emission edge on the shorter wavelength side of the phosphorescence spectrum of DACT-II.

Accordingly, the light-emitting device of one embodiment of the present invention is found to have favorable characteristics when including a light-emitting layer having a structure in which the T₁ level of a host material is higher than the T₁ level of a TADF material.

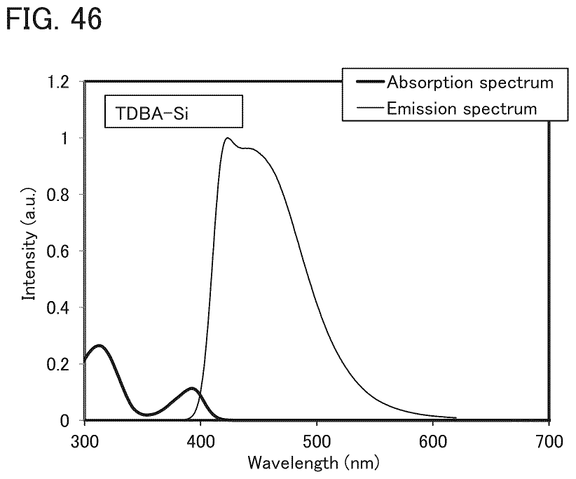

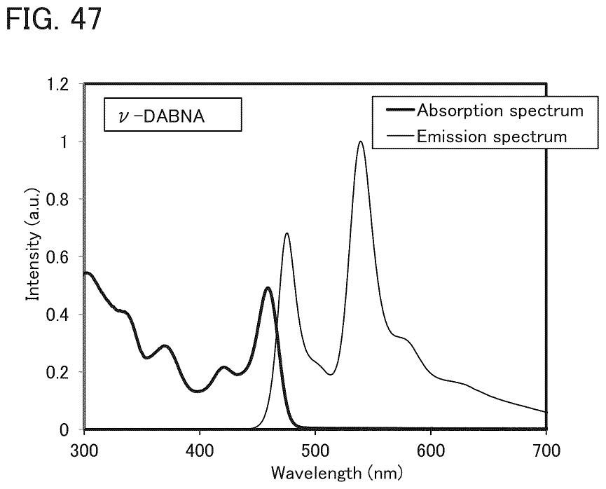

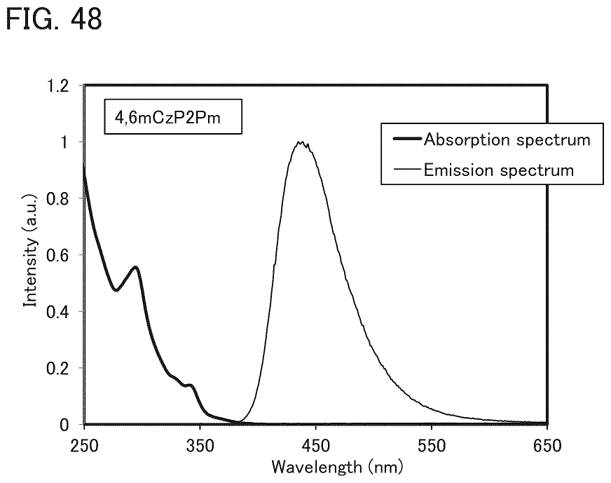

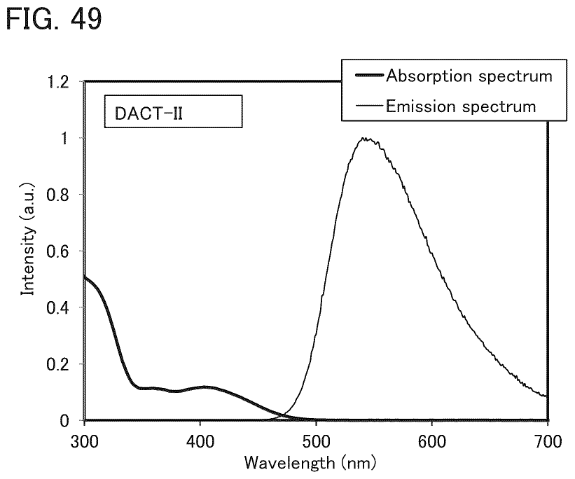

FIG. 46 to FIG. 49 show measurement results of emission and absorption spectra of thin films of TDBA-Si, ν-DABNA, 4,6mCzP2Pm, and DACT-II at room temperature. FIG. 46 shows the emission and absorption spectra of TDBA-Si, FIG. 47 shows the emission and absorption spectra of ν-DABNA, FIG. 48 shows the emission and absorption spectra of 4,6mCzP2Pm, and FIG. 49 shows the emission and absorption spectra of DACT-II. The emission and absorption spectra of each material were measured using a 50-nm-thick thin film formed by evaporation over a quartz substrate. The emission spectra (PL spectra) were measured with a fluorescence spectrophotometer (FP-8600, produced by JASCO Corporation). An emission edge on a shorter wavelength side of each of the emission spectra was determined as the intersection between a tangent and the horizontal axis or the baseline. The tangent was drawn at a point at which the slope on a shorter wavelength side of the shortest-wavelength peak (or the shortest-wavelength shoulder peak) of the emission spectrum has the maximum absolute value. The absorption spectra were measured with an ultraviolet-visible spectrophotometer (V-770DS, produced by JASCO Corporation). An absorption edge of each of the absorption spectra was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value.

A wavelength (401 nm) of an emission edge on a shorter wavelength side of the PL spectrum (fluorescence spectrum) of TDBA-S₁ measured at room temperature shown in FIG. 46 is shorter than a wavelength (477 nm) of an absorption edge on a longer wavelength side of the absorption spectrum of ν-DABNA measured at room temperature shown in FIG. 47. Such a relation allows efficient transfer of excitation energy to ν-DABNA in the light-emitting device B-1 and enables ν-DABNA to emit light efficiently.

As shown in FIG. 46, a wavelength of an emission edge on a shorter wavelength side of the PL spectrum (fluorescence spectrum) of ν-DABNA measured at room temperature is 461 nm; thus, the S₁ level of ν-DABNA can be calculated to be 2.69 eV. According to the results of the PL spectrum (fluorescence spectrum) measured at room temperature and the phosphorescence spectrum measured at a low temperature (10 K) (see FIG. 38B) of ν-DABNA, a difference in wavelength of the emission edge on the shorter wavelength side between the fluorescence spectrum (room temperature) and the phosphorescence spectrum (10 K) is 30 nm, and an energy difference between the S₁ level and the T₁ level is 0.16 eV. Thus, ν-DABNA can be regarded as a TADF material.

A wavelength (398 nm) of an emission edge on a shorter wavelength side of the PL spectrum (fluorescence spectrum) of 4,6mCzP2Pm measured at room temperature shown in FIG. 48 is shorter than a wavelength (478 nm) of an absorption edge on a longer wavelength side of the absorption spectrum of DACT-II measured at room temperature shown in FIG. 49. Such a relation allows efficient transfer of excitation energy to DACT-II in the light-emitting device G-1 and enables DACT-II to emit light efficiently.

As shown in FIG. 49, a wavelength of an emission edge on a shorter wavelength side of the PL spectrum (fluorescence spectrum) of DACT-II measured at room temperature is 487 nm; thus, the S₁ level of DACT-II can be calculated to be 2.55 eV. According to the results of the PL spectrum (fluorescence spectrum) measured at room temperature and the phosphorescence spectrum measured at a low temperature (10 K) (see FIG. 39B) of DACT-II, a difference in wavelength of the emission edge on the shorter wavelength side between the fluorescence spectrum (room temperature) and the phosphorescence spectrum (10 K) is 25 nm, and an energy difference between the S₁ level and the T₁ level is 0.13 eV. Thus, DACT-II can be regarded as a TADF material.

### <Measurement Results of T₁ Level of Other Materials>

Described here are calculation results of the T₁ levels of materials used for the layers (the first hole-transport layer 911, the first electron-transport layer 913, the second hole-transport layer 916, and the second electron-transport layer 9181) adjacent to the light-emitting layers of each light-emitting device, obtained by measuring emission spectra of materials at a low temperature. For the calculation of each T₁ level, a PL spectrum (phosphorescence spectrum) was measured at a measurement temperature of 10 K using a 50-nm-thick thin film of a sample formed over a quartz substrate, and the energy of an emission edge on a shorter wavelength side of the spectrum was regarded as the T₁ level. The measurement was performed with a PL microscope (LabRAM HR-PL, produced by HORIBA, Ltd.) and a He—Cd laser (wavelength: 325 nm) as excitation light. The emission edge was determined as the intersection between a tangent and the horizontal axis (representing wavelength) or the baseline. The tangent was drawn at a point at which the slope on a shorter wavelength side of the shortest-wavelength peak (or the shortest-wavelength shoulder peak) of the emission spectrum has the maximum absolute value.

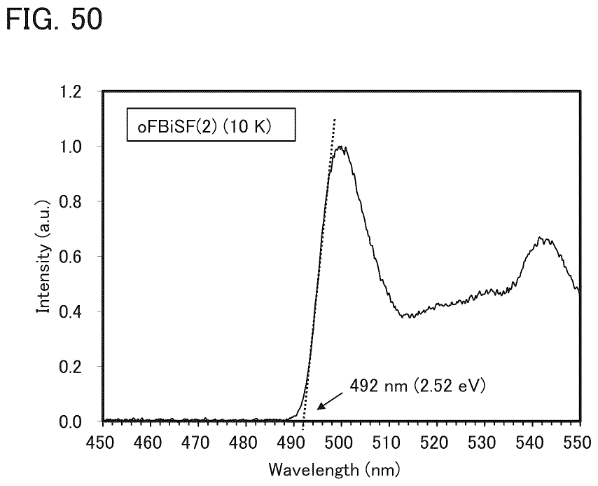

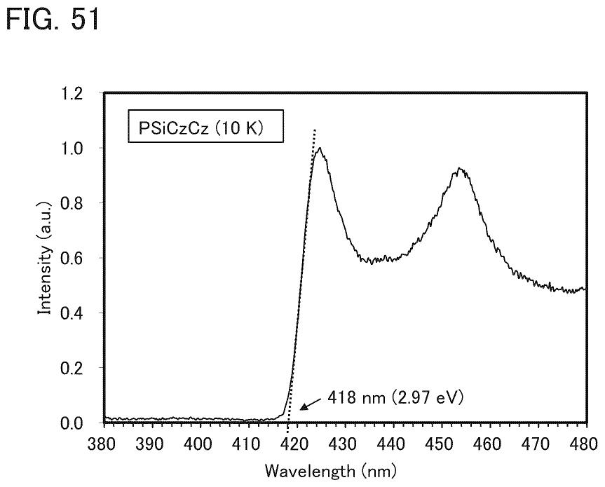

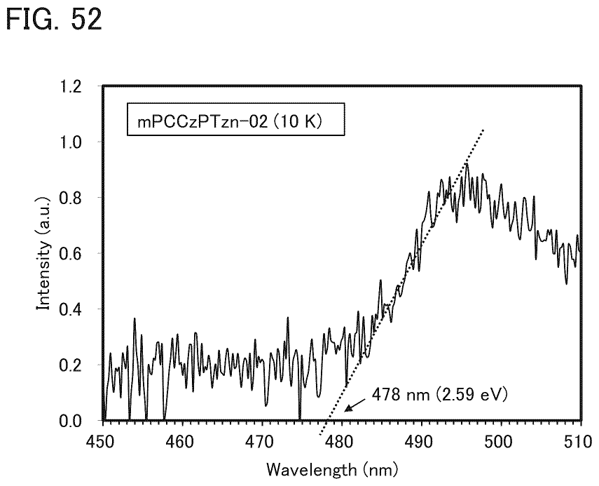

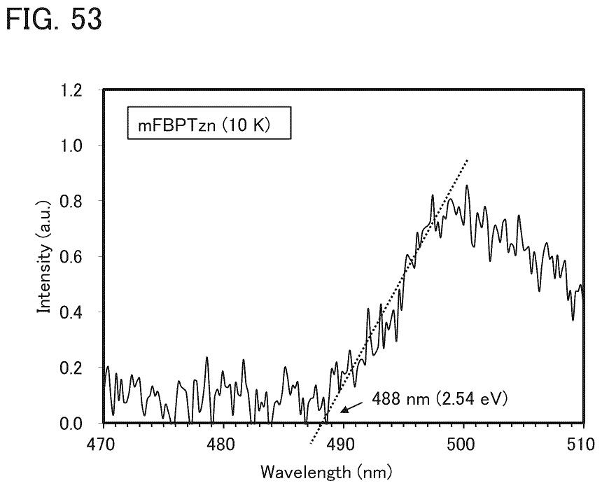

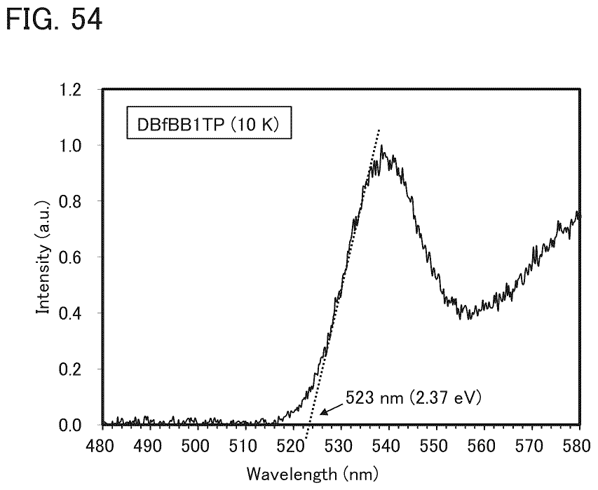

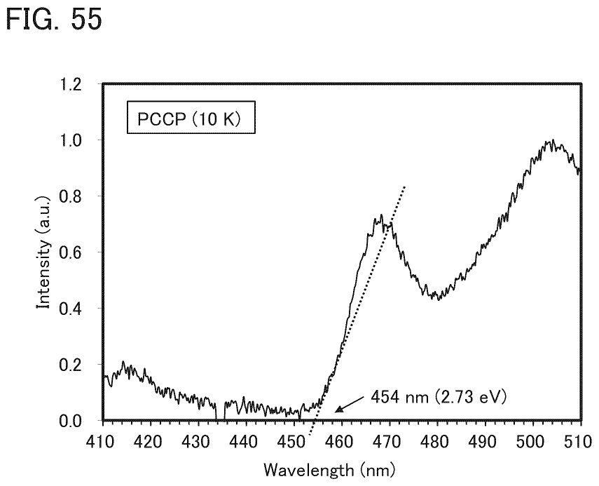

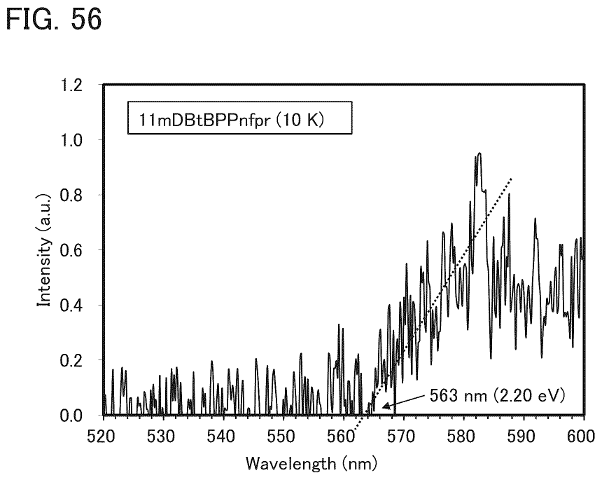

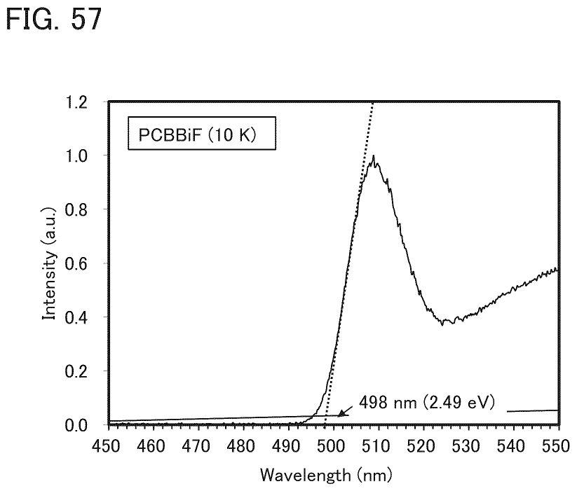

FIG. 50 shows the measurement result of oFBiSF(2). FIG. 51 shows the measurement result of PSiCzCz. FIG. 52 shows the measurement result of mPCCzPTzn-02. FIG. 53 shows the measurement result of mFBPTzn. FIG. 54 shows the measurement result of DBfBB1TP. FIG. 55 shows the measurement result of PCCP. FIG. 56 shows the measurement result of 11mDBtBPPnfpr. FIG. 57 shows the measurement result of PCBBiF.

From the emission edges on the shorter wavelength sides of the emission spectra shown in FIG. 50 to FIG. 57, the T₁ levels of oFBiSF(2), PSiCzCz, mPCCzPTzn-02, mFBPTzn, DBfBB1TP, PCCP, 11mDBtBPPnfpr, and PCBBiF are calculated to be 2.52 eV, 2.97 eV, 2.59 eV, 2.54 eV, 2.37 eV, 2.73 eV, 2.20 eV, and 2.49 eV, respectively.

The above results reveal that, in the light-emitting device B-1, the T₁ levels of PSiCzCz used for the first hole-transport layer 911_2 and mPCCzPTzn-02 used for the first electron-transport layer 913 are each higher than the T₁ level of ν-DABNA as a TADF material used for the first light-emitting layer 912, and the T₁ levels of PSiCzCz used for the second hole-transport layer 916_2 and mFBPTzn used for the second electron-transport layer 9181 are each higher than the T₁ level of ν-DABNA as a TADF material used for the second light-emitting layer 917. The above results also reveal that, in the light-emitting device G-1, the T₁ levels of PCCP used for the first hole-transport layer 911_2 and mPCCzPTzn-02 used for the first electron-transport layer 913 are each higher than the T₁ level of DACT-II as a TADF material used for the first light-emitting layer 912, and the T₁ levels of PCCP used for the second hole-transport layer 916_2 and mFBPTzn used for the second electron-transport layer 918_1 are each higher than the T₁ level of DACT-II as a TADF material used for the second light-emitting layer 917.

Accordingly, the light-emitting device of one embodiment of the present invention is found to have favorable characteristics when having a structure in which the T₁ level of a material used for a layer adjacent to a light-emitting layer is higher than the T₁ level of a TADF material used for the light-emitting layer.

### <Estimation of Power Consumption>

Next, assuming that a display apparatus 1 includes the light-emitting device R-1, the light-emitting device G-1, and the light-emitting device B-2 respectively in red, green, and blue subpixels; a display apparatus 2 includes the light-emitting device R-1, the light-emitting device G-2, and the light-emitting device B-1 respectively in red, green, and blue subpixels; and a comparative display apparatus includes the light-emitting device R-2, the light-emitting device G-3, and the light-emitting device B-3 respectively in red, green, and blue subpixels, the power consumptions of their display portions (excluding the power consumption of a driving transistor, a driving circuit, and the like) were tentatively calculated. Note that each of the light-emitting devices assumed to be used in the display apparatuses is a tandem light-emitting device, and the same light-emitting substance is used in the plurality of light-emitting layers in each of the light-emitting devices. Thus, the display apparatuses are side-by-side display apparatuses.

The conditions of the display apparatuses assumed for the tentative calculation are as follows.

TABLE 5

| | |
|---|---|
| Panel size | 5 inches (16:9) |
| Panel area | 68.9 cm² |

| | | |
|---|---|---|
| Aperture ratio | 30% | Red 10% |
| | | Green 10% |
| | | Blue 10% |

| | |
|---|---|
| Effective luminance | 1000 cd/m² in displaying white on the entire screen |
| Circular polarizing plate | Not used |

First, in each display apparatus under the above-described conditions, the luminances (effective luminances) of the light-emitting devices of RGB required to obtain 1000 cd/m² emission of white light with CIE 1931 chromaticity coordinates (x, y)=(0.31, 0.33) when the display apparatus is made to emit white light from the entire screen were calculated.

Next, the luminances (intrinsic luminances) required to obtain the calculated effective luminances of the light-emitting devices of RGB were calculated in consideration of the aperture ratios. The intrinsic luminance is the luminance (effective luminance) at which each light-emitting device actually emits light in order to obtain the effective luminance of 1000 cd/m² when the display apparatus is made to emit white light with CIE 1931 chromaticity coordinates (x, y)=(0.31, 0.33) from the entire screen. Since the aperture ratio of the whole display apparatus subjected to the tentative calculation is 30% and the aperture ratio per emission color is 10%, the intrinsic luminance is approximately ten times the effective luminance.

From the measurement results of the light-emitting devices described above and the intrinsic luminances, the current density and voltage for making each light-emitting device emit light at the intrinsic luminance can be obtained. In other words, in each display apparatus under the above-described conditions, the current density and voltage of each light-emitting device to obtain 1000 cd/m² luminance emission of white light with CIE 1931 chromaticity coordinates (x, y)=(0.31, 0.33) when the display apparatus is made to emit white light from the entire screen can be obtained.

The power consumption is calculated by multiplying the amount of current by the voltage. The amount of current is calculated by multiplying the current density, the panel area, and the aperture ratio. The display apparatuses subjected to the tentative calculation each have a diagonal size of 5 inches, an aspect ratio of 16:9, a panel area of 68.9 cm², and an aperture ratio of the light-emitting device of each color of 10%, and the amount of current can be calculated by multiplying the current density calculated in the previous paragraph by these values. Furthermore, the power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display apparatus (except for the power consumption of the driving transistor, the driving circuit, and the like) can be obtained.

Table 6 shows the results of calculating the power consumption of the display apparatus 1 assumed to include the light-emitting devices R-1, G-1, and B-2.

TABLE 6
Display apparatus 1

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.690 | 0.309 | 256 | 2557 | 55.1 | 4.64 | 32.0 | 5.78 | 185 |
| Green | 0.215 | 0.679 | 674 | 6743 | 92.3 | 7.31 | 50.4 | 8.11 | 408 |
| Blue | 0.137 | 0.0574 | 69.9 | 699 | 12.1 | 5.79 | 39.9 | 7.47 | 298 |
| Full white | 0.313 | 0.329 | 1000 | — | 56.4 | — | 122 | — | 891 |

Table 7 shows the results of calculating the power consumption of the display apparatus 2 assumed to include the light-emitting devices R-1, G-2, and B-1.

TABLE 7
Display apparatus 2

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.690 | 0.309 | 274 | 2741 | 54.9 | 4.99 | 34.4 | 5.82 | 200 |
| Green | 0.206 | 0.726 | 621 | 6207 | 57.7 | 10.8 | 74.1 | 6.82 | 505 |
| Blue | 0.126 | 0.0811 | 105 | 1053 | 38.0 | 2.77 | 19.1 | 7.09 | 135 |
| Full white | 0.313 | 0.329 | 1000 | — | 54.0 | — | 128 | — | 841 |

Table 8 shows the results of calculating the power consumption of the comparative display apparatus assumed to include the light-emitting devices R-2, G-3, and B-3.

TABLE 8
Comparative display apparatus

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.692 | 0.308 | 261 | 2607 | 54.7 | 4.77 | 32.9 | 6.16 | 202 |
| Green | 0.206 | 0.725 | 669 | 6688 | 57.3 | 11.7 | 80.5 | 7.56 | 608 |
| Blue | 0.138 | 0.0555 | 70.5 | 705 | 11.4 | 6.18 | 42.6 | 7.87 | 335 |
| Full white | 0.313 | 0.329 | 1000 | — | 44.2 | — | 156 | — | 1146 |

The above tables show that the display apparatuses 1 and 2 each assumed to include the light-emitting devices of embodiments of the present invention have higher current efficiencies and lower driving voltages in white light emission than the comparative display apparatus assumed to include the light-emitting devices R-2, G-3, and B-3. Furthermore, it has been found that the power consumptions of the display apparatuses 1 and 2 are lower than the power consumption of the comparative display apparatus.

The above results show that the light-emitting devices of embodiments of the present invention have favorable characteristics, and the light-emitting devices B-1 and G-1 each have a particularly high emission efficiency.

### Example 2

This example will describe specific fabrication methods and characteristics of light-emitting device B-4, G-4, and R-3 that can be used in the display apparatus of one embodiment of the present invention. In addition, power consumption of the display apparatus of one embodiment of the present invention including these light-emitting devices was estimated. Structural formulae of main compounds used for the light-emitting devices are shown below.

The light-emitting devices each have a tandem structure in which, as illustrated in FIG. 20 or FIG. 21, the first EL layer 903, the intermediate layer 905, the second EL layer 904, and the second electrode 902 are stacked over the first electrode 901 formed over the substrate 900 that is a glass substrate. The cap layer 909 is provided over the second electrode. The light-emitting device B-4 has a structure illustrated in FIG. 20, whereas the light-emitting devices G-4 and R-3 each have a structure illustrated in FIG. 21.

As illustrated in FIG. 20, the first EL layer 903 of the light-emitting device B-4 has a structure in which the hole-injection layer 910, the first hole-transport layer 911 (the first hole-transport layers 911_1 and 911_2), the first light-emitting layer 912, and the first electron-transport layer 913 are stacked in this order. The second EL layer 904 thereof has a structure in which the second hole-transport layer 916 (the second hole-transport layers 916_1 and 916_2), the second light-emitting layer 917, the second electron-transport layer 918 (the second electron-transport layers 918_1 and 918_2), and the electron-injection layer 919 are stacked in this order.

Meanwhile, as illustrated in FIG. 21, the first EL layer 903 of each of the light-emitting device G-4 and the light-emitting device R-3 has a structure in which the hole-injection layer 910, the first hole-transport layer 9111, the first light-emitting layer 912, and the first electron-transport layer 913 are stacked in this order. The second EL layer 904 thereof has a structure in which the second hole-transport layer 9161, the second light-emitting layer 917, the second electron-transport layer 918 (the second electron-transport layers 918_1 and 918_2), and the electron-injection layer 919 are stacked in this order.

In each of the light-emitting devices, the intermediate layer 905 includes the electron-injection buffer region 914 and the layer 915 including the electron-relay region and the charge-generation region.

The light-emitting device B-4 is a blue-light-emitting device. The light-emitting device B-4 is the light-emitting device of one embodiment of the present invention in which a TADF material is used for the first light-emitting layer 912 and the second light-emitting layer 917. In the light-emitting device B-4, the second electron-transport layer 9182 includes an organic compound having a triazine ring.

The light-emitting device G-4 is a green-light-emitting device. The light-emitting device G-4 is a light-emitting device in which the first light-emitting layer 912 and the second light-emitting layer 917 each include a phosphorescent substance. In the light-emitting device G-4, the second electron-transport layer 918_2 includes an organic compound having a triazine ring.

The light-emitting device R-3 is a red-light-emitting device in which a phosphorescent substance is used for the first light-emitting layer 912 and the second light-emitting layer 917. In the light-emitting device R-3, the second electron-transport layer 9182 includes an organic compound having a triazine ring.

The light-emitting devices were each fabricated by a continuous vacuum process. Structural formulae of organic compounds used for the light-emitting devices are shown below.

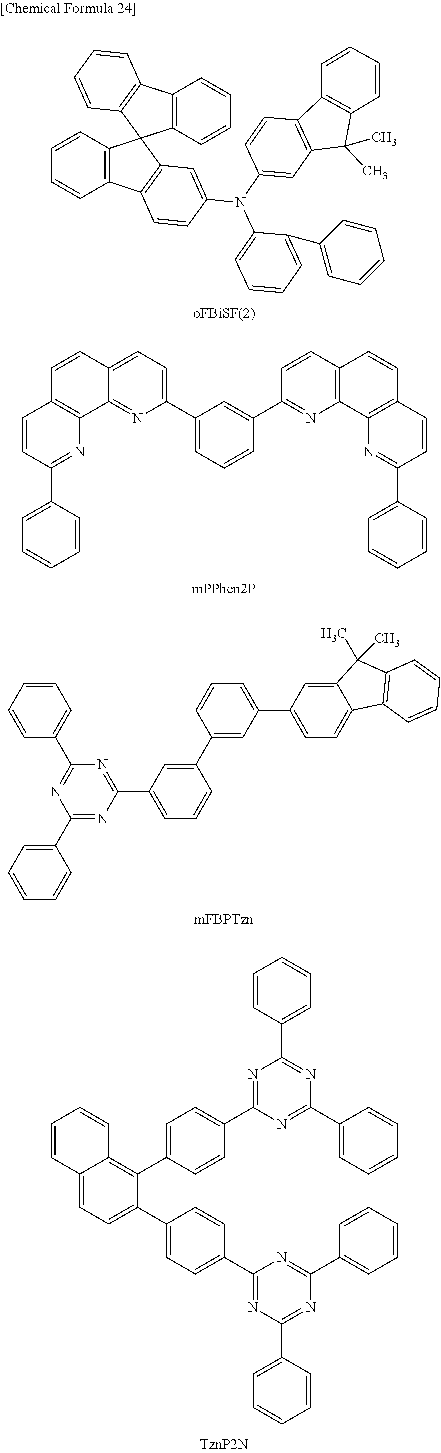 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc3ccc4ccc(-c5cccc(-c6ccc7ccc8ccc(-c9ccccc9)nc8c7n6)c5)nc4c3n2)cc1 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1]

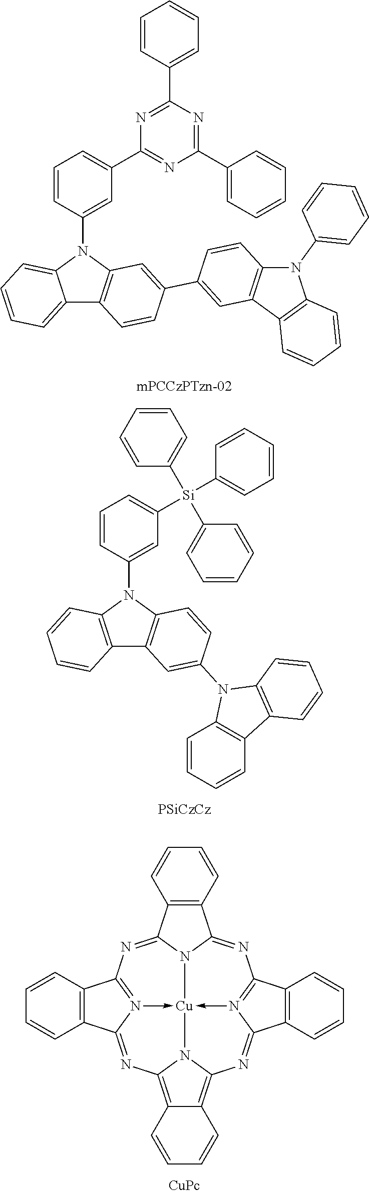

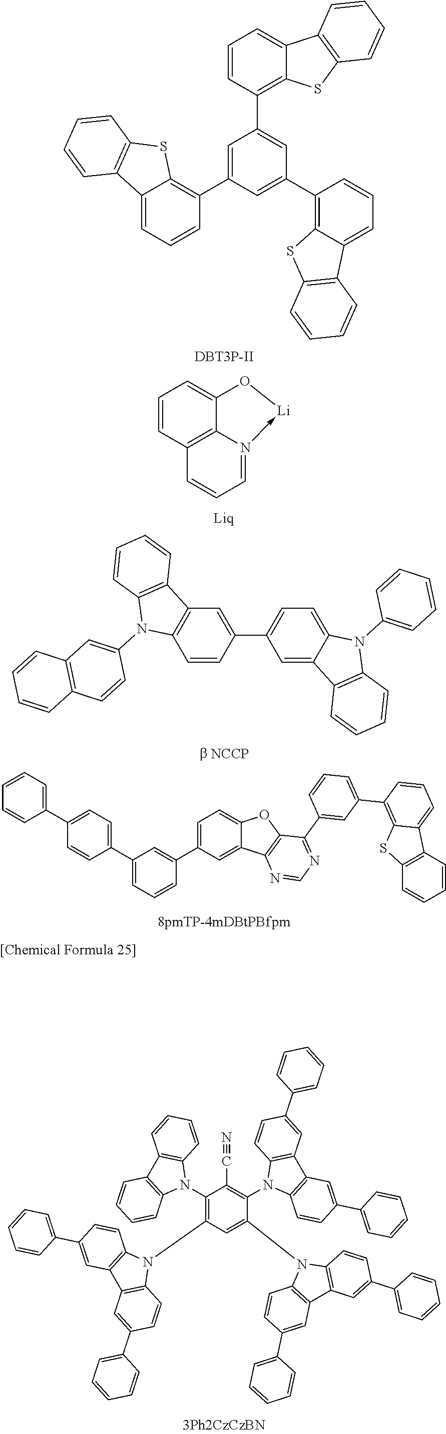

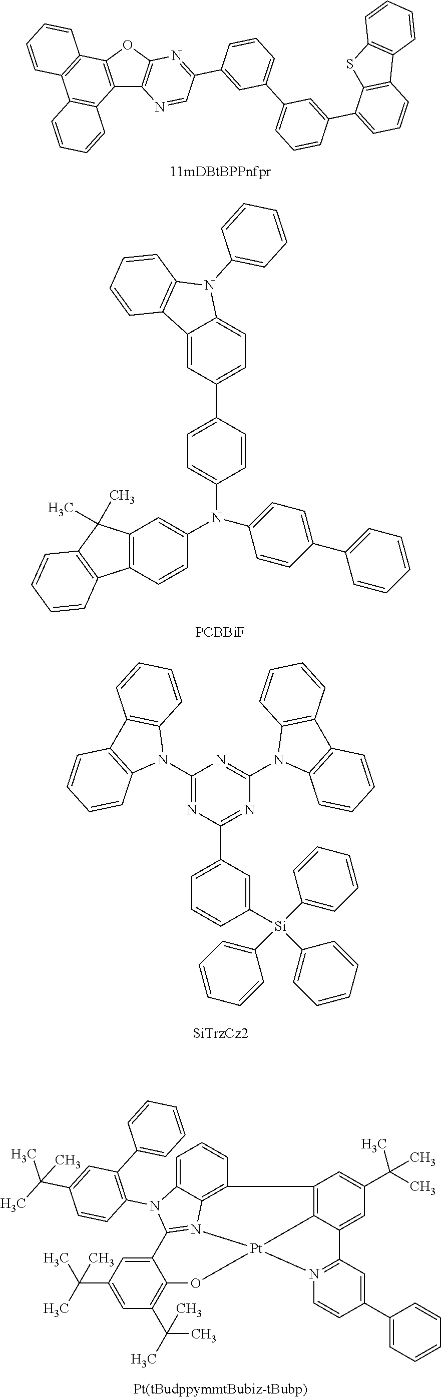

### <Fabrication Method of Light-Emitting Device B-4>

The light-emitting device B-4 is different from the light-emitting device B-1 in the structures of the first and second light-emitting layers 912 and 917, the electron-injection buffer region 914, the electron-injection layer 919, and the first and second hole-transport layers 911 and 916. Other components were fabricated in a manner similar to that for the light-emitting device B-1.

Specifically, the first and second light-emitting layers of the light-emitting device B-4 were each formed by co-evaporation of 9,9′-{6-[3-(triphenylsilyl)phenyl]-1,3,5-triazine-2,4-diyl}bis(9H-carbazole) (abbreviation: SiTrzCz2), PSiCzCz, and 2-(9H-carbazol-9-yl)-3,5,6-tris(3,6-diphenyl-9H-carbazol-9-yl)benzonitrile (abbreviation: 3Ph2CzCzBN) at a weight ratio of 0.45:0.45:0.10 to a thickness of 25 nm by an evaporation method using resistance heating.

The electron-injection buffer region 914 of the light-emitting device B-4 was formed by co-evaporation of mPPhen2P and ytterbium (Yb) at a volume ratio of 1:0.02 to a thickness of 5 nm by an evaporation method using resistance heating.

The electron-injection layer 919 of the light-emitting device B-4 was formed by co-evaporation of LiF and Yb at a volume ratio of 2:1 to a thickness of 1.5 nm by an evaporation method using resistance heating.

The first hole-transport layer 911_1 was formed by evaporation of oFBiSF(2) to a thickness of 60 nm by an evaporation method using resistance heating. The second hole-transport layer 916_1 was formed by evaporation of oFBiSF(2) to a thickness of 45 nm by an evaporation method using resistance heating.

### <Fabrication Method of Light-Emitting Device G-4>

The light-emitting device G-4 is different from the light-emitting device B-4 in the structures of the first and second light-emitting layers 912 and 917 and the first and second hole-transport layers 911 and 916. Other components were fabricated in a manner similar to that for the light-emitting device B-4.

Specifically, the first and second light-emitting layers 912 and 917 of the light-emitting device G-4 were each formed by co-evaporation of 8mpTP-4mDBtPBfpm, PNCCP, and (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp) at a weight ratio of 0.5:0.5:0.1 to a thickness of 40 nm by an evaporation method using resistance heating.

In the first hole-transport layer 911 of the light-emitting device G-4, the first hole-transport layer 911_2 was not provided. The first hole-transport layer 911 (i.e., the first hole-transport layer 9111) was formed by evaporation of oFBiSF(2) to a thickness of 90 nm by an evaporation method using resistance heating.

In the second hole-transport layer 916 of the light-emitting device G-4, the second hole-transport layer 916_2 was not provided. The second hole-transport layer 916 (i.e., the second hole-transport layer 916_1) was formed by evaporation of oFBiSF(2) to a thickness of 65 nm by an evaporation method using resistance heating.

### <Fabrication Method of Light-Emitting Device R-3>

The light-emitting device R-3 is different from the light-emitting device B-4 in the structures of the first and second light-emitting layers 912 and 917 and the first and second hole-transport layers 911 and 916. Other components were fabricated in a manner similar to that for the light-emitting device B-4.

The first and second light-emitting layers of the light-emitting device R-3 were each formed by co-evaporation of 11mDBtBPPnfpr, PCBBiF, and OCPG-006 at a weight ratio of 0.7:0.3:0.05 to a thickness of 40 nm by an evaporation method using resistance heating.

In the first hole-transport layer 911 of the light-emitting device R-3, the first hole-transport layer 911_2 was not provided. The first hole-transport layer 911 (i.e., the first hole-transport layer 9111) was formed by evaporation of oFBiSF(2) to a thickness of 160 nm by an evaporation method using resistance heating.

In the second hole-transport layer 916 of the light-emitting device R-3, the second hole-transport layer 916_2 was not provided. The second hole-transport layer 916 (i.e., the second hole-transport layer 916_1) was formed by evaporation of oFBiSF(2) to a thickness of 75 nm by an evaporation method using resistance heating.

The structures of the light-emitting devices B-4, G-4, and R-3 are shown below.

TABLE 9

| | Thickness | |
|---|---|---|
| | (nm) | Light-emitting device B-4 |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 25 | SiTrzCz2:PSiCzCz:3Ph2CzCzBN (0.45:0.45:0.10) |
| Second hole-transport layer 916_2 | 5 | PSiCzCz |
| Second hole-transport layer 916_1 | 45 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 25 | SiTrzCz2:PSiCzCz:3Ph2CzCzBN (0.45:0.45:0.10) |
| First hole-transport layer 911_2 | 5 | PSiCzCz |
| First hole-transport layer 911_1 | 60 | oFBiSF(2) |
| Hole-injection layer 910 | 10 | oFBiSF(2):OCHD-003 (1:0.03) |
| First electrode 901 | 85 | ITSO |
| | 100 | Ag |

TABLE 10

| | Thickness | |
|---|---|---|
| | (nm) | Light-emitting device G-4 |
| Cap layer | 70 | DBT3P-II |
| Second electrode 902 | 15 | Ag:Mg (1:0.1) |
| Electron-injection layer 919 | 1.5 | LIF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 8mpTP-4mDBtPBfpm:BNCCP:Pt(tBudppymmtBubiz-tBubp) |
| | | (0.5:0.5:0.1) |
| Second hole-transport layer 916_1 | 65 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 8mpTP-4mDBtPBfpm:βNCCP:Pt(tBudppymmtBubiz-tBubp) |
| | | (0.5:0.5:0.1) |
| First hole-transport layer 911_1 | 90 | oFBiSF(2) |
| Hole-injection layer 910 | 10 | oFBISF(2):OCHD-003 (1:0.03) |
| First electrode 901 | 85 | ITSO |
| | 100 | Ag |

TABLE 11

| | Thickness | |
|---|---|---|
| | (nm) | Light-emitting device R-3 |
| Cap layer | 70 | DBT3P-II |
| Second electrode 902 | 15 | Ag:Mg (1:0.1) |
| Electron-injection layer 919 | 1.5 | LIF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 11mDBtBPPnfpr:PCBBIF:OCPG-006 (0.7:0.3:0.05) |
| Second hole-transport layer 916_1 | 75 | oFBISF(2) |
| Charge-generation region | 10 | oFBiSF(2):OCHD-003 (1.0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 11mDBtBPPnfpr:PCBBIF:OCPG-006 (0.7:0.3:0.05) |
| First hole-transport layer 911_1 | 160 | oFBiSF(2) |
| Hole-injection layer 910 | 10 | oFBiSF(2):OCHD-003 (1.0.03) |
| First electrode 901 | 85 | ITSO |
| | 100 | Ag |

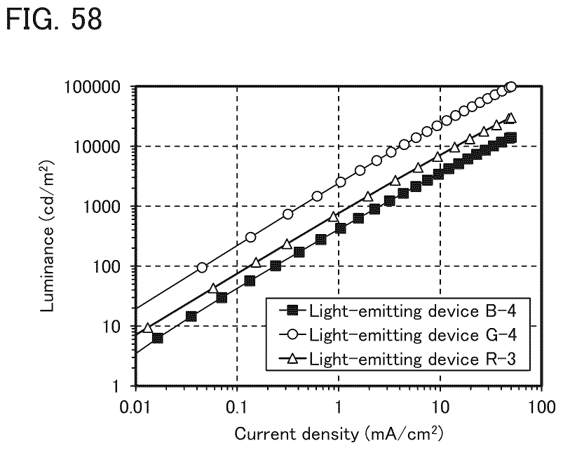

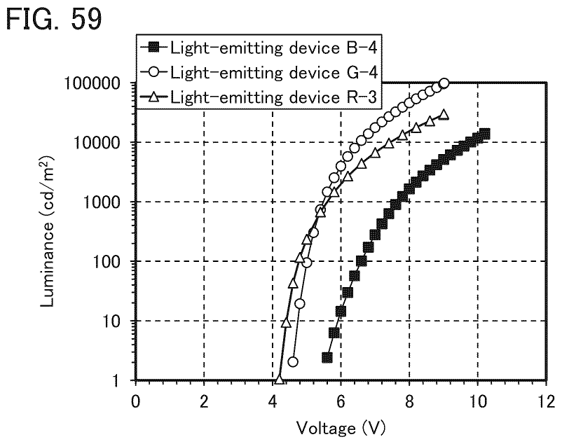

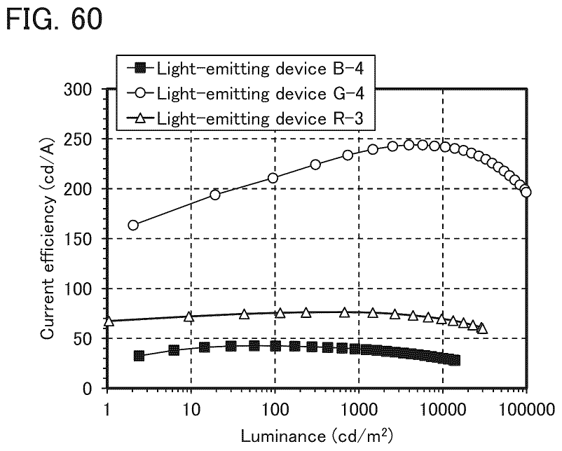

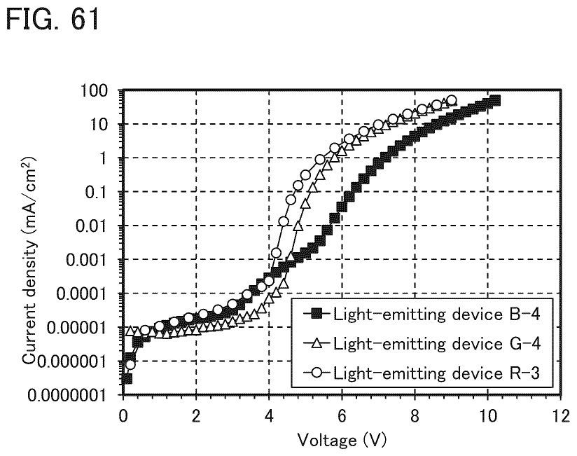

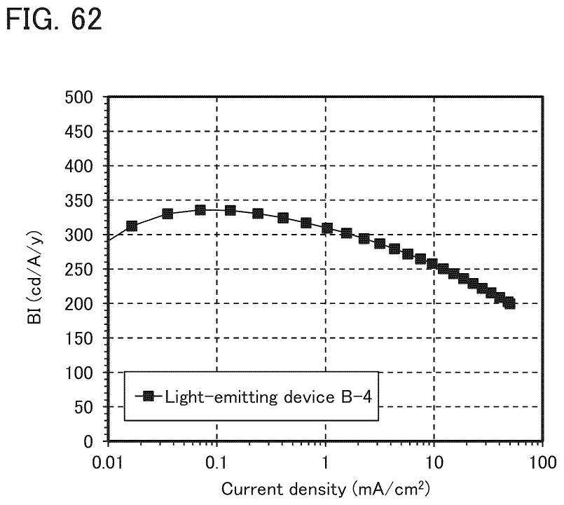

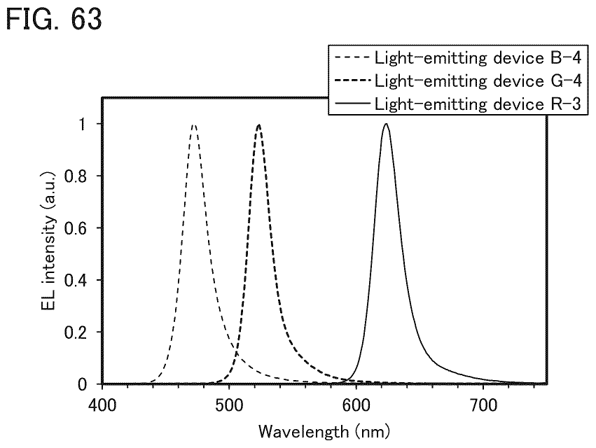

FIG. 58 shows luminance-current density characteristics of the light-emitting devices B-4, G-4, and R-3, FIG. 59 shows luminance-voltage characteristics thereof, FIG. 60 shows current efficiency-luminance characteristics thereof, FIG. 61 shows current density-voltage characteristics thereof, and FIG. 63 shows electroluminescence spectra thereof. FIG. 62 shows blue index (BI)-current density characteristics of the light-emitting device B-4.

Table 12 shows the main characteristics of the light-emitting devices B-4, G-4, and R-3 at a luminance of approximately 1000 cd/m². In this example, the luminance, CIE chromaticity, and electroluminescence spectra were measured at room temperature with a spectroradiometer (SR-UL1R, produced by TOPCON TECHNOHOUSE CORPORATION).

TABLE 12

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting device B-4 | 7.60 | 0.0907 | 2.27 | 0.121 | 0.134 | 897 | 39.6 | 294 |
| Light-emitting device G-4 | 5.40 | 0.0126 | 0.316 | 0.183 | 0.754 | 739 | 234 | — |
| Light-emitting device R-3 | 5.40 | 0.0354 | 0.886 | 0.691 | 0.309 | 676 | 76.3 | — |

It has been found from FIG. 58 to FIG. 63 and the above table that the light-emitting device B-4 exhibits blue light emission originating from 3Ph2CzCzBN and has favorable emission characteristics. Furthermore, it has been found that the light-emitting device G-4 exhibits green light emission originating from Pt(tBudppymmtBubiz-tBubp) and has favorable emission characteristics. Moreover, it has been found that the light-emitting device R-3 exhibits red light emission originating from OCPG-006 and has favorable emission characteristics.

<Calculation of S₁ Levels and T₁ Levels of Light-Emitting Substances>

Described here are calculation results of the S₁ levels and the T₁ levels of 3Ph2CzCzBN, SiTrzCz2, and PSiCzCz, which are the materials used for the light-emitting layers of the light-emitting device B-4, obtained by measuring PL spectra (hereinafter, also referred to as emission spectra) of the materials. The measurement of the PL spectra and the calculation of the S₁ levels and the T₁ levels were performed in manners similar to those in Example 1.

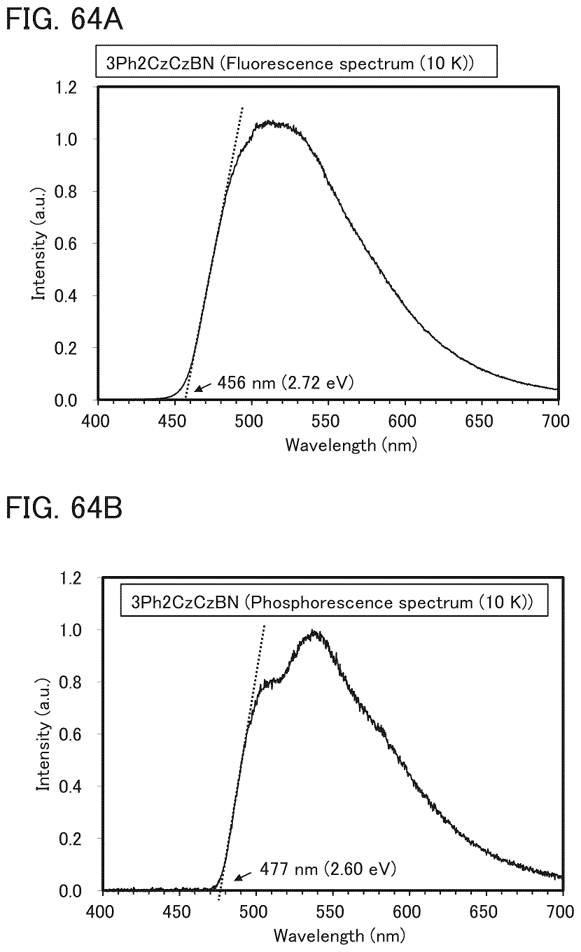

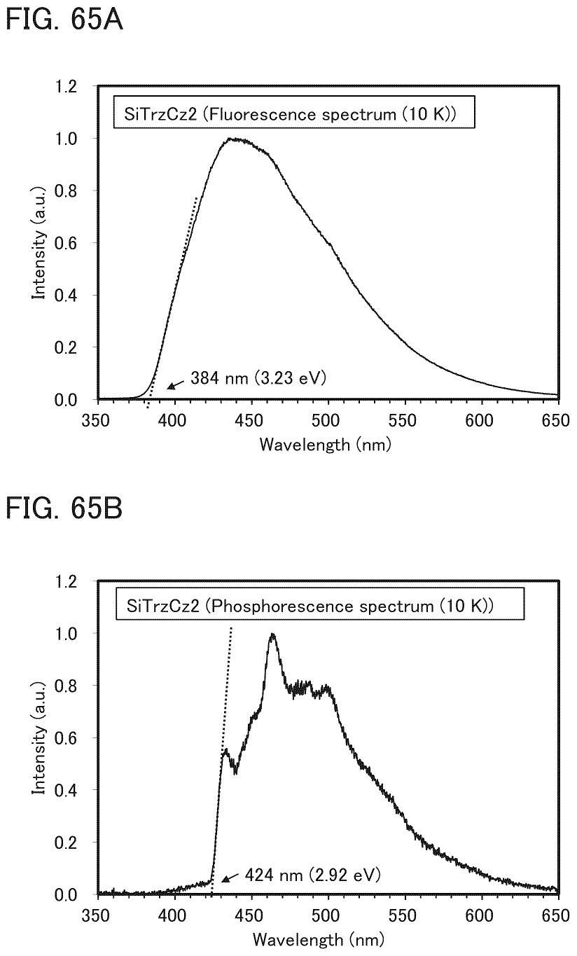

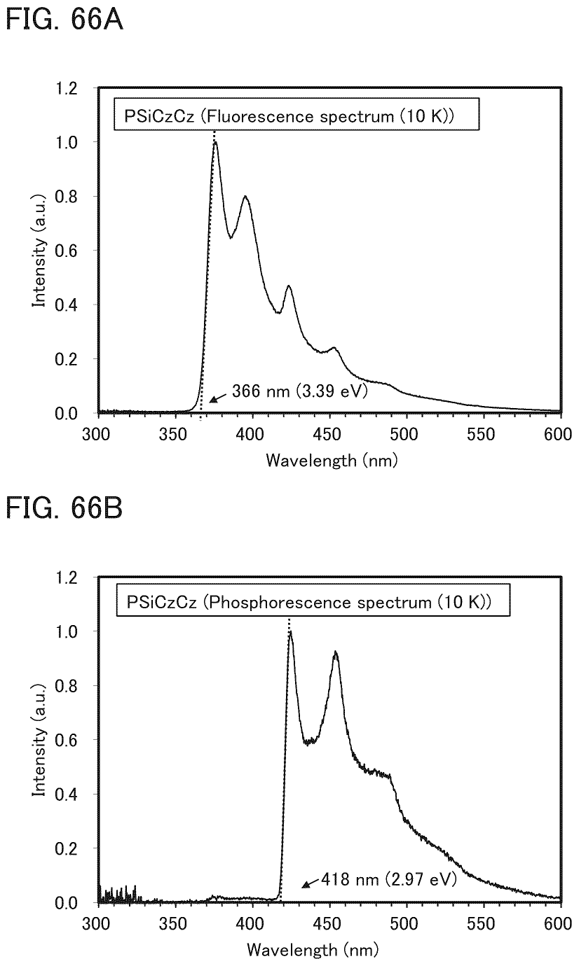

FIG. 64A shows the measurement result of the fluorescence spectrum (10 K) of 3Ph2CzCzBN, and FIG. 64B shows the measurement result of the phosphorescence spectrum (10 K) of 3Ph2CzCzBN. FIG. 65A shows the measurement result of the fluorescence spectrum (10 K) of SiTrzCz2, and FIG. 65B shows the measurement result of the phosphorescence spectrum (10 K) of SiTrzCz2. FIG. 66A shows the measurement result of the fluorescence spectrum (10 K) of PSiCzCz, and FIG. 66B shows the measurement result of the phosphorescence spectrum (10 K) of PSiCzCz.

As shown in FIG. 64A, a wavelength of an emission edge on a shorter wavelength side of the fluorescence spectrum (10 K) of 3Ph2CzCzBN is 456 nm; thus, the S₁ level of 3Ph2CzCzBN is calculated to be 2.72 eV. As shown in FIG. 64B, a wavelength of an emission edge on a shorter wavelength side of the phosphorescence spectrum (10 K) of 3Ph2CzCzBN is 477 nm; thus, the T₁ level of 3Ph2CzCzBN is calculated to be 2.60 eV. According to these results, a difference in wavelength of the emission edge on the shorter wavelength side between the fluorescence spectrum and the phosphorescence spectrum of 3Ph2CzCzBN is found to be 21 nm, and an energy difference between the S₁ level and the T₁ level is calculated to be 0.12 eV.

As described above, the difference in wavelength of the emission edge on the shorter wavelength side between the fluorescence spectrum and the phosphorescence spectrum of 3Ph2CzCzBN is less than or equal to 30 nm, which is extremely small. In addition, the energy difference between the S₁ level and the T₁ level of 3Ph2CzCzBN is greater than 0 eV and less than or equal to 0.20 eV, which is extremely small. Thus, 3Ph2CzCzBN can be regarded as a substance capable of exhibiting thermally activated delayed fluorescence (a TADF material).

As shown in FIG. 65A, a wavelength of an emission edge on a shorter wavelength side of the fluorescence spectrum (10 K) of SiTrzCz2 is 384 nm; thus, the S₁ level of SiTrzCz2 is calculated to be 3.23 eV. As shown in FIG. 65B, a wavelength of an emission edge on a shorter wavelength side of the phosphorescence spectrum (10 K) of SiTrzCz2 is 424 nm; thus, the T₁ level of SiTrzCz2 is calculated to be 2.92 eV. According to these results, a difference in wavelength of the emission edge on the shorter wavelength side between the fluorescence spectrum and the phosphorescence spectrum of SiTrzCz2 is found to be 40 nm, and an energy difference between the S₁ level and the T₁ level is calculated to be 0.31 eV.

As shown in FIG. 66A, a wavelength of an emission edge on a shorter wavelength side of the fluorescence spectrum (10 K) of PSiCzCz is 366 nm; thus, the S₁ level of PSiCzCz is calculated to be 3.39 eV. As shown in FIG. 66B, a wavelength of an emission edge on a shorter wavelength side of the phosphorescence spectrum (10 K) of PSiCzCz is 418 nm; thus, the T₁ level of PSiCzCz is calculated to be 2.97 eV. According to these results, a difference in wavelength of the emission edge on the shorter wavelength side between the fluorescence spectrum and the phosphorescence spectrum of PSiCzCz is found to be 52 nm, and an energy difference between the S₁ level and the T₁ level is calculated to be 0.42 eV.

As described above, each of SiTrzCz2 and PSiCzCz has an energy difference between the S₁ level and the T₁ level greater than 0.20 eV. Accordingly, these materials can be regarded not as substances capable of exhibiting thermally activated delayed fluorescence (TADF materials) but as fluorescent substances.

The above results reveal that, in each of the light-emitting layers of the light-emitting device B-4, the T₁ levels of SiTrzCz2 and PSiCzCz as host materials are each higher than the T₁ level of 3Ph2CzCzBN as a TADF material, and the wavelength of the emission edge on the shorter wavelength side of the phosphorescence spectrum of each of SiTrzCz2 and PSiCzCz is shorter than the wavelength of the emission edge on the shorter wavelength side of the phosphorescence spectrum of 3Ph2CzCzBN.

Accordingly, the light-emitting device of one embodiment of the present invention is found to have favorable characteristics when including a light-emitting layer having a structure in which the T₁ levels of two kinds of host materials are each higher than the T₁ level of a TADF material.

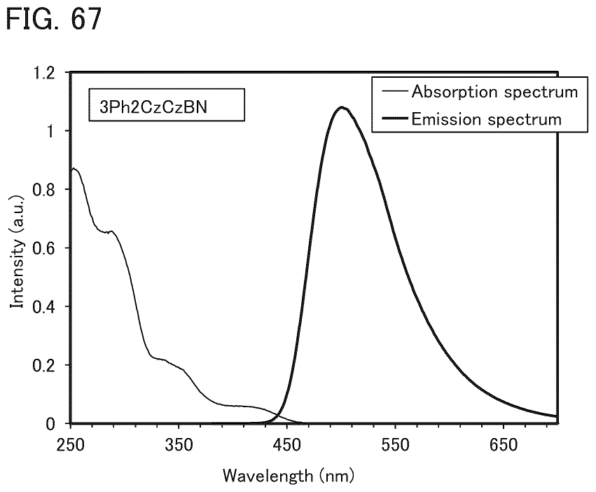

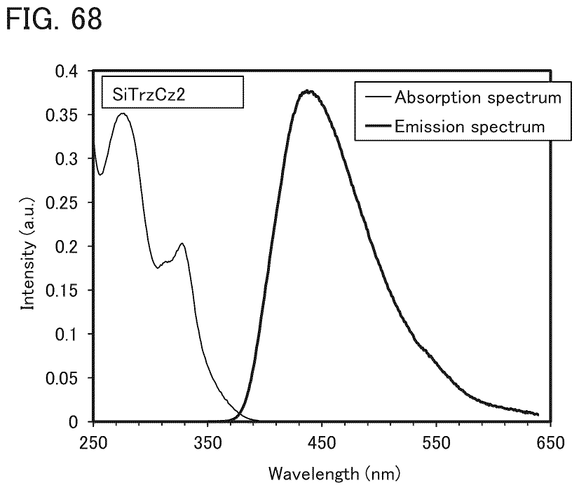

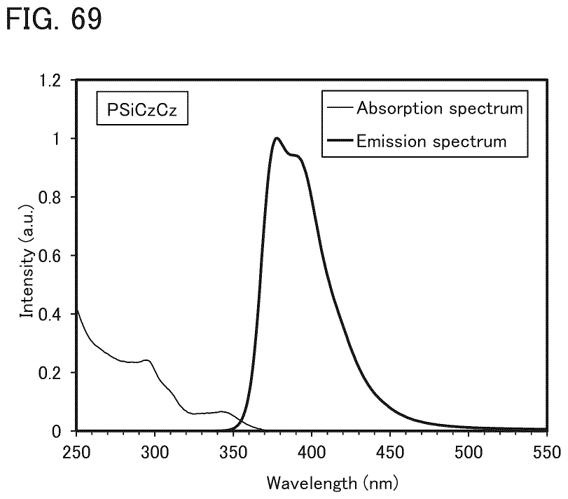

Next, results of emission and absorption spectra of thin films of 3Ph2CzCzBN, SiTrzCz2, and PSiCzCz measured at room temperature are shown. The measurement of the emission and absorption spectra of the materials and the like were performed in manners similar to those in Example 1. FIG. 67 shows the emission and absorption spectra of 3Ph2CzCzBN, FIG. 68 shows the emission and absorption spectra of SiTrzCz2, and FIG. 69 shows the emission and absorption spectra of PSiCzCz.

A wavelength (383 nm) of an emission edge on a shorter wavelength side of the PL spectrum (fluorescence spectrum) of SiTrzCz2 measured at room temperature shown in FIG. 68 and a wavelength (360 nm) of an emission edge on a shorter wavelength side of the PL spectrum (fluorescence spectrum) of PSiCzCz measured at room temperature shown in FIG. 69 are each shorter than a wavelength (459 nm) of an absorption edge on a longer wavelength side of the absorption spectrum of 3Ph2CzCzBN measured at room temperature shown in FIG. 67. Such a relation allows efficient transfer of excitation energy to 3Ph2CzCzBN in the light-emitting device B-4 and enables 3Ph2CzCzBN to emit light efficiently.

As shown in FIG. 67, a wavelength of an emission edge on a shorter wavelength side of the PL spectrum (fluorescence spectrum) of 3Ph2CzCzBN measured at room temperature is 451 nm; thus, the S₁ level of 3Ph2CzCzBN can be calculated to be 2.75 eV. According to the results of the PL spectrum (fluorescence spectrum) measured at room temperature and the phosphorescence spectrum measured at a low temperature (10 K) (see FIG. 64B) of 3Ph2CzCzBN, a difference in wavelength of the emission edge on the shorter wavelength side between the fluorescence spectrum (room temperature) and the phosphorescence spectrum (10 K) is 26 nm, and an energy difference between the S₁ level and the T₁ level is 0.15 eV. Thus, 3Ph2CzCzBN can be regarded as a TADF material.

Next, results of emission spectra (PL spectra) of thin films of SiTrzCz2 and PSiCzCz, which are the materials used for the light-emitting layers of the light-emitting device B-4, measured at room temperature, and a result of an emission spectrum (PL spectrum) of a mixed film, formed by co-evaporation of SiTrzCz2 and PSiCzCz at a weight ratio of 1:1, measured at room temperature are shown. The emission spectra were each measured using a 50-nm-thick thin film formed by evaporation over a quartz substrate. The emission spectra were measured with a fluorescence spectrophotometer FP-8600DS (produced by JASCO Corporation).

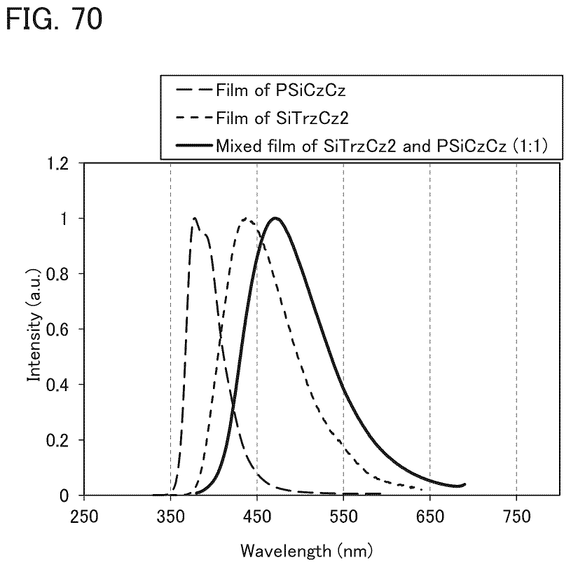

FIG. 70 shows the emission spectra (PL spectra) of the film of SiTrzCz2, the film of PSiCzCz, and the mixed film of SiTrzCz2 and PSiCzCz. Peak wavelengths of the emission spectra of the film of SiTrzCz2, the film of PSiCzCz, and the mixed film of SiTrzCz2 and PSiCzCz are 437 nm, 378 nm, and 471 nm, respectively, revealing that the peak wavelength of the emission spectrum of the mixed film of SiTrzCz2 and PSiCzCz is longer than that of the emission spectrum of each of the film of SiTrzCz2 and the film of PSiCzCz. Thus, it has been found that the emission spectrum of the mixed film of SiTrzCz2 and PSiCzCz is different from a spectrum obtained by superimposing the spectra of the films of SiTrzCz2 and PSiCzCz, and is a long-wavelength-shifted spectrum relative to the emission spectra of the films of SiTrzCz2 and PSiCzCz. The above indicates that SiTrzCz2 and PSiCzCz form, in combination, an exciplex when excited at room temperature, and the observed emission spectrum of the mixed film of SiTrzCz2 and PSiCzCz originates from the exciplex.

Accordingly, the light-emitting device of one embodiment of the present invention is found to have favorable characteristics when two kinds of host materials in a light-emitting layer form an exciplex.

Table 13 shows the results of calculating the power consumption of a display apparatus 3 assumed to include the light-emitting devices B-4, G-4, and R-3, in a manner similar to that in Example 1.

TABLE 13
Display apparatus 3

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.691 | 0.309 | 293 | 2933 | 74.3 | 3.95 | 27.2 | 6.25 | 170 |
| Green | 0.183 | 0.754 | 515 | 5146 | 244 | 2.11 | 14.5 | 6.13 | 89.2 |
| Blue | 0.121 | 0.137 | 192 | 1921 | 37.5 | 5.12 | 35.3 | 8.11 | 287 |
| Full white | 0.313 | 0.329 | 1000 | — | 89.4 | — | 77.1 | — | 546 |

The above table shows that the display apparatus 3 assumed to include the light-emitting devices of embodiments of the present invention has high current efficiency and low driving voltage in white light emission.

The above results show that the light-emitting devices of embodiments of the present invention have favorable characteristics, and the light-emitting device B-4 has a particularly high emission efficiency.

This application is based on Japanese Patent Application Serial No. 2024-134240 filed with Japan Patent Office on Aug. 9, 2024, the entire contents of which are hereby incorporated by reference.

What is claimed is:

1. A light-emitting device comprising:
a first electrode;
a second electrode;
an intermediate layer between the first electrode and the second electrode;
a first light-emitting layer between the first electrode and the intermediate layer;
a second light-emitting layer between the intermediate layer and the second electrode;
a first hole-transport layer between the first electrode and the first light-emitting layer; and
a second hole-transport layer between the intermediate layer and the second light-emitting layer,
wherein the first light-emitting layer comprises a first light-emitting substance,
wherein the second light-emitting layer comprises a second light-emitting substance,
wherein each of the first light-emitting substance and the second light-emitting substance is a TADF material,
wherein at least one of the first hole-transport layer and the second hole-transport layer comprises an organic compound comprising a π-electron rich heteroaromatic ring and no triarylamine skeleton,
wherein a difference between a maximum peak wavelength of an emission spectrum of the first light-emitting substance and a maximum peak wavelength of an emission spectrum of the second light-emitting substance is less than or equal to 30 nm, and
wherein the first light-emitting layer and the second light-emitting layer each emit light with a hue different from a hue of light emitted by a light-emitting layer in at least one of a plurality of adjacent light-emitting devices.

2. The light-emitting device according to claim 1,
wherein the first light-emitting substance is the same substance as the second light-emitting substance.

3. The light-emitting device according to claim 1, further comprising a first electron-transport layer between the first light-emitting layer and the intermediate layer,
wherein the first electron-transport layer comprises an organic compound comprising any one of a triazine ring, a pyrimidine ring, an imidazole ring, and an anthracene ring.

4. The light-emitting device according to claim 1, further comprising a second electron-transport layer between the second light-emitting layer and the second electrode,
wherein the second electron-transport layer comprises a layer comprising an organic compound comprising a triazine ring, and
wherein the intermediate layer comprises a first mixed layer of lithium or a lithium compound and an organic compound comprising a phenanthroline ring.

5. The light-emitting device according to claim 4,
wherein the second electron-transport layer comprises a second mixed layer of lithium or a lithium compound and an organic compound comprising a triazine ring, and
wherein the second mixed layer is between the second electrode and the layer comprising the organic compound comprising the triazine ring.

6. A light-emitting device comprising:
a first electrode;
a second electrode;
an intermediate layer between the first electrode and the second electrode;
a first light-emitting layer between the first electrode and the intermediate layer;
a second light-emitting layer between the intermediate layer and the second electrode;
a first hole-transport layer between the first electrode and the first light-emitting layer; and
a second hole-transport layer between the intermediate layer and the second light-emitting layer,
wherein the first hole-transport layer comprises a first layer and a second layer,
wherein the first layer is in contact with the first light-emitting layer,
wherein the first light-emitting layer comprises a first light-emitting substance and a first organic compound,
wherein a difference between a wavelength of an emission edge on a shorter wavelength side of a fluorescence spectrum of the first light-emitting substance and a wavelength of an emission edge on a shorter wavelength side of a phosphorescence spectrum of the first light-emitting substance is less than or equal to 30 nm,
wherein a wavelength of an emission edge on a shorter wavelength side of a phosphorescence spectrum of the first organic compound is shorter than the wavelength of the emission edge on the shorter wavelength side of the phosphorescence spectrum of the first light-emitting substance,
wherein the second light-emitting layer comprises a second light-emitting substance and a second organic compound,
wherein a difference between a wavelength of an emission edge on a shorter wavelength side of a fluorescence spectrum of the second light-emitting substance and a wavelength of an emission edge on a shorter wavelength side of a phosphorescence spectrum of the second light-emitting substance is less than or equal to 30 nm,
wherein a wavelength of an emission edge on a shorter wavelength side of a phosphorescence spectrum of the second organic compound is shorter than the wavelength of the emission edge on the shorter wavelength side of the phosphorescence spectrum of the second light-emitting substance,
wherein the first layer comprises a third organic compound,
wherein the third organic compound comprises a π-electron rich heteroaromatic ring and no triarylamine skeleton,
wherein the second layer comprises a fourth organic compound,
wherein the fourth organic compound comprises a triarylamine skeleton,
wherein a difference between a maximum peak wavelength of the fluorescence spectrum of the first light-emitting substance and a maximum peak wavelength of the fluorescence spectrum of the second light-emitting substance is less than or equal to 30 nm, and
wherein the first light-emitting layer and the second light-emitting layer each emit light with a hue different from a hue of light emitted by a light-emitting layer in at least one of a plurality of adjacent light-emitting devices.

7. The light-emitting device according to claim 6,
wherein a wavelength of an emission edge on a shorter wavelength side of a fluorescence spectrum of the first organic compound is shorter than a wavelength of an absorption edge on a longer wavelength side of an absorption spectrum of the first light-emitting substance, and
wherein a wavelength of an emission edge on a shorter wavelength side of a fluorescence spectrum of the second organic compound is shorter than a wavelength of an absorption edge on a longer wavelength side of an absorption spectrum of the second light-emitting substance.

8. The light-emitting device according to claim 6,
wherein each of the first light-emitting substance and the second light-emitting substance is a substance capable of exhibiting thermally activated delayed fluorescence.

9. The light-emitting device according to claim 6,
wherein the first light-emitting substance is the same substance as the second light-emitting substance.

10. The light-emitting device according to claim 6,
wherein the fourth organic compound comprises a polycyclic aromatic ring.

11. The light-emitting device according to claim 6, further comprising a first electron-transport layer between the first light-emitting layer and the intermediate layer,
wherein the first electron-transport layer comprises an organic compound comprising any one of a triazine ring, a pyrimidine ring, an imidazole ring, and an anthracene ring.

12. The light-emitting device according to claim 6, further comprising a second electron-transport layer between the second light-emitting layer and the second electrode,
wherein the second electron-transport layer comprises a layer comprising an organic compound comprising a triazine ring, and
wherein the intermediate layer comprises a first mixed layer of lithium or a lithium compound and an organic compound comprising a phenanthroline ring.

13. The light-emitting device according to claim 12,
wherein the second electron-transport layer comprises a second mixed layer of lithium or a lithium compound and an organic compound comprising a triazine ring, and
wherein the second mixed layer is between the second electrode and the layer comprising the organic compound comprising the triazine ring.

14. A display apparatus comprising:
a first light-emitting device; and
a second light-emitting device,
wherein the first light-emitting device and the second light-emitting device emit light of different colors,
wherein the first light-emitting device comprises:
a first electrode;
a second electrode;
a first intermediate layer between the first electrode and the second electrode;
a first light-emitting layer between the first electrode and the first intermediate layer;
a second light-emitting layer between the first intermediate layer and the second electrode;
a first hole-transport layer between the first electrode and the first light-emitting layer; and
a second hole-transport layer between the first intermediate layer and the second light-emitting layer,
wherein the first light-emitting layer comprises a first light-emitting substance,
wherein the second light-emitting layer comprises a second light-emitting substance,
wherein the first light-emitting substance is a substance capable of exhibiting thermally activated delayed fluorescence,
wherein the second light-emitting substance is a substance capable of exhibiting thermally activated delayed fluorescence,
wherein at least one of the first hole-transport layer and the second hole-transport layer comprises a first organic compound comprising no triarylamine skeleton,
wherein a difference between a maximum peak wavelength of an emission spectrum of the first light-emitting substance and a maximum peak wavelength of an emission spectrum of the second light-emitting substance is less than or equal to 30 nm,
wherein the second light-emitting device comprises:
a third electrode;
a fourth electrode;
a second intermediate layer between the third electrode and the fourth electrode;
a third light-emitting layer between the third electrode and the second intermediate layer;
a fourth light-emitting layer between the second intermediate layer and the fourth electrode;
a third hole-transport layer between the third electrode and the third light-emitting layer; and
a fourth hole-transport layer between the second intermediate layer and the fourth light-emitting layer,
wherein the third light-emitting layer comprises a third light-emitting substance,
wherein the fourth light-emitting layer comprises a fourth light-emitting substance,
wherein at least one of the third hole-transport layer and the fourth hole-transport layer comprises a second organic compound comprising a triarylamine skeleton, and
wherein a difference between a maximum peak wavelength of an emission spectrum of the third light-emitting substance and a maximum peak wavelength of an emission spectrum of the fourth light-emitting substance is less than or equal to 30 nm.

15. The display apparatus according to claim 14,
wherein the first organic compound comprises a π-electron rich heteroaromatic ring, and
wherein each of the third light-emitting substance and the fourth light-emitting substance is a phosphorescent substance.

16. The display apparatus according to claim 14,
wherein each of the third light-emitting substance and the fourth light-emitting substance is a fluorescent substance.
